(19) United States
(12) Patent Application Publication
(10) Pub. No.: US 2026/0365915 A1
(43) Pub. Date: Nov. 19, 2026

(54) COLOR CONVERSION COMPOSITION, COLOR CONVERSION MEMBER, AND LIGHT SOURCE UNIT, DISPLAY, AND LIGHTING DEVICE INCLUDING SAME

(71) Applicant: Toray Industries, Inc., Chuo-ku, Tokyo (JP)

(72) Inventor: Hirotoshi SAKAINO, Otsu-shi, Shiga (JP)

(73) Assignee: Toray Industries, Inc., Chuo-ku, Tokyo (JP)

(21) Appl. No.: 19/110,974

(22) PCT Filed: Sep. 25, 2023
(86) PCT No.: PCT/JP2023/034738

§ 371 Date: Mar. 12, 2025

(30) Foreign Application Priority Data
Sep. 28, 2022 (JP) 2022-154559

(51) Int. Cl. C09K 11/02; C09K 11/06; H10H 20/851

(52) U.S. Cl. CPC C09K 11/02; C09K 11/06; H10H 20/8512; C09K 2211/1055; C09K 2211/107

(57) ABSTRACT

A color conversion composition of an aspect of the present invention is a color conversion composition including at least one luminescent material and a binder resin. The binder resin contains at least one branched polymer selected from the group consisting of a star polymer, a graft polymer, and a hyperbranched polymer.

### CROSS REFERENCE TO RELATED APPLICATIONS

This application is the U.S. National Phase of PCT/JP2023/034738, filed Sep. 25, 2023, which claims priority to Japanese Patent Application No. 2022-154559, filed Sep. 28, 2022, the disclosures of these applications being incorporated herein by reference in their entireties for all purposes.

### FIELD OF THE INVENTION

The present invention relates to a color conversion composition, a color conversion member, and a light source unit, a display, and a lighting device including the same.

### BACKGROUND OF THE INVENTION

There are many studies on the application of multi-color technology based on color conversion systems to liquid crystal displays, organic EL displays, lighting devices, and the like. Color conversion represents to convert light emitted from a light emitter into a light with a longer wavelength, and includes converting, for example, blue emission into green or red emission.

A composition (hereinafter referred to as color conversion composition) having this color conversion function is formed into a sheet and combined, for example, with a blue light source, and three primary colors of blue, green, and red can thereby be obtained from the blue light source, that is, white light can be obtained. A white light source obtained by combining a blue light source with a sheet having a color conversion function (hereinafter referred to as color conversion sheet) is used as a light source unit such as a backlight unit, and such a light source unit is combined with a liquid crystal driving portion and a color filter, whereby a full-color display can be manufactured. Further, the white light source obtained by combining a blue light source with a color conversion sheet can be used as a white light source (lighting device) such as a LED lighting as it is.

The problem to be solved in a liquid crystal display utilizing a color conversion system includes improvement of color reproducibility and durability. High color purity of blue, green, and red, achieved by reducing the full width at half maximum of the emission spectrum of a light source unit with respect to blue, green, and red light, is effective in improving color reproducibility. As a means to solve this task, for example, color conversion materials containing an organic fluorescent material have been proposed (see, for example, Patent Literatures 1 and 2). In addition, as technologies to improve the durability, a technology comprising adding a light stabilizer (see, for example, Patent Literatures 3) and a technology to improve durability by an oxygen barrier (see, for example, Patent Literature 4) have been proposed.

### PATENT LITERATURE

Patent Literature 1: JP 2010-61824 A
Patent Literature 2: JP 2014-136771 A
Patent Literature 3: JP 2019-50381 A
Patent Literature 4: WO 2017/057287

### SUMMARY OF THE INVENTION

Conventionally, the technologies described in Patent Literatures 1 to 4 enable obtaining a color conversion composition having excellent color reproducibility, and relatively excellent durability. However, in response to recent demands for higher definition such as 4K or 8K, higher dynamic range (HDR), and higher contrast due to local dimming, illumination required for the light source units of liquid crystal displays has been increasing, and higher durability is also required for color conversion members.

An object of the present invention to be solved is to achieve both improved color reproducibility and durability in a color conversion composition or color conversion member (for example, color conversion sheet) used for light source units, displays such as liquid crystal displays or lighting devices such as LED light. In particular, the present invention aims to provide a color conversion member that achieves both light emission with high color purity and high durability.

In order to solve the above problem and achieve the object, the present invention has a constitution described in any one of [1] to [17] below.

[1] The color conversion composition according to the present invention is a color conversion composition including:
at least one luminescent material and a binder resin,
wherein the binder resin contains at least one branched polymer selected from the group consisting of a star polymer, a graft polymer, and a hyperbranched polymer.

[2] In the color conversion composition according to the present invention described above in [1],
the binder resin contains at least the star polymer, and
an arm polymer of the star polymer is a polymer of at least one monomer selected from the group consisting of a vinyl compound, acrylic acid, acrylate ester, acrylamide, methacrylic acid, methacrylate ester, and methacrylamide.

[3] In the color conversion composition according to the present invention described above in [1] or [2],
the binder resin contains at least the star polymer, and
a core part of the star polymer is a part containing any one of a sugar alcohol derivative, a cyclic siloxane derivative, and silsesquioxane.

[4] In the color conversion composition according to the present invention described above in [1] or [3],
the binder resin contains at least the star polymer, and
a core part of the star polymer is a part containing silsesquioxane.

[5] In the color conversion composition according to the present invention described above in any one of [1] to [4],
the binder resin contains at least the star polymer, and
a core part of the star polymer is a part containing a sugar alcohol derivative.

[6] In the color conversion composition according to the present invention described above in any one of [1] to [5],
an acid value of the at least one branched polymer is 10 mgKOH/g or less.

[7] In the color conversion composition according to the present invention described above in any one of [1] to [6],
a base number of the at least one branched polymer is 10 mgKOH/g or less.

[8] In the color conversion composition according to the present invention described above in any one of [1] to [7],
the binder resin further contains a resin that does not fall under any one of the star polymer, the graft polymer, and the hyperbranched polymer, the resin being a polymer of at least one monomer selected from the group consisting of acrylate ester, methacrylate ester, and styrene, or a hydrogenated product thereof.

[9] In the color conversion composition according to the present invention described above in any one of [1] to [8],
the binder resin further contains a resin that does not fall under any one of the star polymer, the graft polymer, and the hyperbranched polymer, the resin having a glass transition temperature of 100 °C or more.

[10] In the color conversion composition according to the present invention described above in any one of [1] to [9],
a full width at half maximum of an emission spectrum at an emission peak wavelength of the at least one luminescent material is 60 nm or less.

[11] In the color conversion composition according to the present invention described above in any one of [1] to [10],
the at least one luminescent material contains a compound having a partial structure of the general formula (1):

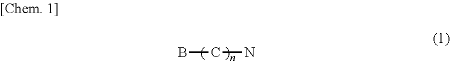

(wherein in the general formula (1), B is a boron atom, N is a nitrogen atom, and C is a carbon atom; n is an integer of 0 to 2; and when n is 0, the partial structure of the general formula (1) is a directly combined structure between B and N).

[12] In the color conversion composition according to the present invention described above in any one of [1] to [11],
the at least one luminescent material contains at least one of a compound of the general formula (2), a compound of the general formula (3), and a compound of the general formula (4):

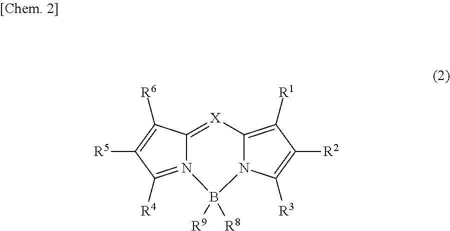

(wherein in the general formula (2), X is C—R⁷ or N; each of R¹ to R⁹, which may be the same as or different from one another, is a substituent selected from a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, a carbonyl group, a carboxyl group, an oxycarbonyl group, an ester group, a carbamoyl group, an amide group, a sulfonyl group, a sulfonate ester group, a sulfonamide group, an amino group, an imino group, a nitro group, a silyl group, a siloxanyl group, a boryl group, a phosphine oxide group, and a fused ring and an aliphatic ring each formed between adjacent substituents; and each of the R¹ to R⁹ may independently be substituted with the selected substituent, and these substituents may be further substituted with the selected substituent)

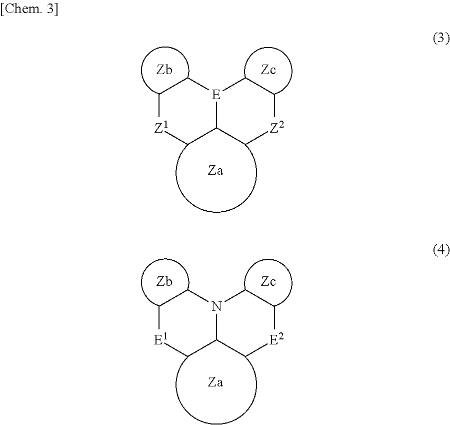

(wherein in the general formula (3) or the general formula (4), the rings Za, Zb, and Zc independently are a substituted or unsubstituted aryl ring having 6 to 30 ring-forming carbon atoms or a substituted or unsubstituted heteroaryl ring having 5 to 30 ring-forming carbon atoms; Z¹ and Z² are independently an oxygen atom, NRa (a nitrogen atom bearing a Ra substituent), or sulfur atom; in cases where Z¹ is NRa, the substituent Ra, together with the ring Za or the ring Zb, optionally forms a ring; in cases where Z² is NRa, the substituent Ra, together with the ring Za or the ring Zc, optionally forms a ring; E is a boron atom, a phosphorus atom, SiRa (a silicon atom bearing a Ra substituent), or P═O; E¹ and E² are independently BRa (a boron atom bearing a Ra substituent), PRa (a phosphorus atom bearing a Ra substituent), SiRa₂ (a silicon atom bearing two Ra substituents), P(═O)Ra₂ (a phosphine oxide bearing two Ra substituents) or P(═S)Ra₂ (phosphine sulfide bearing two Ra substituents), C═O (a carbonyl group), S(═O) or S(═O)₂; in cases where E¹ is BRa, PRa, SiRa₂, P(═O)Ra₂, or P(═S)Ra₂, the substituent Ra, together with the ring Za or the ring Zb, optionally forms a ring; in cases where E² is BRa, PRa, SiRa₂, P(═O)Ra₂, or P(═S)Ra₂, the substituent Ra, together with the ring Za or the ring Zc, optionally forms a ring; each of substituents Ra independently is a substituent selected from a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, a carbonyl group, a carboxyl group, an oxycarbonyl group, an ester group, a carbamoyl group, an amide group, a sulfonyl group, a sulfonate ester group, a sulfonamide group, an amino group, an imino group, a nitro group, a silyl group, a siloxanyl group, a boryl group, a phosphine oxide group, and a fused ring and an aliphatic ring each formed between adjacent substituents; and the substituent Ra may independently be substituted with the selected substituent, and these substituents may be further substituted with the selected substituent).

[13] A color conversion member according to the present invention includes the color conversion composition described above in any one of [1] to [12] or a cured product thereof.

[14] A light source unit according to the present invention includes:
a light source, and
the color conversion member described above in [13].

[15] In the light source unit according to the present invention described above in [14],
the light source is a light-emitting diode or an organic electroluminescence element with a maximum light emission having a wavelength of in the range of 400 nm to 500 nm.

[16] A display according to the present invention includes the light source unit described above in [14] or [15].

[17] A lighting device according to the present invention includes the light source unit described above in or [15].

The color conversion composition according to the present invention and the color conversion member using the same provide both light emission with high color purity and high durability, and therefore are effective in achieving both improved color reproducibility and improved durability.

### BRIEF DESCRIPTION OF THE DRAWINGS

FIG. 1 is a schematic cross-sectional view depicting the first example of a color conversion member according to an embodiment of the present invention.

FIG. 2 is a schematic cross-sectional view depicting the second example of a color conversion member according to an embodiment of the present invention.

FIG. 3 is a schematic cross-sectional view depicting the third example of a color conversion member according to an embodiment of the present invention.

FIG. 4 is a schematic cross-sectional view depicting the fourth example of a color conversion member according to an embodiment of the present invention.

FIG. 5 is a schematic cross-sectional view depicting the fifth example of a color conversion member according to an embodiment of the present invention.

FIG. 6 is a schematic cross-sectional view depicting the sixth example of a color conversion member according to an embodiment of the present invention.

### DETAILED DESCRIPTION OF EMBODIMENTS OF THE INVENTION

Suitable embodiments of the color conversion composition, the color conversion member, and the light source unit, display, and lighting device including the same, according to the present invention will be specifically described below, but the present invention is not limited to the following embodiments and can be modified in various ways depending on the purpose and application.

### <Color Conversion Composition>

The color conversion composition according to the embodiment of the present invention (hereinafter sometimes abbreviated as the color conversion composition of the present invention) contains at least one luminescent material and a binder resin. In this color conversion composition, the binder resin contains at least one branched polymer selected from the group consisting of star polymers, graft polymers and hyperbranched polymers. The luminescent material and the binder resin contained in the color conversion composition of the present invention will be described below in order.

### <Luminescent Material>

The color conversion composition according to the embodiment of the present invention contains at least one luminescent material. The luminescent material in the present invention refers to a material that when irradiated with a certain type of light emits a light with a wavelength different from that light.

Examples of the luminescent material include inorganic fluorescent substance, fluorescent pigment, fluorescent dye, and quantum dot. The color conversion composition of the present invention may contain two or more luminescent materials. In order to achieve high-efficiency color conversion, a material exhibiting light emission characteristics with high quantum yield is preferred as the luminescent material. Particularly, a quantum dot or an organic luminescent material is preferably used. Furthermore, from the viewpoints of uniformity of dispersion, reduction in the amount used, and reduction in environmental load, it is more preferable to use an organic luminescent material as the luminescent material.

Examples of the organic luminescent material are as follows. Examples of the suitable organic luminescent material include a compound having a fused aryl ring such as naphthalene, anthracene, phenanthrene, pyrene, chrysene, naphthacene, triphenylene, perylene, fluoranthene, fluorene, indene, and a derivative thereof. Examples of the suitable organic luminescent material further include a heteroaryl ring-containing compound and a derivative thereof, such as furan, pyrrole, thiophene, silole, 9-silafluorene, 9,9′-spirobisilafluorene, benzothiophene, benzofuran, indole, dibenzothiophene, dibenzofuran, imidazopyridine, phenanthroline, pyridine, pyrazine, naphthyridine, quinoxaline and pyrrolopyridine, and borane derivatives.

Examples of the suitable organic luminescent material further include stilbene derivatives such as 1,4-distyrylbenzene, 4,4′-bis(2-(4-diphenylaminophenyl)ethenyl)biphenyl, and 4,4′-bis(N-(stilben-4-yl)-N-phenylamino)stilbene; aromatic acetylene derivatives; tetraphenylbutadiene derivatives; aldazine derivatives; pyrromethene derivatives, and diketopyrrolo[3,4-c]pyrrole derivatives. Examples of the suitable organic luminescent material further include coumarin derivatives such as coumarin 6, coumarin 7, and coumarin 153; azole derivatives such as imidazole, thiazole, thiadiazole, carbazole, oxazole, oxadiazole, triazole, and metal complexes thereof; cyanine-based compounds such as indocyanine green; a xanthene-based compounds and thioxanthene-based compounds such as fluorescein, eosin, and rhodamine.

Examples of the suitable organic luminescent material further include polyphenylene-based compounds; naphthalimide derivatives; phthalocyanine derivatives and metal complexes thereof; porphyrin derivatives and metal complexes thereof; oxazine-based compounds such as Nile Red and Nile Blue; helicene-based compounds; and aromatic amine derivatives such as N,N′-diphenyl-N,N′-di(3-methylphenyl)-4,4′-diphenyl-1,1′-diamine. Examples of the suitable organic luminescent material further include organic metal complex compound of iridium (Ir), ruthenium (Ru), rhodium (Rh), palladium (Pd), platinum (Pt), osmium (Os), europium (Eu), rhenium (Re) and the like. However, the organic luminescent material of the present invention is not limited to those mentioned above.

The organic luminescent material may be a fluorescent material or a phosphorescent material, but in order to achieve high color purity, a fluorescent material is preferred. As mentioned above, in order to improve color reproducibility, it is preferable that the full width at half maximum of the emission spectrum of each of blue, green and red colors is small. For this reason, the full width at half maximum of the emission spectrum at the emission peak wavelength of at least one luminescent material contained in the color conversion composition of the present invention is preferably 60 nm or less, and more preferably 50 nm or less.

As one embodiment of the present invention, from the viewpoint of exhibiting light emission with high color purity, it is preferable that the at least one luminescent material described above contains a compound having a partial structure of the general formula (1).

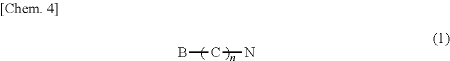

In the general formula (1), B is a boron atom, N is the nitrogen atom, and C is a carbon atom. n is an integer of 0 to 2. When n is 0, a partial structure of the general formula (1) is a directly combined structure between B and N.

The compound having the partial structure of the general formula (1) exhibits emission with high color purity due to the interaction between the Lewis acidic boron atom and the Lewis basic nitrogen atom.

In addition, as one embodiment of the present invention, from the viewpoint of exhibiting light emission with high color purity and having good durability, it is preferable that the at least one luminescent material described above contains at least one of a compound of the general formula (2), a compound of the general formula (3), and a compound of the general formula (4).

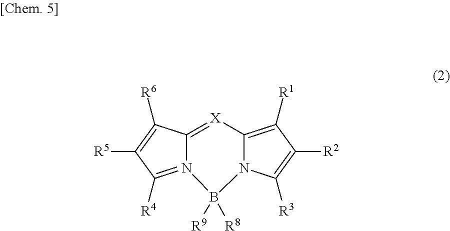

In the general formula (2), X is C—R⁷ or N. Each of R¹ to R⁹, which may be the same as or different from one another, is a substituent selected from a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, a carbonyl group, a carboxyl group, an oxycarbonyl group, an ester group, a carbamoyl group, an amide group, a sulfonyl group, a sulfonate ester group, a sulfonamide group, an amino group, an imino group, a nitro group, a silyl group, a siloxanyl group, a boryl group, a phosphine oxide group, and a fused ring and an aliphatic ring each formed between adjacent substituents. Each of R¹ to R⁹ independently may be further substituted with a substituent selected from them. The substituent with which each of R¹ to R⁹ is substituted may be further substituted with a substituent selected from them.

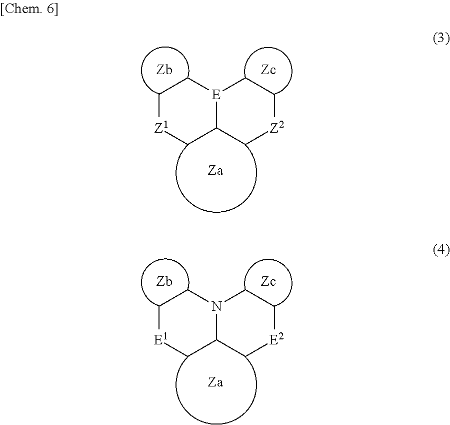

In the general formula (3) or the general formula (4), the rings Za, Zb, and Zc independently represent a substituted or unsubstituted aryl ring having 6 to 30 ring-forming carbon atoms or a substituted or unsubstituted heteroaryl ring having 5 to 30 ring-forming carbon atoms.

In the general formula (3), Z¹ and Z² are independently an oxygen atom, NRa (a nitrogen atom bearing a Ra substituent), or a sulfur atom. In cases where Z¹ is NRa, the substituent Ra, together with the ring Za or the ring Zb, optionally forms a ring. In cases where Z² is NRa, the substituent Ra, together with the ring Za or the ring Zc, optionally forms a ring. E is a boron atom, a phosphorus atom, SiRa (a silicon atom bearing a Ra substituent), or P═O.

In the general formula (4), E¹ and E² are independently BRa (a boron atom bearing a Ra substituent), PRa (a phosphorus atom bearing a Ra substituent), SiRa₂ (a silicon atom bearing two Ra substituents), P(═O)Ra₂ (a phosphine oxide bearing two Ra substituents) or P(═S)Ra₂ (a phosphine sulfide bearing two Ra substituents), C═O (carbonyl group), S(═O), or S(═O)₂. In cases where E¹ is BRa, PRa, SiRa₂, P(═O)Ra₂, or P(═S)Ra₂, the substituent Ra, together with the ring Za or the ring Zb, optionally forms a ring. In cases where E² is BRa, PRa, SiRa₂, P(═O)Ra₂, or P(═S)Ra₂, the substituent Ra, together with the ring Za or the ring Zc, optionally forms a ring.

Each of the above substituent Ra independently is a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, a carbonyl group, a carboxyl group, an oxycarbonyl group, an ester group, a carbamoyl group, an amide group, a sulfonyl group, a sulfonate ester group, a sulfonamide group, an amino group, an imino group, a nitro group, a silyl group, a siloxanyl group, a boryl group, or a phosphine oxide group, and a fused ring and an aliphatic ring each formed between adjacent substituents. Moreover, the substituent Ra may be further substituted with a substituent selected from them. The substituent with which the substituent Ra is substituted may be further substituted with a substituent selected from them.

In all of the groups described above, hydrogen can be deuterium. This is also the case for the compounds or partial structures thereof described in the following. In the present specification, for example, a substituted or unsubstituted aryl group having a carbon number of 6 to 40 means that the number of carbons is from 6 to 40 including the number of carbons contained in a substituent substituted on the aryl group, and the same applies to other substituents of which carbon number is specified.

The word “unsubstituted” in the phrase “substituted or unsubstituted” refers to substitution with a hydrogen atom(s) or a deuterium atom(s). The phrase “substituted or unsubstituted” used in the context of the compounds or partial structures thereof described below has the same meaning as described above.

In all of the groups above, when the group is substituted, the substituent is an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, a carbonyl group, a carboxyl group, an oxycarbonyl group, an ester group, a carbamoyl group, an amide group, a sulfonyl group, a sulfonate ester group, a sulfonamide group, an imino group, an amino group, a nitro group, a silyl group, a siloxanyl group, a boryl group, or a phosphine oxide group. These substituents may further be substituted with the above-described substituent.

The alkyl group represents, for example, a saturated aliphatic hydrocarbon group such as methyl group, ethyl group, n-propyl group, isopropyl group, n-butyl group, sec-butyl group and tert-butyl group, which may or may not have a substituent. The additional substituent in the case of being substituted is not particularly limited and includes, for example, an alkyl group, halogen, an aryl group, and a heteroaryl group, and this is a common feature in the following description. Furthermore, the number of carbon atoms in the alkyl groups is not specifically limited, but is preferably not less than 1 and not more than 20, more preferably not less than 1 and not more than 8, in view of availability and cost.

“Cycloalkyl group” refers to a saturated alicyclic hydrocarbon group, such as a cyclopropyl group, a cyclohexyl group, a norbornyl group, or an adamantyl group, and the cycloalkyls may be substituted or unsubstituted. The number of carbon atoms in the alkyl groups is not specifically limited, but is preferably not less than 3 and not more than 20.

“Heterocyclic group” refers to an aliphatic ring having an atom other than carbon in the ring, such as a pyran ring, a piperidine ring, or cyclic amide, and the heterocycles may be substituted or unsubstituted. The number of carbon atoms in the heterocyclic groups is not specifically limited, but is preferably not less than 2 and not more than 20.

“Alkenyl group” refers to an unsaturated aliphatic hydrocarbon group containing a double bond, such as a vinyl group, an allyl group, or a butadienyl group, and the alkenyls may be substituted or unsubstituted. The number of carbon atoms in the alkenyl groups is not specifically limited, but is preferably not less than 2 and not more than 20.

“Cycloalkenyl group” refers to an unsaturated alicyclic hydrocarbon group containing a double bond, such as a cyclopentenyl group, a cyclopentadienyl group, or a cyclohexenyl group, and the cycloalkenyls may be substituted or unsubstituted. The number of carbon atoms in the cycloalkenyl groups is not specifically limited, but is preferably not less than 3 and not more than 20.

“Alkynyl group” refers to an unsaturated aliphatic hydrocarbon group containing a triple bond, such as an ethynyl group, and the alkynyls may be substituted or unsubstituted. The number of carbon atoms in the alkynyl groups is not specifically limited, but is preferably not less than 2 and not more than 20.

“Alkoxy group” refers to a functional group containing an aliphatic hydrocarbon group connected via an ether linkage, such as a methoxy group, an ethoxy group, or a propoxy group, and the aliphatic hydrocarbon group may be substituted or unsubstituted. The number of carbon atoms in the alkoxy groups is not specifically limited, but is preferably not less than 1 and not more than 20.

“Alkylthio group” refers to an alkoxy group in which the oxygen atom in the ether linkage is replaced by a sulfur atom. The hydrocarbon group in an alkylthio group may be substituted or unsubstituted. The number of carbon atoms in the alkylthio groups is not specifically limited, but is preferably not less than 1 and not more than 20.

“Aryl ether group” refers to a functional group containing an aromatic hydrocarbon group connected via an ether linkage, such as a phenoxy group, and the aromatic hydrocarbon group may be substituted or unsubstituted. The number of carbon atoms in the aryl ether groups is not specifically limited, but is preferably not less than 6 and not more than 40.

“Aryl thioether group” refers to an aryl ether group in which the oxygen atom in the ether linkage is replaced by a sulfur atom. The aromatic hydrocarbon group in an aryl thioether group may be substituted or unsubstituted. The number of carbon atoms in the aryl thioether groups is not specifically limited, but is preferably not less than 6 and not more than 40.

“Aryl group” refers to an aromatic hydrocarbon group, such as a phenyl group, a biphenyl group, a terphenyl group, a naphthyl group, a fluorenyl group, a benzofluorenyl group, a dibenzofluorenyl group, a phenanthryl group, an anthracenyl group, a benzophenanthryl group, a benzoanthracenyl group, a chrysenyl group, a pyrenyl group, a fluoranthenyl group, a triphenylenyl group, a benzofluoranthenyl group, a dibenzoanthracenyl group, a perylenyl, or a helicenyl group. Among them, a phenyl group, a biphenyl group, a terphenyl group, a naphthyl group, a fluorenyl group, a phenanthryl group, an anthracenyl group, a pyrenyl group, a fluoranthenyl group, and a triphenylenyl group are preferred. The aryl groups may be substituted or unsubstituted. The number of carbon atoms in the aryl groups is not specifically limited, but is preferably not less than 6 and not more than 40 and more preferably not less than 6 and not more than 30.

The aryl group is preferably a phenyl group, a biphenyl group, a terphenyl group, a naphthyl group, a fluorenyl group, a phenanthryl group, or an anthracenyl group, more preferably a phenyl group, a biphenyl group, a terphenyl group, or a naphthyl, still more preferably a phenyl group, a biphenyl group, or a terphenyl group, and particularly preferably a phenyl group.

In the case where each substituent is further substituted with an aryl group, the aryl group is preferably a phenyl group, a biphenyl group, a terphenyl group, a naphthyl group, a fluorenyl group, a phenanthryl group, or an anthracenyl group, more preferably a phenyl group, a biphenyl group, a terphenyl group, or a naphthyl group, and particularly preferably a phenyl group.

“Heteroaryl group” refers to an aromatic ring group having one or more atoms other than carbon in the ring, such as a pyridyl group, a furanyl group, a thienyl, quinolinyl group, an isoquinolinyl group, a pyrazinyl, pyrimidyl group, a pyridazinyl group, a triazinyl group, a naphthyridinyl group, a cinnolinyl group, a phthalazinyl group, a quinoxalinyl group, a quinazolinyl group, a benzofuranyl group, a benzothienyl group, an indolyl group, a dibenzofuranyl group, a dibenzothienyl group, a carbazolyl group, a benzo-carbazolyl group, a carbolinyl group, an indolo-carbazolyl group, a benzofuro-carbazolyl group, a benzothieno-carbazolyl group, a dihydroindeno-carbazolyl group, a benzoquinolinyl group, an acridinyl group, a dibenzoacridinyl group, a benzoimidazolyl group, an imidazopyridyl group, a benzoxazolyl group, a benzothiazolyl group, or a phenanthrolinyl group. However, naphthyridinyl refers to any of a 1,5-naphthyridinyl group, a 1,6-naphthyridinyl group, a 1,7-naphthyridinyl group, a 1,8-naphthyridinyl group, a 2,6-naphthyridinyl group, or a 2,7-naphthyridinyl group. The heteroaryl groups may be substituted or unsubstituted. The number of carbon atoms in the heteroaryl groups is not specifically limited, but is preferably not less than 2 and not more than 40 and more preferably not less than 2 and not more than 30.

The heteroaryl group is preferably a pyridyl group, a furanyl group, a thienyl group, a quinolinyl group, a pyrimidyl group, a triazinyl group, a benzofuranyl, benzothienyl group, an indolyl group, a dibenzofuranyl, dibenzothienyl group, a carbazolyl group, a benzoimidazolyl group, an imidazopyridyl group, a benzoxazolyl group, a benzothiazolyl group, or a phenanthrolinyl group, more preferably a pyridyl group, a furanyl group, a thienyl group, or a quinolinyl group, and particularly preferably a pyridyl group.

In cases where each substituent is further substituted with a heteroaryl group, the heteroaryl group is preferably a pyridyl group, a furanyl group, a thienyl, quinolinyl group, a pyrimidyl group, a triazinyl group, a benzofuranyl group, a benzothienyl group, an indolyl, dibenzofuranyl group, a dibenzothienyl group, a carbazolyl group, a benzoimidazolyl group, an imidazopyridyl group, a benzoxazolyl group, a benzothiazolyl group, or a phenanthrolinyl group, more preferably a pyridyl group, a furanyl group, a thienyl group, or a quinolinyl group, and particularly preferably a pyridyl group.

Halogen represents an atom selected from fluorine, chlorine, bromine and iodine. Additionally, a carbonyl group, a carboxyl group, an oxycarbonyl group, an ester group, a carbamoyl group, an amide group and an imino group may be substituted or unsubstituted. The substituent includes, for example, an alkyl group, a cycloalkyl group, an aryl group, and a heteroaryl group, and these substituents may be further substituted.

A sulfonyl group, a sulfonate ester group, and a sulfonamide group are groups of —S(═O)₂R¹⁰, —S(═O)₂OR¹⁰, and —S(═O)₂NR¹⁰R¹¹, respectively. The R¹⁰ and R¹¹ are each a hydrogen atom or selected from the same group as those mentioned above for the substituent when the group is substituted.

“Amino group” refers to a substituted or unsubstituted amino group. In cases where an amino group is substituted, the substituent may be, for example, an aryl group, a heteroaryl group, a linear alkyl group, or a branched alkyl group. As the aryl group and the heteroaryl group, a phenyl group, a naphthyl group, a pyridyl group and a quinolinyl group are preferable. These substituents may be further substituted. The number of carbon atoms is not specifically limited, but is preferably not less than 2 and not more than 50, more preferably not less than 6 and not more than 40, and particularly preferably not less than 6 and not more than 30.

“Silyl group” refers to, for example, an alkylsilyl group, such as a trimethylsilyl group, a triethylsilyl group, a tert-butyldimethylsilyl group, a propyldimethylsilyl group, or a vinyldimethylsilyl group; or an arylsilyl group, such as a phenyldimethylsilyl group, a tert-butyl(diphenyl)silyl group, a triphenylsilyl group, or a trinaphthylsilyl group. The substituent on the silicon atom may be further substituted. The number of carbon atoms in the silyl groups is not specifically limited, but is preferably not less than 1 and not more than 30.

“Siloxanyl group” refers to a group containing a silicon compound connected via an ether linkage, such as trimethylsiloxanyl. The substituent on the silicon atom may be further substituted. In addition, “boryl group” refers to a substituted or unsubstituted boryl group. In cases where a boryl group is substituted, the substituent may be, for example, an aryl group, a heteroaryl group, a linear alkyl group, a branched alkyl group, an aryl ether group, an alkoxy group, or a hydroxyl group. Among these, an aryl group and an aryl ether group are preferred.

The phosphine oxide group is a group represented by —P(═O)R¹⁰R¹¹. R¹⁰ and R¹¹ in the phosphine oxide group are each a hydrogen atom or selected from the same group as those mentioned above for the substituent when the group is substituted.

In the compound of the general formula (2), arbitrary adjacent two substituents (for example, R² and R³ in the general formula (2)) may be bonded each other to form a conjugated or non-conjugated fused ring or an aliphatic ring. Such a fused ring or aliphatic ring may include, in addition to carbon, an element selected from the group consisting of nitrogen, oxygen, sulfur, phosphorus, and silicon as a constituent element. The fused ring or aliphatic ring described above may further be fused to another ring.

The compound of the general formula (2), the compound of the general formula (3), and the compound of the general formula (4) exhibit a high fluorescence quantum yield and provide an emission spectrum with the peak full width at half maximum being small at the emission peak wavelength, so that both efficient color conversion and high color purity can be achieved.

Furthermore, various properties and physical properties such as luminous efficiency, color purity, thermal stability, light stability and dispersibility can be adjusted by introducing an appropriate substituent into an appropriate position of the compound of the general formula (2), the compound of the general formula (3), and the compound of the general formula (4). For example, in the compound of the general formula (2), compared with the case where all of R¹, R³, R⁴ and R⁶ are hydrogen atoms, when at least one of R¹, R³, R⁴ and R⁶ is a substituted or unsubstituted alkyl group, a substituted or unsubstituted aryl group, a substituted or unsubstituted heteroaryl group, or a substituted or unsubstituted ester group, better thermal stability and light stability are exhibited.

In the general formula (2), preferred examples of R¹, R³, R⁴ and R⁶ are methyl group, ethyl group, isopropyl group, tert-butyl group, cyclohexyl group, phenyl group, biphenyl group, terphenyl group, naphthyl group, pyridyl group, quinolinyl group, methyl ester group, ethyl ester group, and phenyl ester group, which groups may be further substituted. Each of R¹, R³, R⁴ and R⁶ may be the same as or different from one another.

In the general formula (2), each of R⁸ and R⁹ is preferably an fluorine, a fluorine-containing alkyl group, a fluorine-containing heteroaryl group, a fluorine-containing aryl group, a fluorine-containing alkoxy group, a fluorine-containing aryloxy group, a fluorine-containing heteroaryloxy group, or a cyano group. Particularly, for the reason that the compound is stable against excitation light and a higher fluorescence quantum yield is obtained, each of R⁸ and R⁹ is more preferably fluorine or a cyano group.

In the general formula (2), X is preferably C—R⁷ from the viewpoint of light stability. In addition, from the viewpoint of giving a higher fluorescence quantum yield and hardly undergoing thermal decomposition and from the viewpoint of light stability, it is preferred that, in the general formula (2), X is C—R⁷, and R⁷ is a substituted or unsubstituted aryl group, or a substituted or unsubstituted heteroaryl group. Among them, R⁷ is preferably a substituted or unsubstituted phenyl group, because reduction in light stability due to excessively increased twisting of the carbon-carbon bond can be suppressed.

Furthermore, when R⁷ in the general formula (2) is a group having a structure of the following general formula (5), R⁷ becomes appropriately bulky, thereby preventing the reduction of the fluorescence quantum yield due to concentration quenching, etc. In addition, the reactivity around the carbon atom to which R⁷ is bonded can be reduced, thereby improving light stability. For this reason, the structure of the general formula (5) is particularly preferred as the structure of R⁷ in the general formula (2).

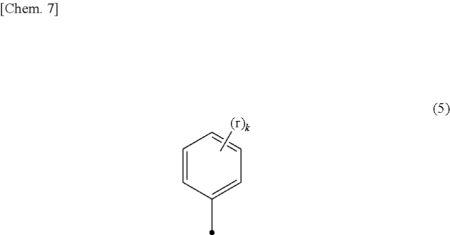

In the general formula (5), r is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an aryl ether group, an aryl thioether group, an aryl group, a heteroaryl group, halogen, a cyano group, an aldehyde group, a carbonyl group, a carboxyl group, an oxycarbonyl group, an ester group, a carbamoyl group, an amide group, an amino group, an imino group, a nitro group, a silyl group, a siloxanyl group, a boryl group, and a phosphine oxide group. k is an integer of 1 to 3. When k is 2 or more, r may be the same as or different from one another.

From the viewpoint of being appropriately bulky and further preventing reduction of the fluorescence quantum yield, r in the general formula (5) is preferably a substituted or unsubstituted aryl group or a substituted or unsubstituted heteroaryl group, more preferably a substituted or unsubstituted aryl group. Especially among the aryl groups, a phenyl group and a naphthyl group are particularly preferred. When these aryl groups are substituted, examples of the substituent includes an alkyl group, a heterocyclic group, an alkenyl group, a hydroxyl group, an alkoxy group, an aryl ether group, an aryl group, a heteroaryl group, halogen, a cyano group, a carboxyl group, and an ester group, which groups may be further substituted. In the case where r is an aryl group in the general formula (5), k in the general formula (5) is preferably 1 or 2, and more preferably 2.

In addition, from the viewpoint of controlling the fluorescence wavelength or absorption wavelength or increasing the compatibility with a solvent, r in the general formula (3) is preferably a substituted or unsubstituted alkyl group, a substituted or unsubstituted alkoxy group, or halogen. Among them, from the viewpoint of dispersibility, a tert-butyl group or a methoxy group is particularly preferred as the r.

From the viewpoint of preventing aggregation of luminescent materials due to thermal diffusion, etc., and the accompanying reduction of the quantum yield, at least one of R¹ to R⁷ in the general formula (2) is preferably an appropriately bulky substituent. Among them, at least one of R², R⁵, and R⁷ is more preferably an appropriately bulky substituent, and all R², R⁵, and R⁷ particularly preferably are appropriately bulky substituents.

Examples of the appropriately bulky substituents of R² and R⁵ include substituted or unsubstituted alkyl groups, substituted or unsubstituted cycloalkyl groups, substituted or unsubstituted aryl groups, and substituted or unsubstituted ester groups. As the bulky substituents described above, substituted or unsubstituted ester groups are more preferred, substituted or unsubstituted aryl ester groups are even more preferred, and substituted or unsubstituted phenyl ester groups are especially preferred. Among them, a phenyl ester group substituted with an aryl group is preferable as the bulky substituent described above.

Examples of the appropriately bulky substituent of R⁷ include substituted or unsubstituted aryl groups and substituted or unsubstituted heteroaryl groups. Among them, substituted or unsubstituted phenyl groups are more preferable, and a group of the above general formula (5) is particularly preferable.

In another aspect of the compound of the general formula (2), at least one of R¹ to R⁷ is preferably an electron withdrawing group. In particular, it is preferred that (1) at least one of R¹ to R⁶ is an electron withdrawing group, (2) R⁷ is an electron withdrawing group, or (3) at least one of R¹ to R⁶ is an electron withdrawing group and R⁷ is an electron withdrawing group. Introduction of an electron withdrawing group into a compound of the general formula (2) makes it possible to greatly decrease the electron density of the central skeleton. Therefore, the stability of that compound against oxygen is further improved. As a result, durability of the luminescent material containing that compound can be further improved.

The electron withdrawing group, otherwise called an electron-accepting group, is, in the electronic theory of organic chemistry, an atomic group that draws electrons by an induction effect or a resonance effect from an atomic group on which the group is substituted. The electron withdrawing group includes a group in which the value of a substituent constant (σp (para)) of Hammett's rule is positive. The substituent constant (σp (para)) of Hammett's rule can be quoted from KAGAKU BINRAN (Chemical Handbook), Basic Edition, 5th rev., (page: II-380). A phenyl group takes a positive value in some examples as described above, but a phenyl group is not encompassed by the electron withdrawing group in the present invention.

Examples of the electron withdrawing group include-F (σp: +0.20), —Cl (σp: +0.28), —Br (σp: +0.30), —I (σp: +0.30), —CO₂R¹² (σp: +0.45 when R¹² is an ethyl group), —CONH₂ (σp: +0.38), —COR¹² (σp: +0.49 when R¹² is a methyl group), —CF₃ (σp: +0.51), —SO₂R¹² (σp: +0.69 when R¹² is a methyl group), and —NO₂ (σp: +0.81). Each R¹² independently represents a hydrogen atom, a substituted or unsubstituted aromatic hydrocarbon group having a ring-forming carbon number of 6 to 30, a substituted or unsubstituted heterocyclic group having a ring-forming carbon number of 5 to 30, a substituted or unsubstituted alkyl group having a carbon number of 1 to 30, or a substituted or unsubstituted cycloalkyl group having a carbon number of 1 to 30. Specific examples of each of these groups are the same as those described above.

The electron withdrawing group is preferably fluorine, a fluorine-containing aryl group, a fluorine-containing heteroaryl group, a fluorine-containing alkyl group, a substituted or unsubstituted acyl group, a substituted or unsubstituted ester group, a substituted or unsubstituted amide group, a substituted or unsubstituted sulfonyl group, or a cyano group, because they are unlikely to be decomposed chemically.

The electron withdrawing group is more preferably a fluorine-containing alkyl group, a substituted or unsubstituted acyl group, a substituted or unsubstituted ester group, or a cyano group, because they prevent concentration quenching, which leads to an effect of enhancing the emission quantum yield. Particularly preferable electron withdrawing groups are substituted or unsubstituted ester groups.

As another embodiment of the compound of the general formula (2), at least one of the four pairs of structures: R¹ and R², R² and R³, R⁴ and R⁵, and R⁵ and R⁶, is preferably a ring structure of any one of the following general formulae (6A) to (6D). Each ring structure of each of the general formulae (6A) to (6D) has a double bond. Therefore, any of the ring structures is introduced into the above compound, so that the conjugation can be extended and the light emission can have longer wavelength. Furthermore, the ring structure introduced into the above compound allows the double bond site to be fixed to the central skeleton by a chemical bond, thereby making it possible to suppress excessive structural relaxation in the excited state and to obtain light emission with good color purity.

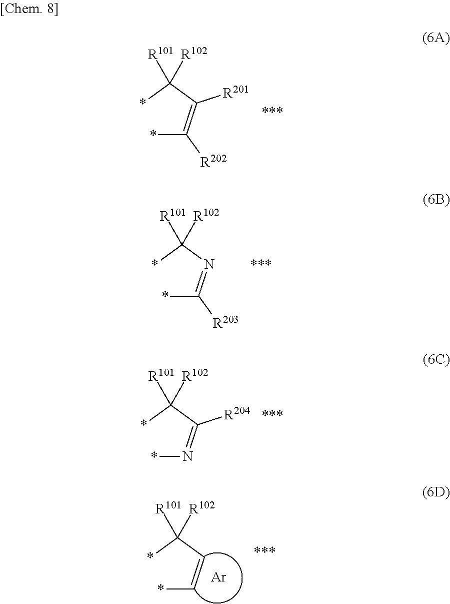

In the general formulae (6A) to (6D), each of R¹⁰¹, R¹⁰², and R²⁰¹ to R²⁰⁴ has the same meaning as R¹ to R⁷ in the general formula (2) mentioned above. Ar is a substituted or unsubstituted aromatic hydrocarbon ring, or a substituted or unsubstituted aromatic heterocycle. In each ring structure of each of the general formulae (6A) to (6D), R¹⁰¹ and R¹⁰² may form a ring. In each ring structure of each of the general formulae (6A) to (6D), the symbol * indicates a connection with the pyrromethene skeleton.

For example, in the compound of the general formula (2), it is preferable that one of the two pairs of structures: R¹ and R², and R² and R³, is a ring structure of any one of the general formulae (6A) to (6D), and the structures of R⁴, R⁵, and R⁶ are not ring structures formed between adjacent groups. Particularly, when the structure of R² and R³ is a ring structure of the general formula (6D) and R⁷ is an aryl group, the aryl group is more preferably selected from a substituted or unsubstituted phenyl group, or an aryl group having a structure in which two or more rings are fused.

As another embodiment of the compound of the general formula (2), it is preferable that one of the two pairs of structures: R¹ and R², and R² and R³, is a ring structure of any one of the general formulae (6A) to (6D), and one of the two pairs of structures: R⁴ and R⁵, R⁵ and R⁶, is a ring structure of any one of the general formulae (6A) to (6D). Particularly, when both pairs: R² and R³, and R⁵ and R⁶, have a ring structure of the general formula (6D), and R⁷ is an aryl group, the aryl group is more preferably selected from a substituted or unsubstituted phenyl group, or an aryl group having a structure in which two or more rings are fused.

In the ring structure of the general formula (6D), Ar is preferably a substituted or unsubstituted benzene ring, a substituted or unsubstituted naphthalene ring, a substituted or unsubstituted phenanthrene ring, a substituted or unsubstituted pyridine ring, a substituted or unsubstituted pyrimidine ring, or a substituted or unsubstituted pyrazine ring. Further, when Ar is a substituted or unsubstituted benzene ring, thermal stability and photochemical stability are improved. For this reason, a substituted or unsubstituted benzene ring is preferable as Ar in the general formula (6D).

In the general formulae (6A) to (6D), when each of R¹⁰¹ and R¹⁰² is a substituted or unsubstituted alkyl group, a substituted or unsubstituted aryl group, or a substituted or unsubstituted heteroaryl group, the compound of the general formula (2) exhibits better thermal stability and light stability, which is preferable. In particular, when each of R¹⁰¹ and R¹⁰² is a substituted or unsubstituted alkyl group or a substituted or unsubstituted aryl group, the fluorescence quantum yield becomes higher. Therefore, it is preferable that each of R¹⁰¹ and R¹⁰² is a substituted or unsubstituted alkyl group or a substituted or unsubstituted aryl group. Specific examples of the preferable substituent include an alkyl groups such as a methyl group, an ethyl group, an isopropyl group, and a tert-butyl group, and an aryl group such as phenyl group. Among them, from the viewpoints of ease of synthesis and dispersibility, a methyl group and a phenyl group are particularly preferred. When these groups are the substituents, quenching due to aggregation between molecules is suppressed.

In the general formulae (6A) to (6D), R¹⁰¹ and R¹⁰² may form a ring. When R¹⁰¹ and R¹⁰² form a ring, structural relaxation can be suppressed, and sharp emission can be obtained. In addition, thermal vibration of the entire molecule is suppressed, improving thermal stability. A preferred example of the case where R¹⁰¹ and R¹⁰² form a ring is a case where they form a spirofluorene ring. Specifically, a preferred example is a structure in which R¹⁰¹ and R¹⁰² are both benzene rings and form a ring.

In one of the preferred examples of the compound of the general formula (2), each of R¹, R³, R⁴, and R⁶ may be the same as or different from one another, and all of them are substituted or unsubstituted phenyl groups, X is C—R⁷, and R⁷ is a substituted or unsubstituted phenyl group. In this case, at least one of R¹, R³, R⁴, R⁶, and R⁷ is more preferably a phenyl group substituted with a methoxy group.

In another one of the preferred examples of the compound of the general formula (2), each of R¹, R³, R⁴, and R⁶ may be the same as or different from one another, and all of them are substituted or unsubstituted alkyl groups, X is C—R⁷, and R⁷ is a substituted or unsubstituted phenyl group. In this case, each of R² and R⁵, which may be the same as or different from each other, is more preferably a substituted or unsubstituted ester group, still more preferably a substituted or unsubstituted aryl ester group.

Still another one of the preferred examples of the compound of the general formula (2) is a case where the structure of each of R² and R³ is a ring structure of the general formula (6D), Ar in the general formula (6D) is a substituted or unsubstituted benzene ring, each of R¹⁰¹ and R¹⁰² in the general formula (6D), which may be the same as or different from each other, is a substituted or unsubstituted alkyl group or a substituted or unsubstituted phenyl group, and R⁷ in the general formula (2) is a substituted or unsubstituted phenyl group. In this case, each of R⁴ and R⁶, which may be the same as or different from each other, is more preferably a substituted or unsubstituted phenyl group. It is also preferable that R¹⁰¹ and R¹⁰² in the general formula (6D) form a ring.

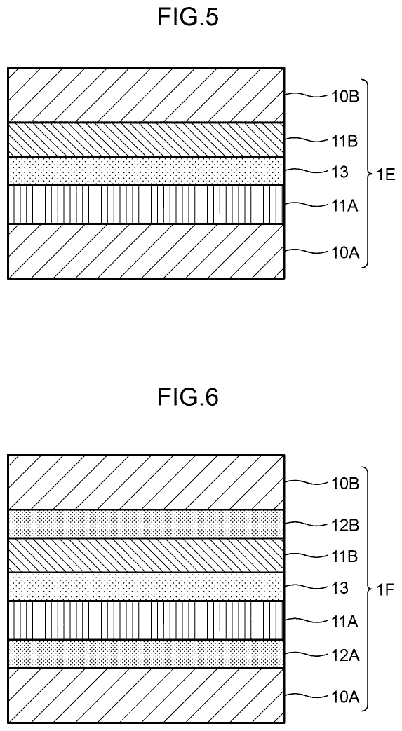

As the luminescent material used in the color conversion composition of the present invention, a luminescent material that emits delayed fluorescence can also suitably be used. Here, the luminescent material that emits delayed fluorescence is described on pages 87 to 103 of “State-of-the-Art Organic Light-Emitting Diodes” (edited by Adachi Chihaya and Fujimoto Hiroshi, published by CMC Publishing Co. Ltd.). The literature illustrates that by bringing the energy levels of the singlet excited and triplet excited states of a luminescent material into close proximity, the reverse energy transfer from the triplet excited state to the singlet excited state, which normally has a low transition probability, occurs with high efficiency, resulting in thermally activated delayed fluorescence (TADF). Further, the mechanism of generation of delayed fluorescence is illustrated in FIG. 5 in the literature. The delayed fluorescence emission can be determined by transient photo luminescence (PL) measurement.

It has also been reported that the reverse energy transfer from the triplet excited state to the singlet excited state can be accelerated by matching the energy levels of the singlet excited state and triplet excited state of an luminescent material (Nature Photonics volume 14, pages 643-649 (2020)). In addition, compounds with the energy level of the triplet excited state higher than that of the singlet excited state of luminescent materials have been eagerly studied.

In the present specification, luminescent materials that emit fluorescence through a highly efficient transition from the triplet excited state to the singlet excited state, including luminescent materials that emit thermally activated delayed fluorescence, are expressed as “luminescent materials that emit delayed fluorescence”. Hereinafter, the “luminescent materials that emit delayed fluorescence” may be abbreviated as “delayed fluorescent material”.

In general, fluorescence is emitted from the singlet excited state generated after photoexcitation of the luminescent material, and the luminescent material in the triplet excited state generated by intersystem crossing is thermally deactivated under room temperature conditions. Therefore, no fluorescence is emitted from the luminescent material in the triplet excited state. On the other hand, as described above, the luminescent material that emits delayed fluorescence, even after generation of triplet excited state, is rapidly converted to the singlet excited state and then emits fluorescence. Therefore, the triplet excited state, which could not contribute to light emission in usual fluorescent materials, can contribute to fluorescence. Therefore, high-efficiency light emission is obtained.

In addition, the luminescent material in the triplet excited state is highly reactive and long-lived, and therefore easily reacts with surrounding molecules. For example, in the presence of oxygen, oxygen, which has high reactivity and high mobility, receives energy from the luminescent material in the triplet excited state, generating singlet oxygen, which causes oxidative deterioration of the luminescent material. On the other hand, in the absence of oxygen, the molecules surrounding the luminescent material can receive the above energy. That is, even when oxygen is not present and singlet oxygen is not generated, existence of the luminescent material in the triplet excited state, which is highly reactive, for a long time proceeds reaction between the luminescent material and the surrounding molecules, resulting in deterioration of the luminescent material.

However, when the luminescent material in the above-described triplet excited state is a delayed fluorescent material, the delayed fluorescent material in the triplet excited state is rapidly converted to the delayed fluorescent material in the singlet excited state. Therefore, the delayed fluorescent material is less likely to undergo deterioration resulting from a reaction between the delayed fluorescent material in the triplet excited state and the molecules surrounding it, and the delayed fluorescent material can exhibit excellent durability. That is, in order to achieve high durability, it is better for the luminescent material to undergo rapid reverse intersystem crossing from the triplet excited state to the singlet excited state. For example, the rate constant of this reverse intersystem crossing is preferably 1.0×10² s⁻¹ or more.

For a molecular design for bringing the energy levels of the singlet excited and triplet excited states into close proximity, it is effective to combine an electron-donating skeleton and an electron-accepting skeleton in the same molecule. Thus, the highest occupied molecular orbital (HOMO) and the lowest unoccupied molecular orbital (LUMO) can be separated in the molecule. The electron-donating skeleton and the electron-accepting skeleton may be combined directly or via a linking group. In the latter case, the linking group is preferably a skeleton comprising aromatic hydrocarbon.

In the compound containing the partial structure of the general formula (1) mentioned above, the electron-donating nitrogen atom and the electron-accepting boron atom are positioned in close proximity to each other in the molecule. A compound containing such a partial structure is a compound capable of enabling separation between HOMO and LUMO by the multiple resonance effect. In order to clearly separate the HOMO and the LUMO and bring the energy level of the singlet excited state and the energy level of the triplet excited state closer to each other, it is preferable that the luminescent material contains two or more partial structures of the general formula (1) in the molecule.

The compound of the general formula (3) and the compound of the general formula (4) mentioned above are molecules in which an electron-donating atom and an electron-accepting atom are positioned in close proximity to each other in the molecule, and are capable of enabling HOMO-LUMO separation by the multiple resonance effect.

In the general formula (3) and the general formula (4), examples of the substituted or unsubstituted aryl ring having a ring-forming carbon number of 6 to 30 in the ring Za, the ring Zb, and the ring Zc include aromatic hydrocarbon rings such as benzene rings, naphthalene rings, phenanthrene rings, chrysene rings, anthracene rings, and pyrene rings. Among them, benzene rings are preferable from the viewpoint of ensuring the solubility. Examples of the heteroaryl ring having a ring-forming carbon number of 5 to 30 include aromatic heteroaryl ring structures such as pyridine rings, quinoline rings, and phenanthroline rings. Among them, pyridine rings are preferable, from the viewpoint of raw-material availability and difficulty of synthesis.

In the general formula (3) and the general formula (4), the substituent Ra is preferably a group having a carbon number of 6 to 40 including that of the substituent. The substituent Ra is preferably a substituted or unsubstituted aryl group, a substituted or unsubstituted heteroaryl group, or a substituted or unsubstituted alkyl group, more preferably a substituted or unsubstituted aryl group. Examples of the substituted or unsubstituted aryl group include substituted or unsubstituted phenyl groups, substituted or unsubstituted biphenyl groups, substituted or unsubstituted fluorenyl groups, substituted or unsubstituted naphthyl groups, and substituted or phenanthrenyl groups. Among them, substituted or unsubstituted phenyl groups are more preferable.

The above-mentioned delayed fluorescent material is preferable as a luminescent material contained in the color conversion material of the present invention because when its π-conjugation system is extended, reverse intersystem crossing from the triplet excited state to the singlet excited state occurs more efficiently, thereby further improving durability. From such a viewpoint, in the general formula (3), it is preferable that each of Z¹ and Z² is an oxygen atom or NRa, because the π-conjugation system is efficiently extended.

Since the π-conjugation system is efficiently extended as mentioned above, E in the general formula (3) is preferably a boron atom, and E¹ and E² in the general formula (4) are preferably BRa. In the general formula (3) and the general formula (4), it is preferable that the rings Za, Zb, and Zc are preferably benzene rings, because the π-conjugation system is efficiently extended.

The compound of the general formula (3) and the compound of the general formula (4) are molecules, in which an electron-donating nitrogen atom of amine and an electron-accepting boron atom are optimally positioned, enabling HOMO-LUMO separation by the multiple resonance effect, as described in literatures, for example, Adv. Mater., 2016, 28, 2777-2781. In view of clearly separating HOMO from LUMO and bringing the energy level of the singlet excited state and the energy level of the triplet excited state into closer proximity, thereby making it easier to emit delayed fluorescence, it is preferable that in the general formula (3), E is a boron atom having strong electron-accepting properties, and Z¹ and Z² are both NRa which is a group having strong electron-donating properties.

In addition, due to the multiple resonance effect, an emission spectrum shown by each of the compound of the general formula (3) and the compound of the general formula (4) is sharper than those shown by compounds with an electron-donating skeleton and an electron-accepting skeleton combined. Therefore, since the luminescent material contained in the color conversion composition of the present invention is a compound of the general formula (3) or the general formula (4), light emission with high color purity can be obtained. That is, the compounds of the general formula (3) or the general formula (4) are preferred as the luminescent material because they are advantageous for color gamut improvement of displays. Furthermore, the compound of the general formula (3) or the general formula (4) has the rings Za, Zb, and Zc present surrounding the E atom in the general formula (3) or the general formula (4), in which LUMO is mainly localized, and thus the LUMO can be delocalized from the E atom to each ring. By delocalizing the LUMO, the multiple resonance effect works efficiently, resulting in light emission with high color purity. The above E atom is the E atom in the general formula (3), and is each of E¹ and E² atoms in the general formula (4).

Furthermore, in the general formula (3) and the general formula (4), it is more preferable that the substituent Ra forms a structure in which the substituent Ra is bonded to at least one ring of the ring Za, ring Zb, and ring Zc. This is because bonding of the substituent Ra to at least one ring of the ring Za, ring Zb, and ring Zc can be expected to further enhance the effect of sterically protecting E in the general formula (3) and E¹ and E² in the general formula (4) and further improve the effect of preventing reduction of the fluorescence quantum yield.

The following are examples of each of the compound of the general formula (2), the compound of the general formula (3), and the compound of the general formula (4) mentioned above. However, these compounds are not limited to the following compounds.

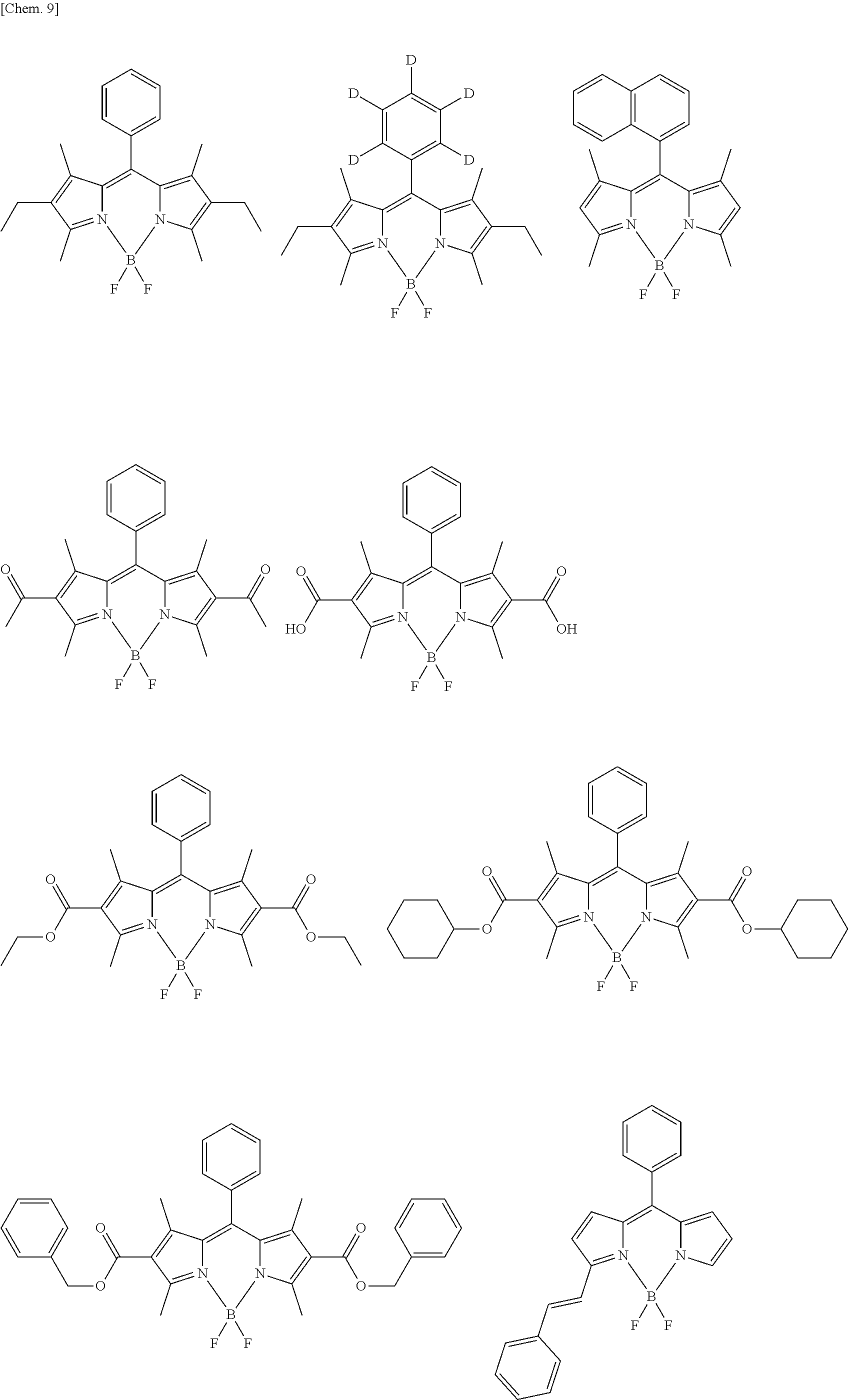

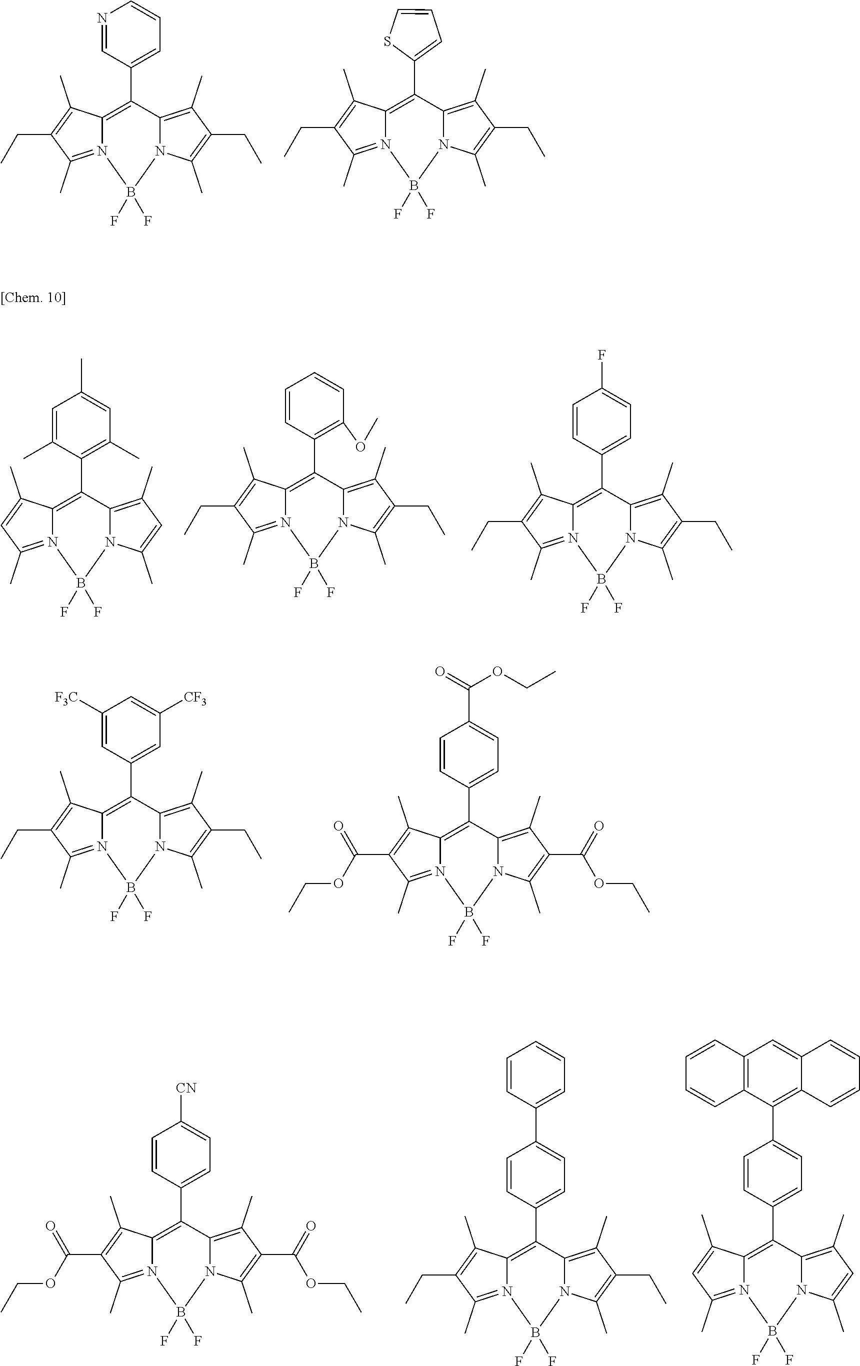

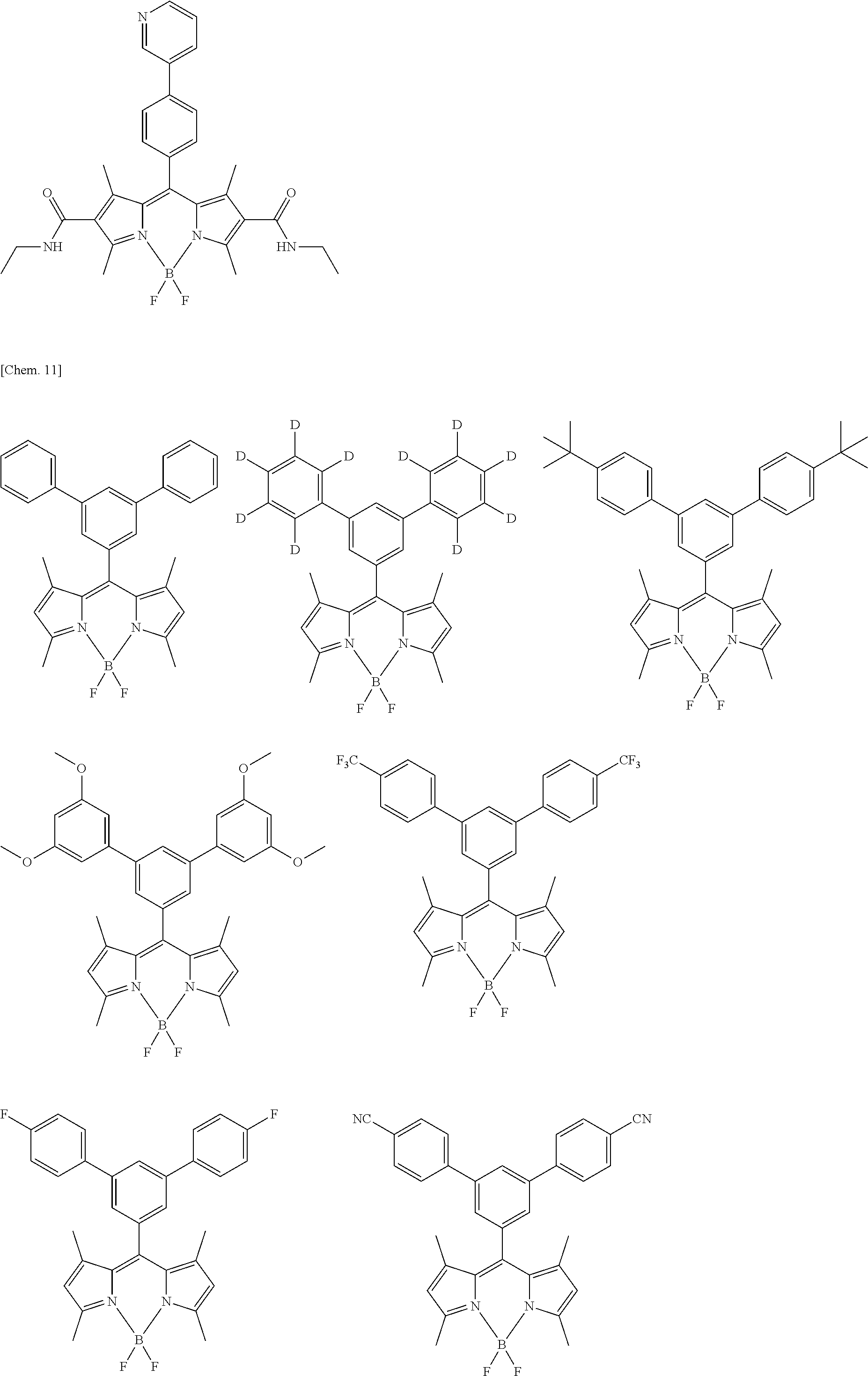

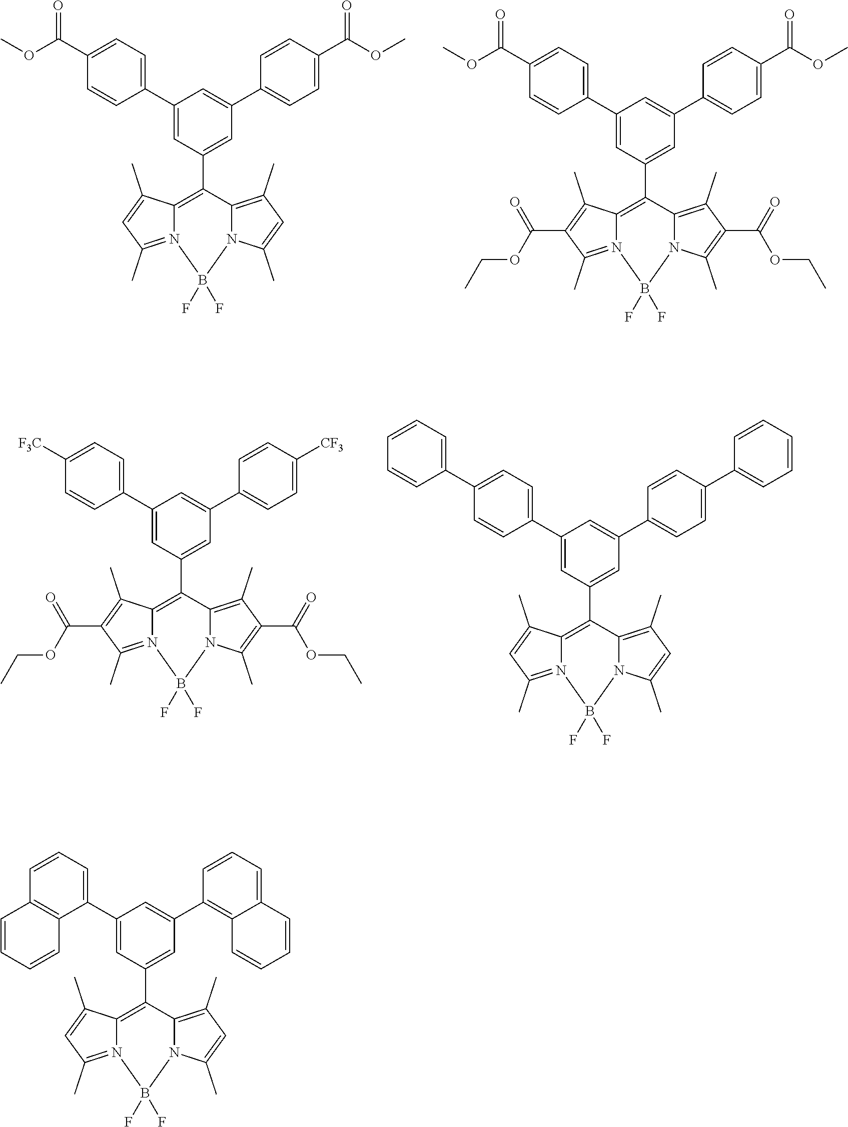

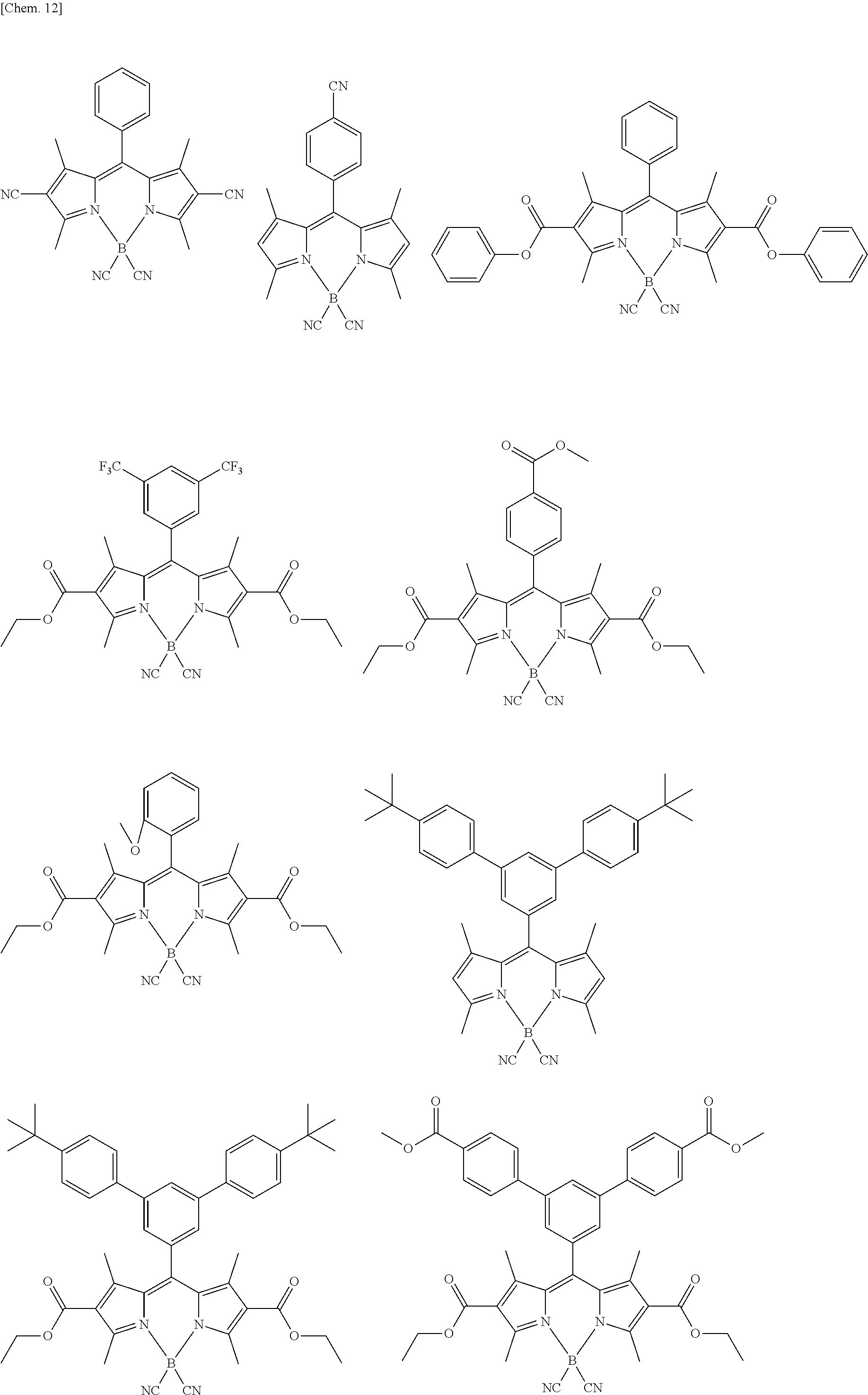

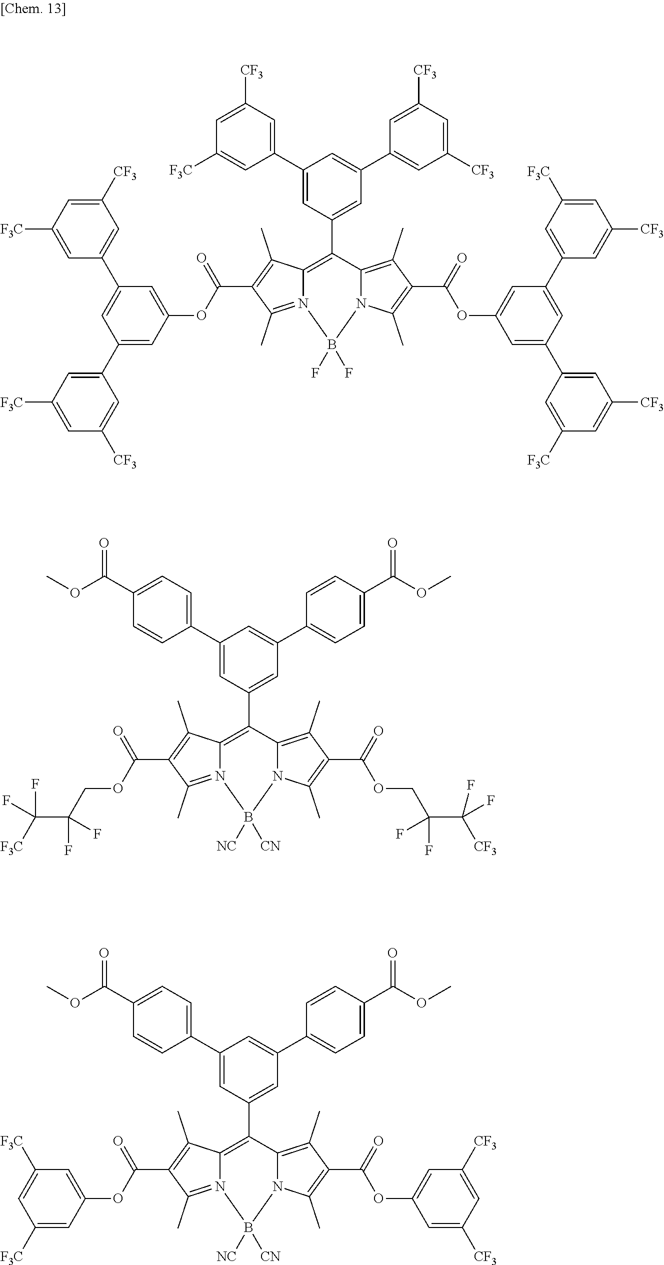

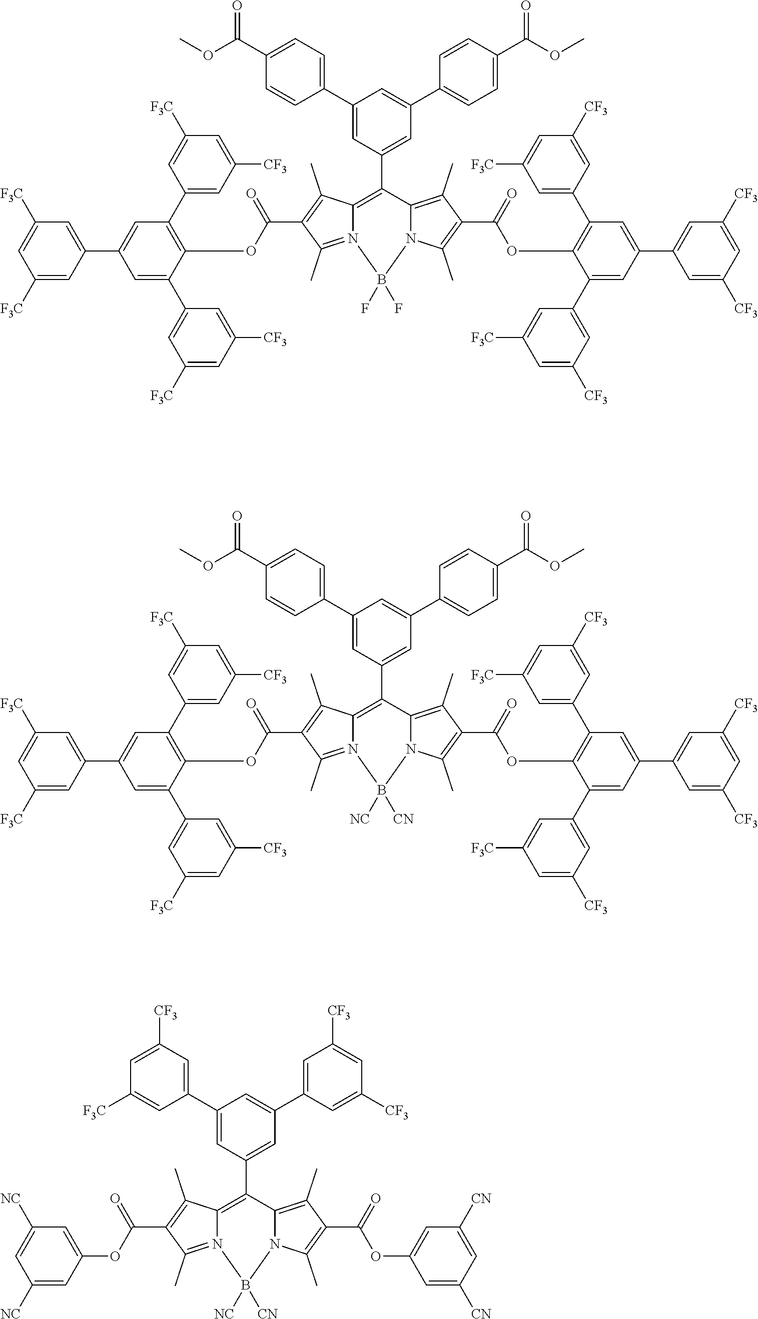

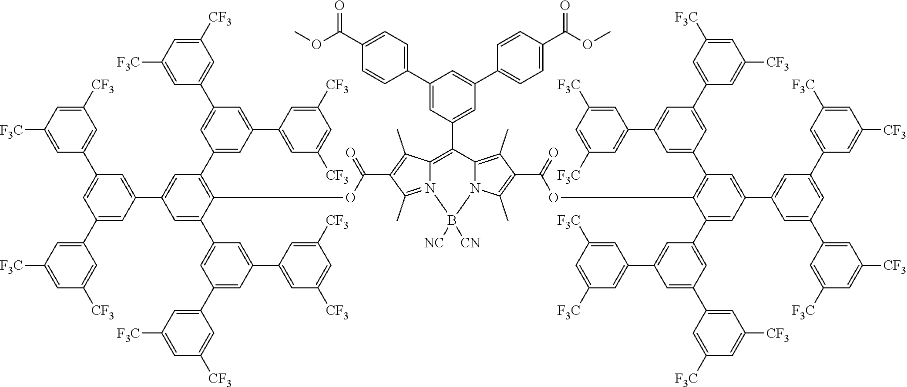

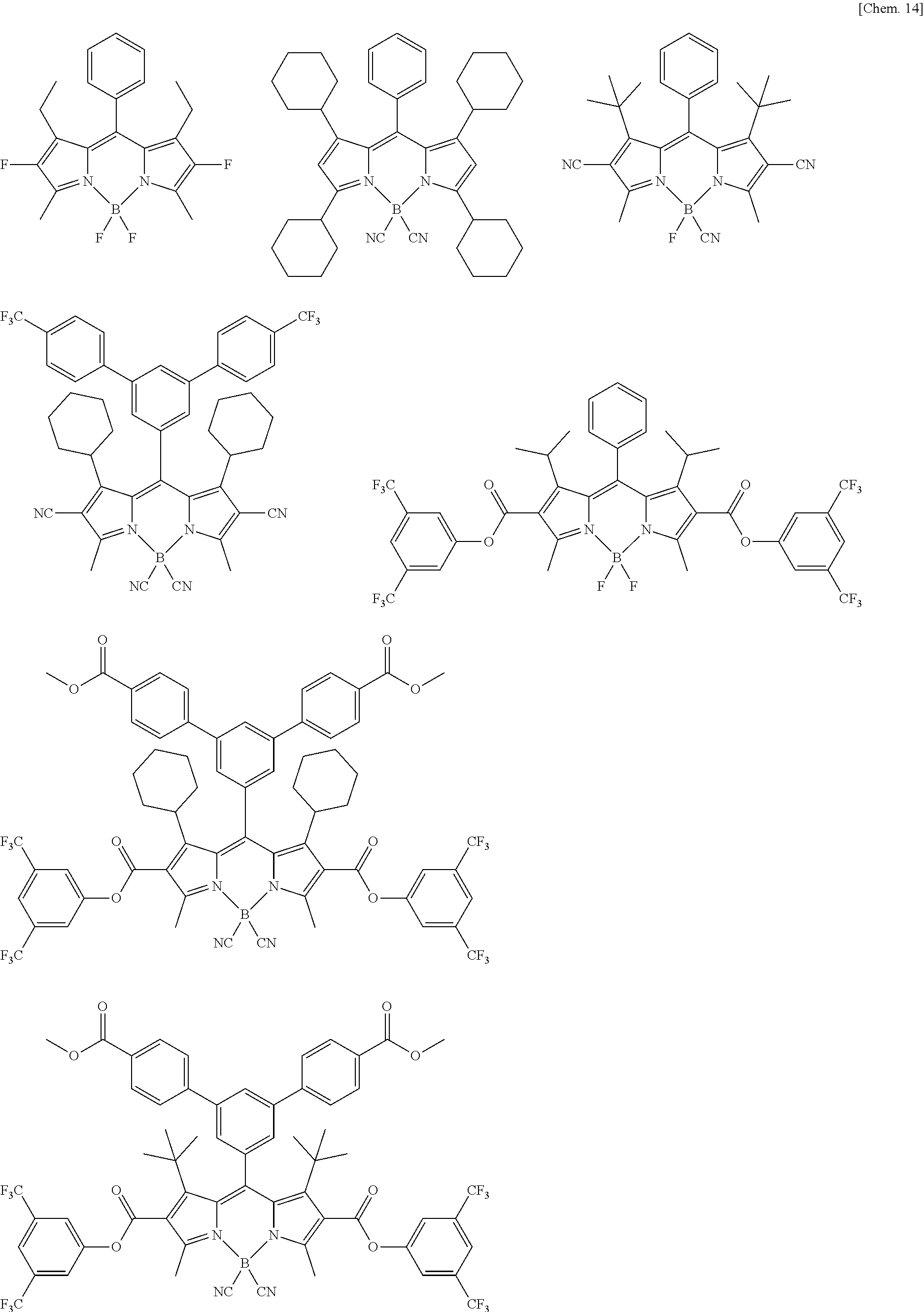

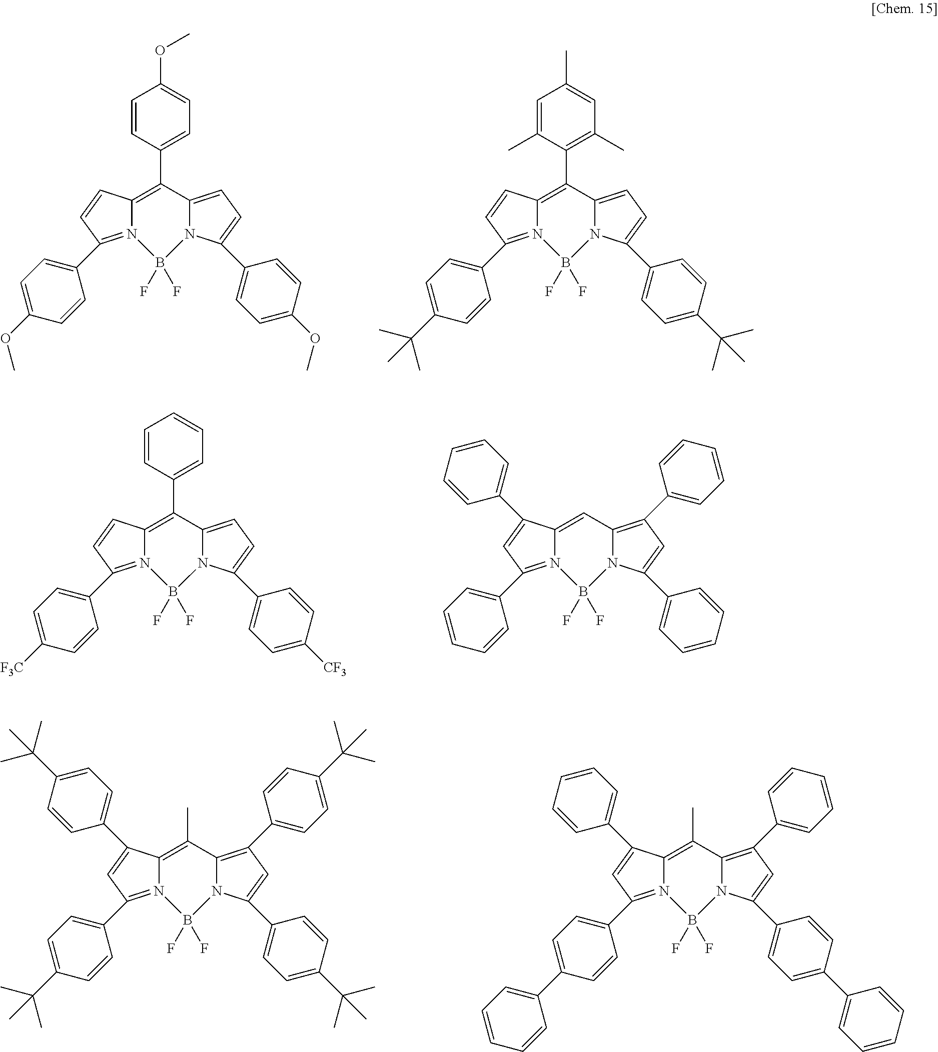

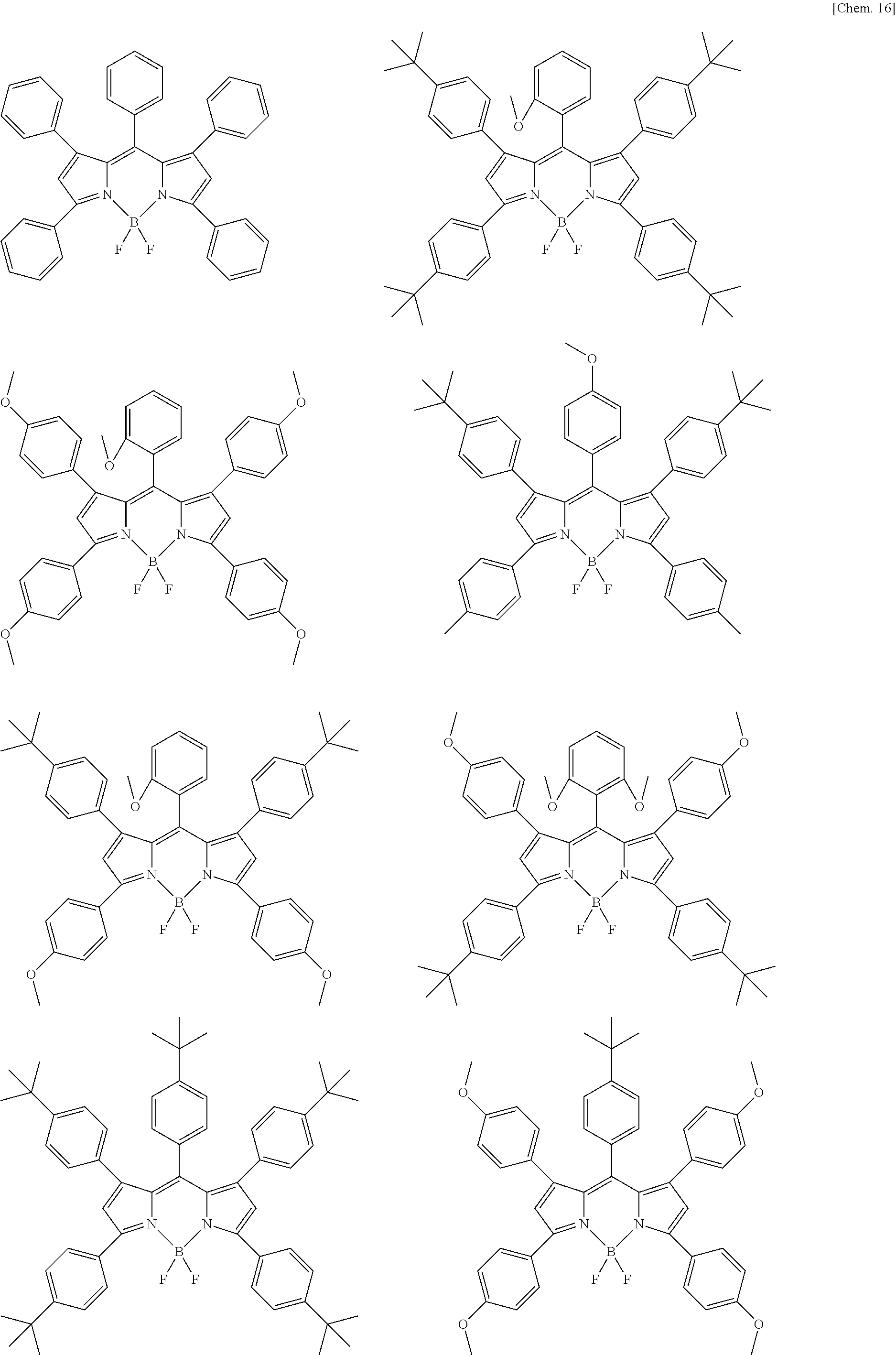

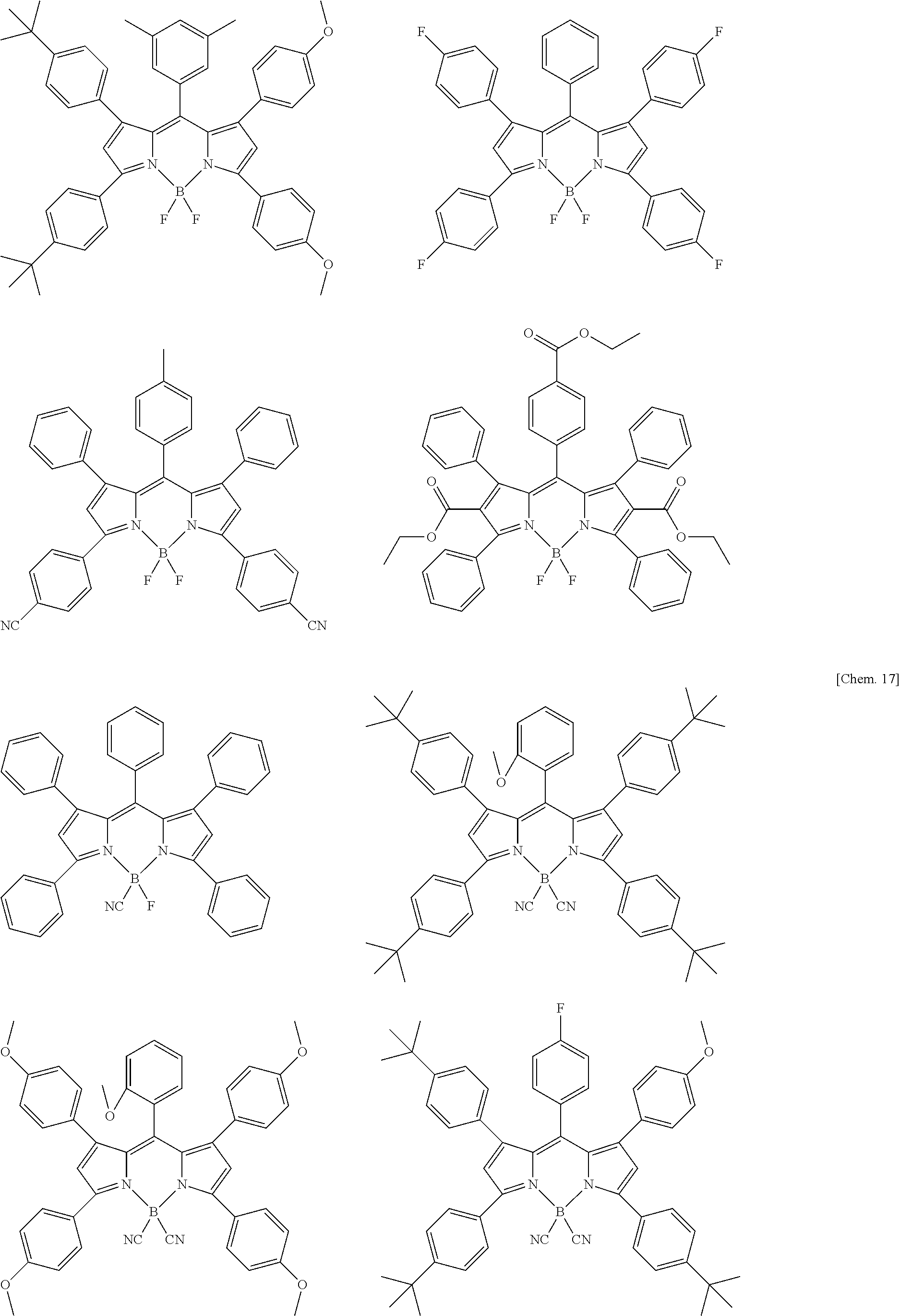

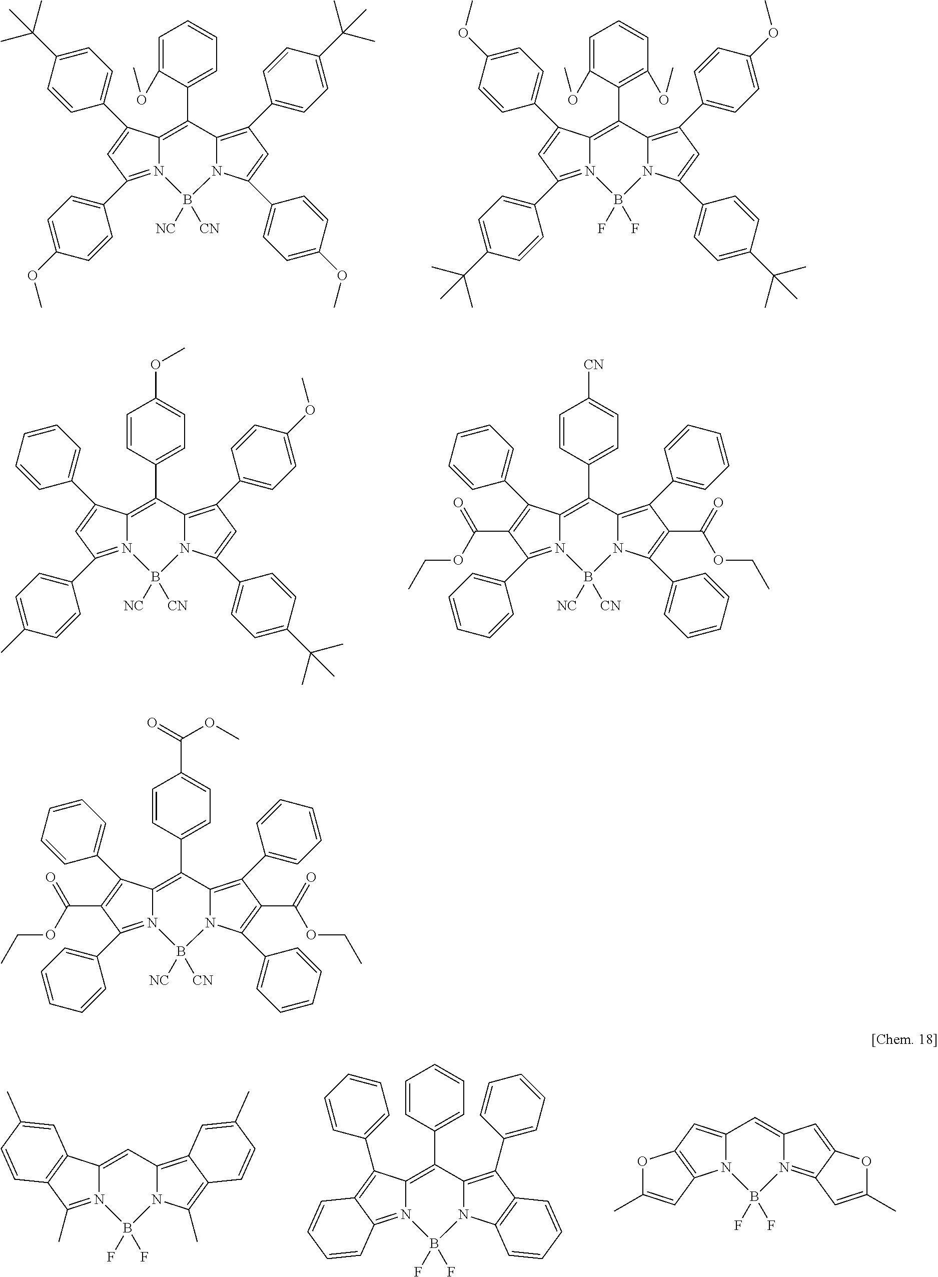

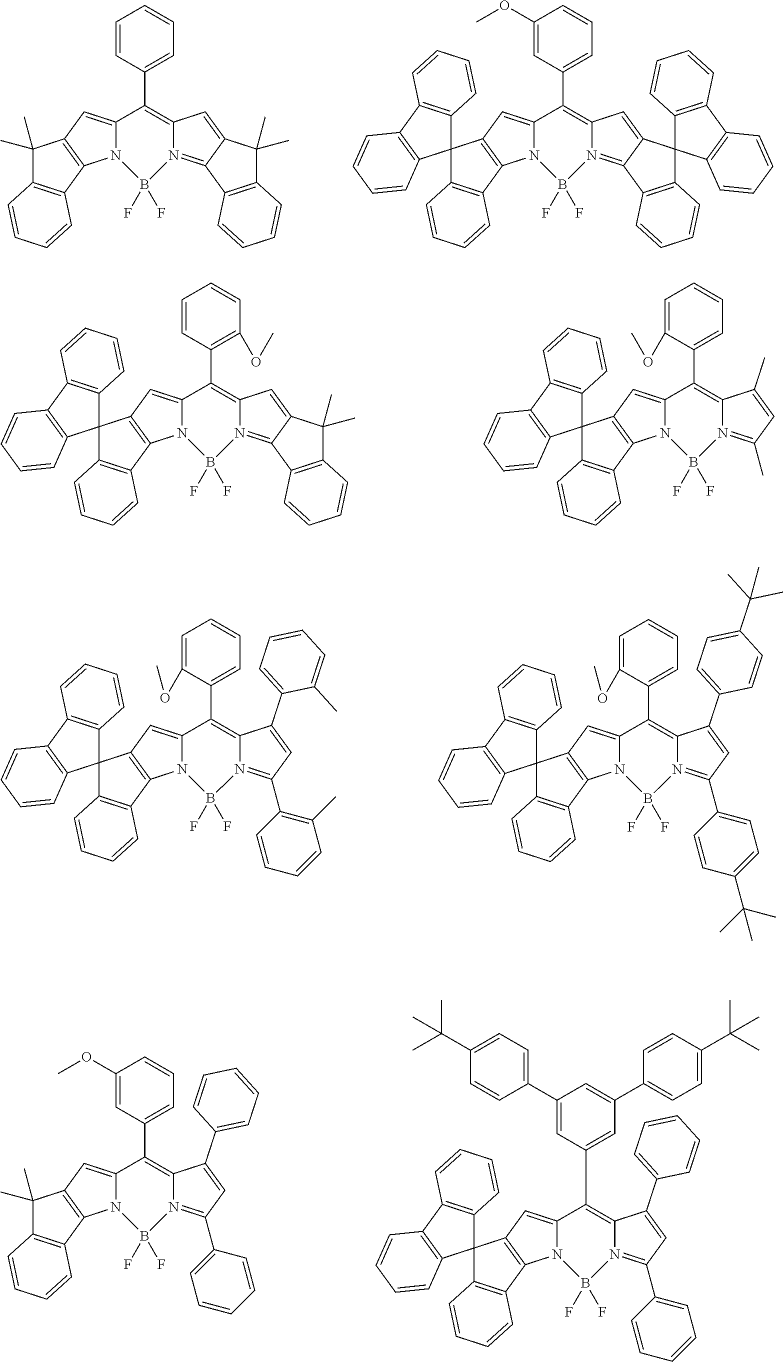

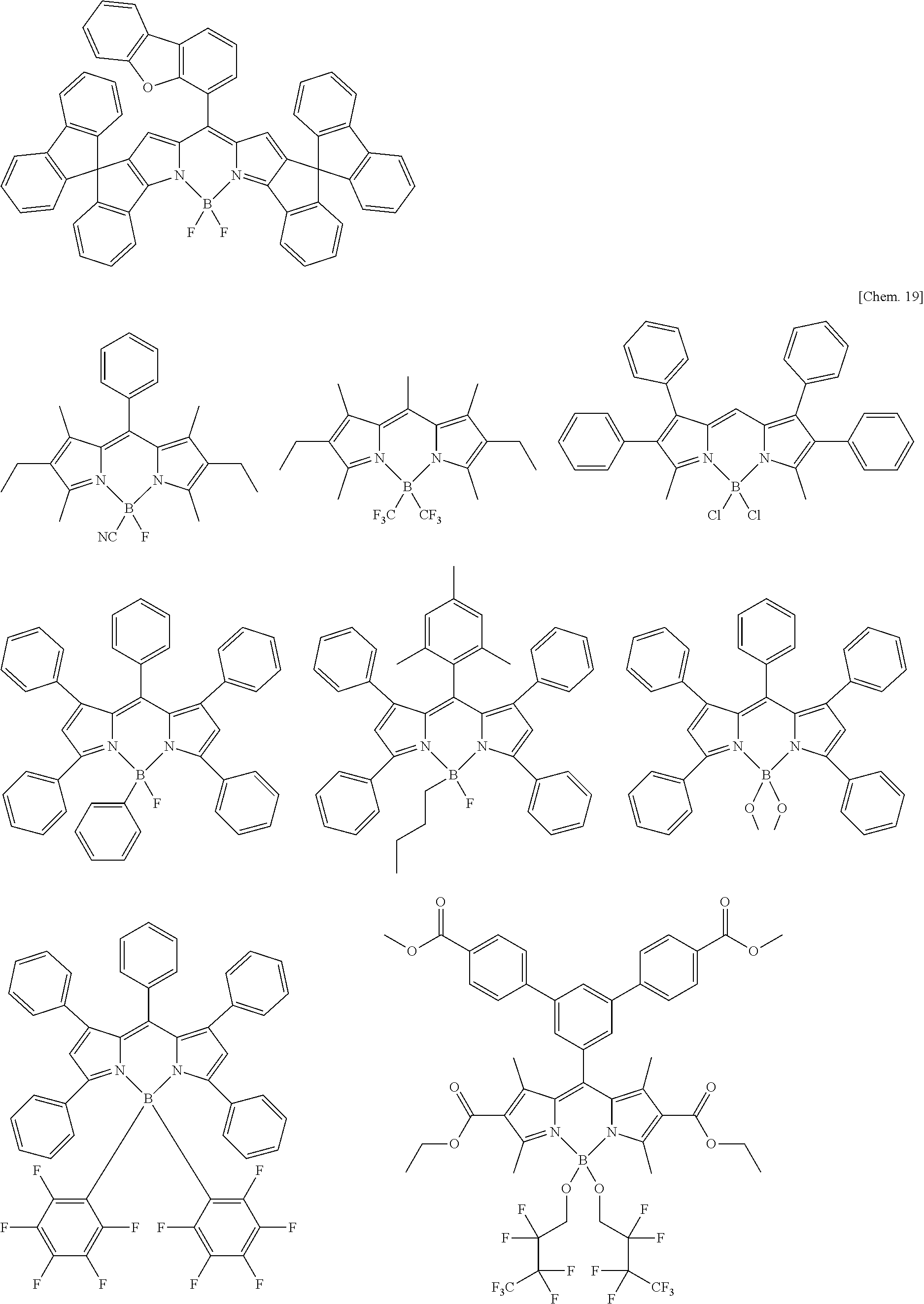

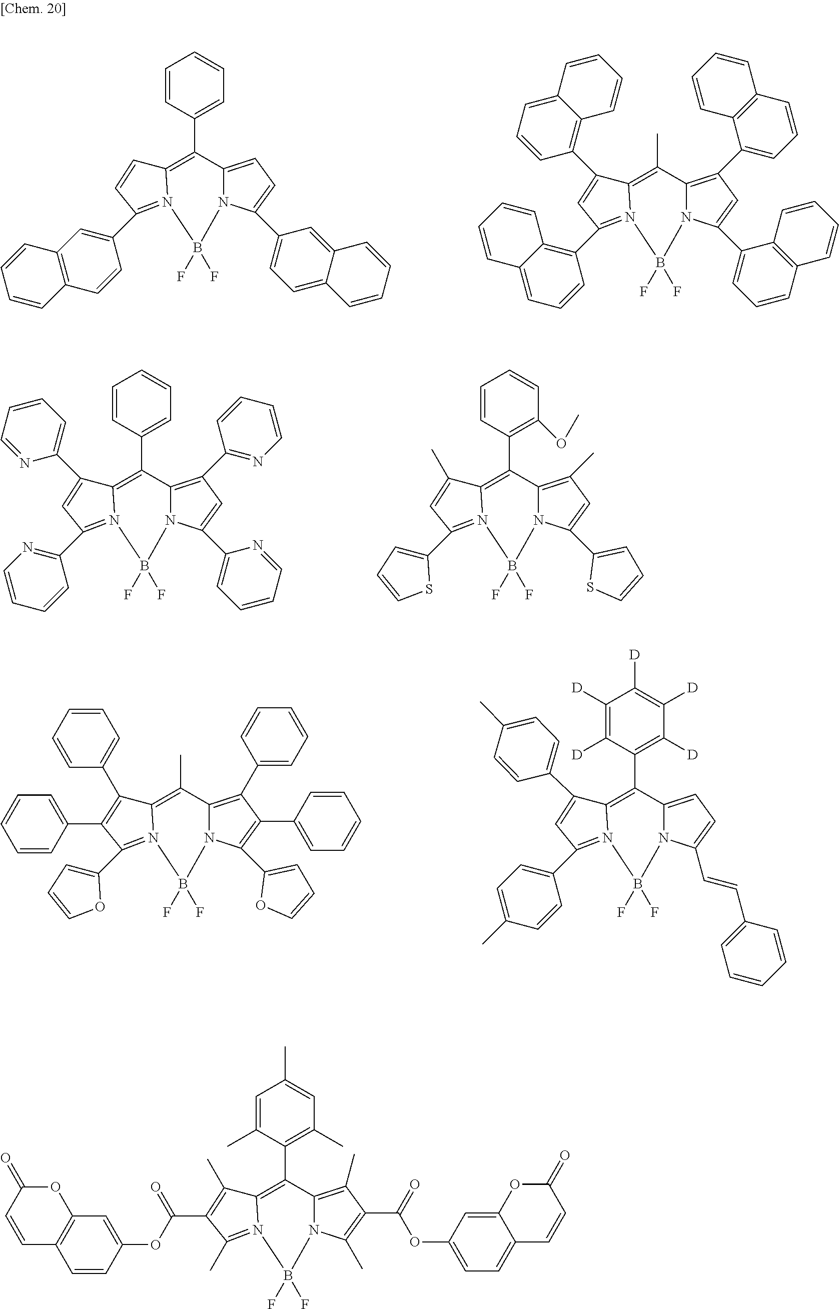

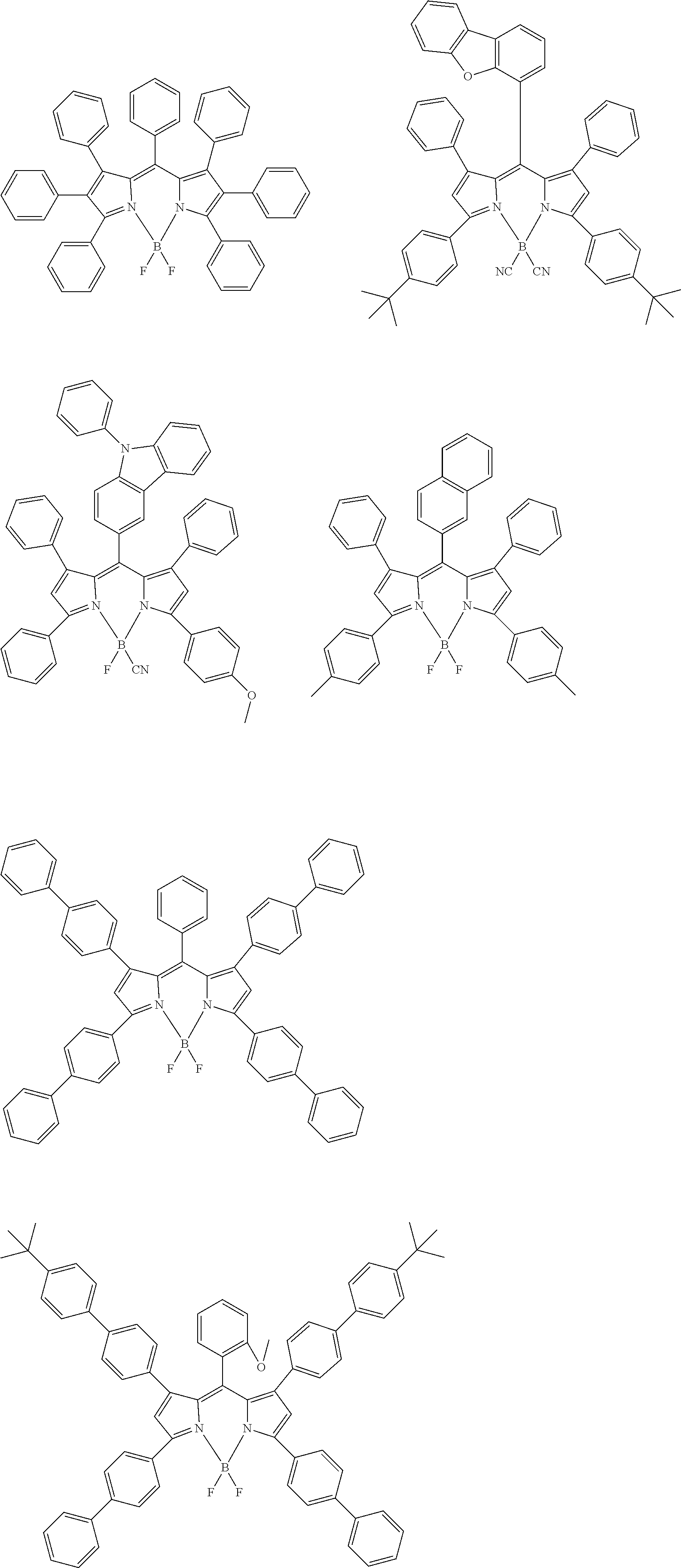

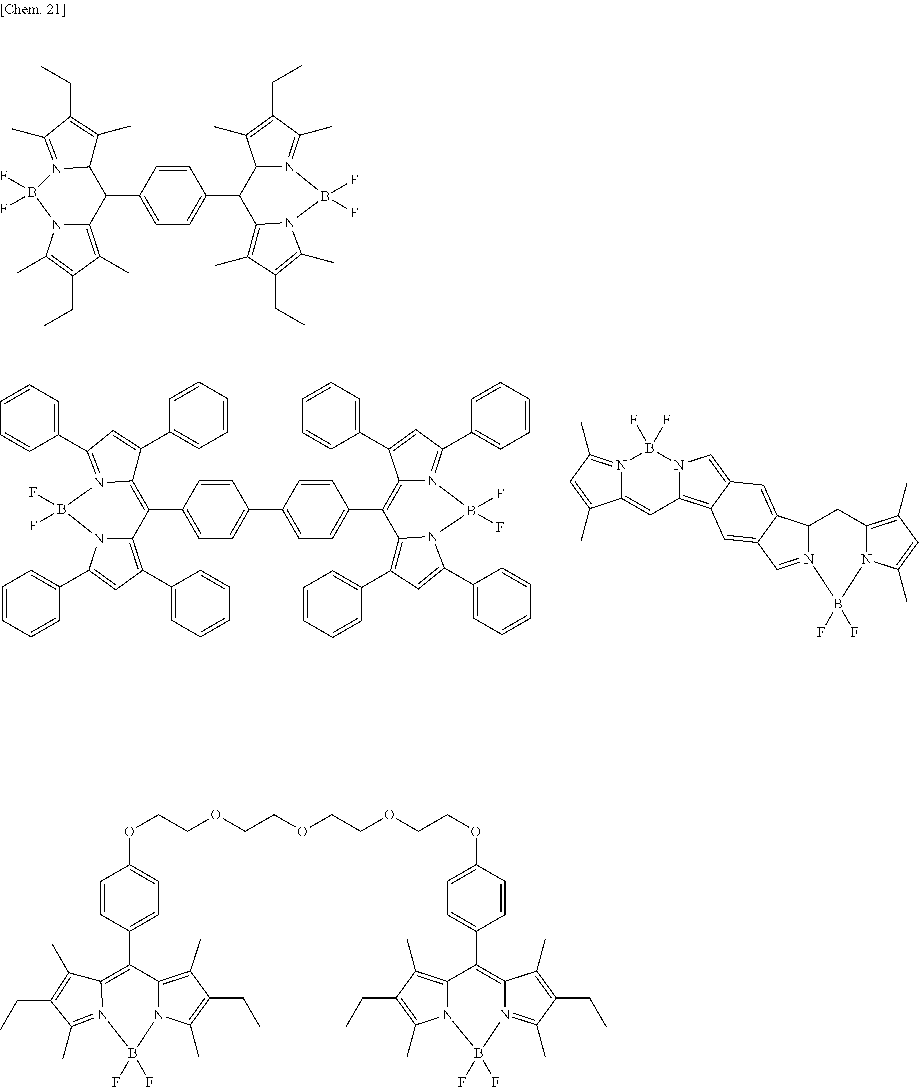

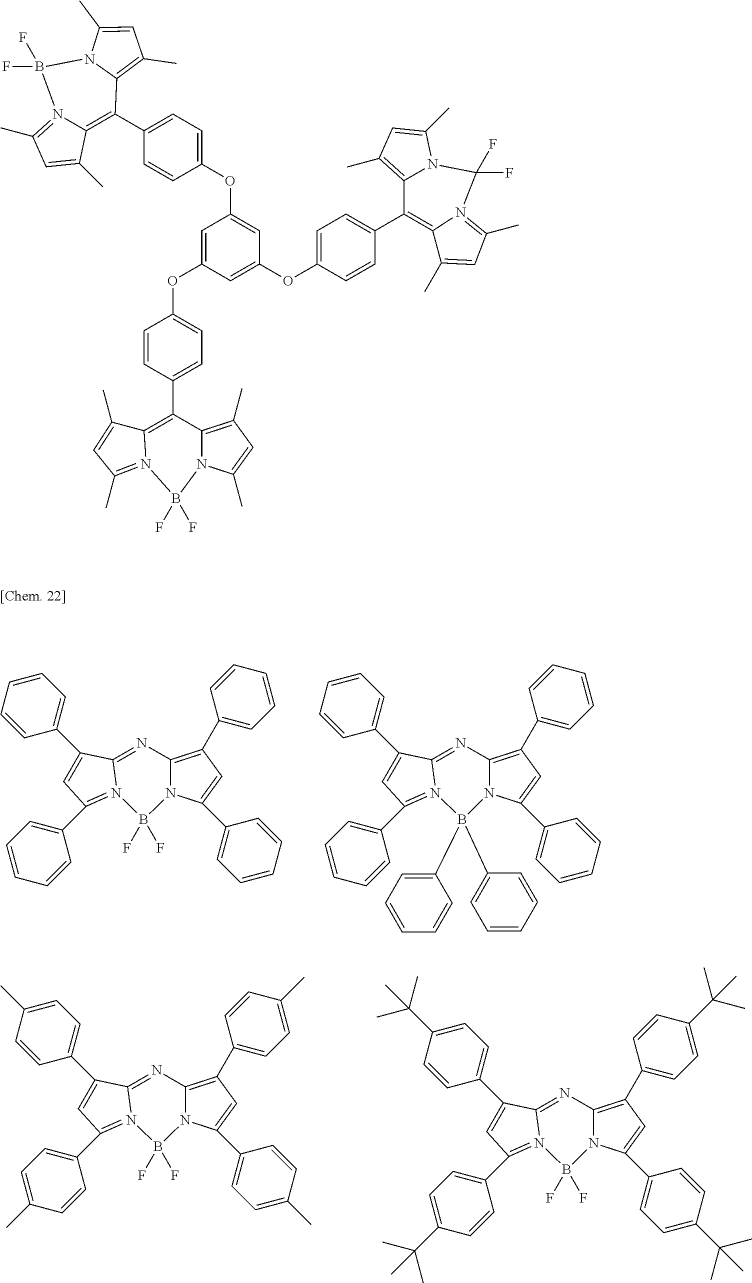

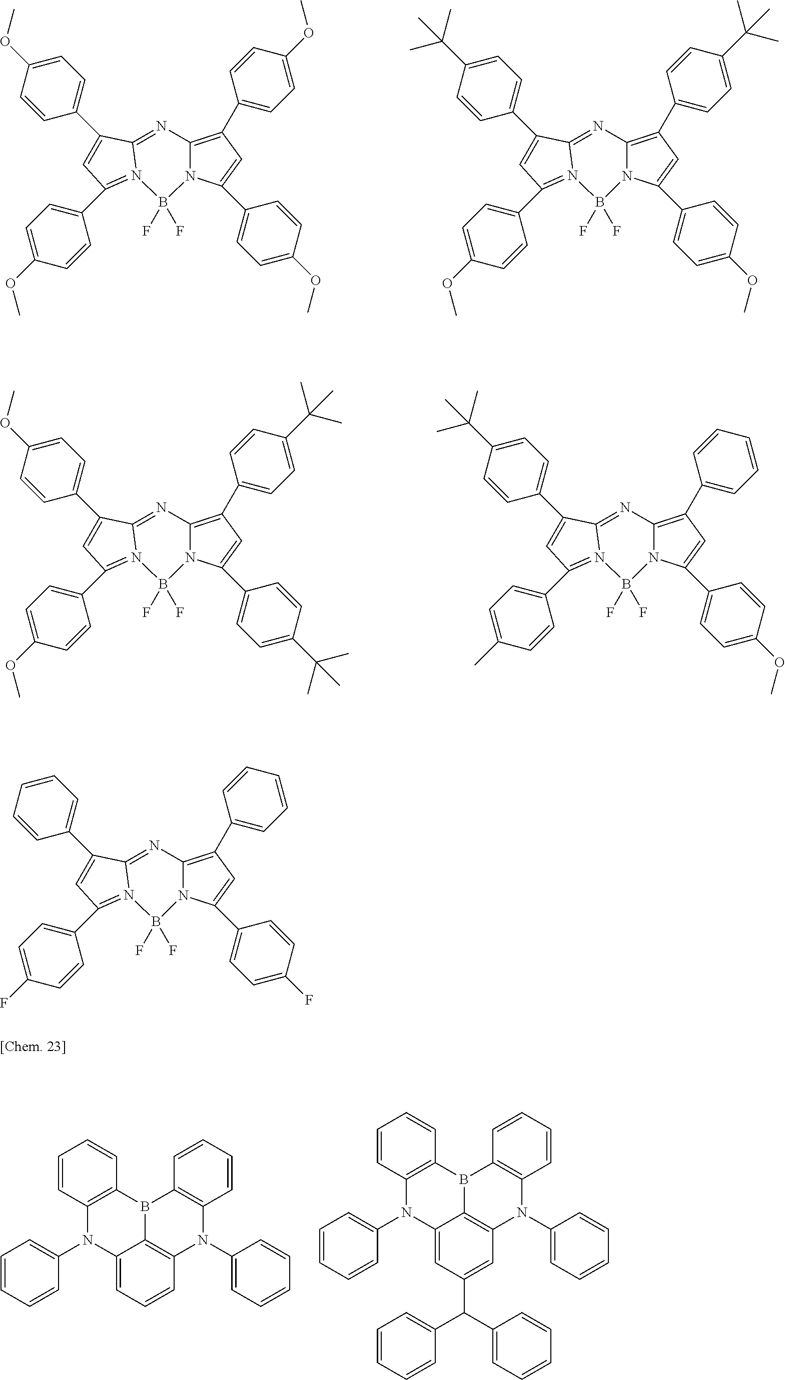

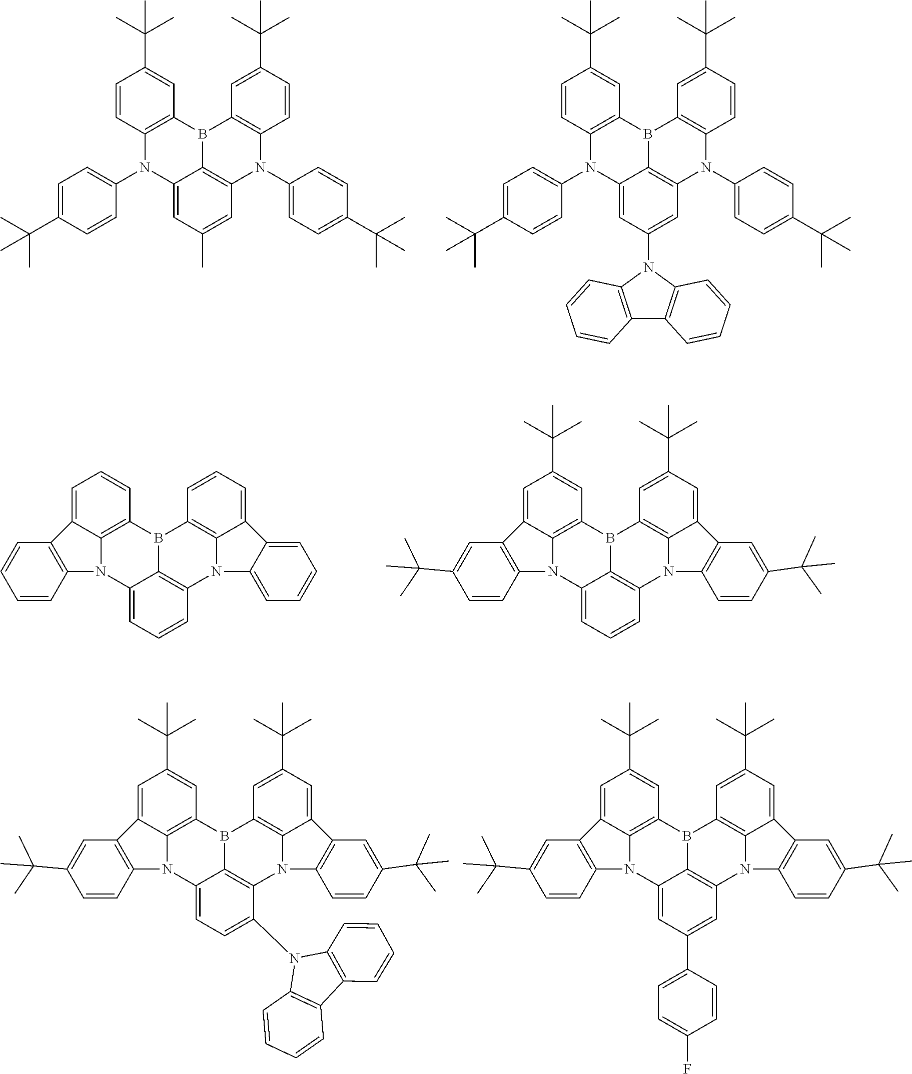

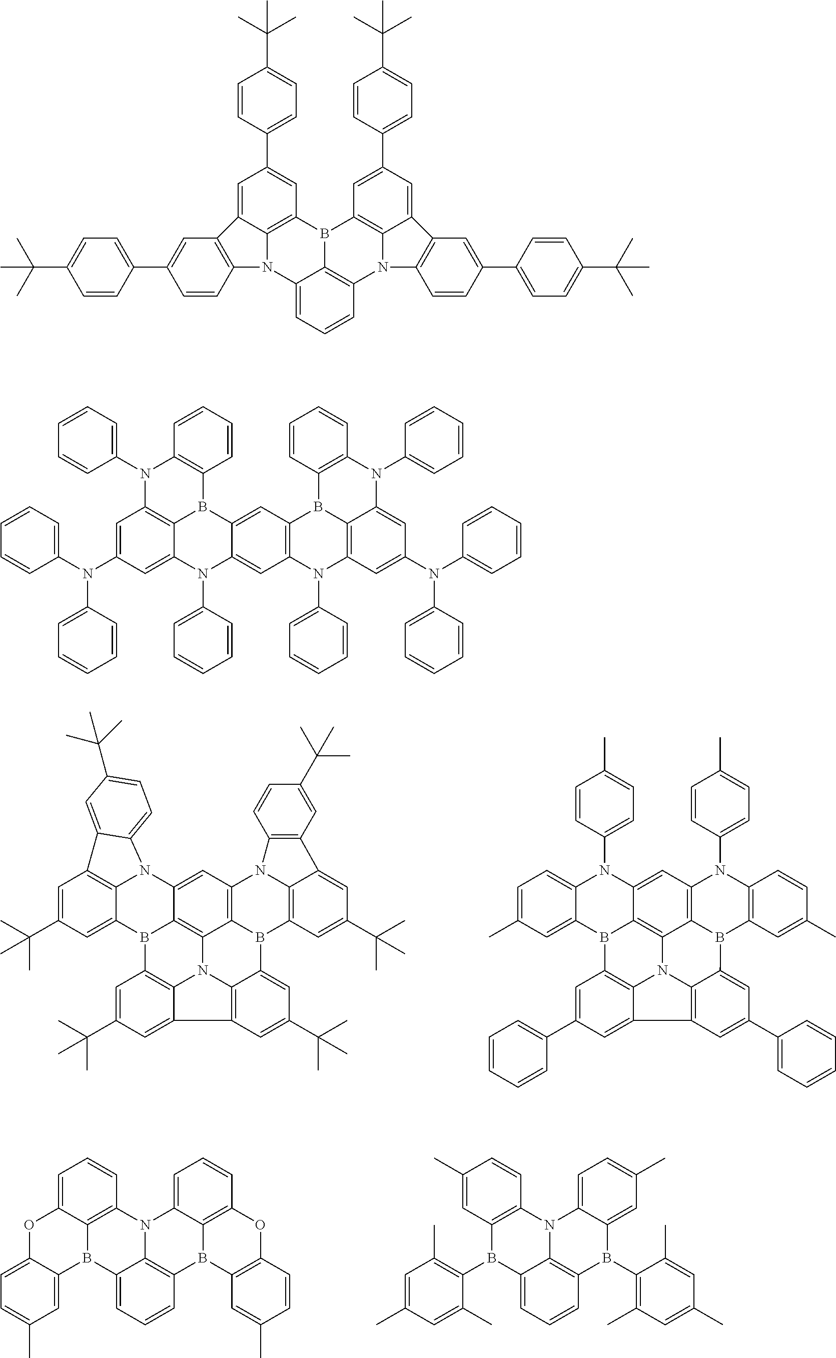

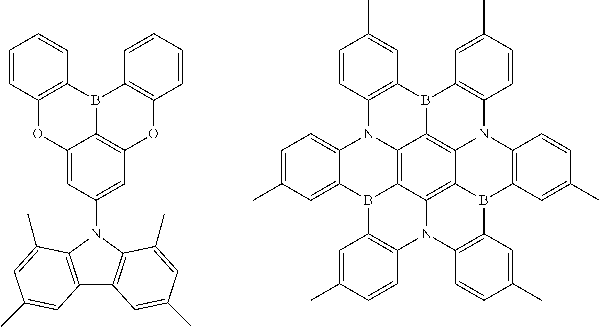

The color conversion composition of the present invention preferably contains the luminescent material (a) described below. The luminescent material (a) is a luminescent material that emits light with a peak wavelength observed in the region of 500 nm to less than 580 nm by use of excitation light with a wavelength of 400 nm to 500 nm. Hereinafter, the light emission observed to have a peak wavelength in the range of 500 nm to less than 580 nm is referred to as “green emission”. In general, the higher the energy of the excitation light is, the more likely a material will decompose. However, the excitation energy of the excitation light in the wavelength range of 400 nm to 500 nm is relatively small. Thus, green emission with good color purity is obtained without causing decomposition of a luminescent material (a) in the color conversion composition.

Further, the color conversion composition of the present invention preferably contains at least one of the luminescent material (a) and the luminescent material (b) as shown below. As mentioned above, the luminescent material (a) is a luminescent material that emits light with a peak wavelength of 500 nm to less than 580 nm by use of excitation light with a wavelength of 400 nm to 500 nm. The luminescent material (b) is a luminescent material that emits light with a peak wavelength observed in the region of 580 nm to 750 nm when excited by at least one of excitation light with a wavelength of 400 nm to 500 nm and light emitted by the luminescent material (a). Hereinafter, the light emission observed to have a peak wavelength in the region of 580 nm to 750 nm is referred to as “red emission”.

Part of the excitation light with a wavelength of 400 nm to 500 nm partially transmits through the color conversion composition or color conversion member (a member containing the color conversion composition or a cured product thereof) of the present invention, and thus in the case of using a blue LED having a sharp emission peak, each of blue, green and red colors exhibits an emission spectrum in a sharp profile, making it possible to obtain white light with good color purity. As a result, particularly in a display, more vivid colors and a larger color gamut can be efficiently produced. In the lighting applications, compared with a currently prevailing white LED fabricated by combining a blue LED and a yellow fluorescent substance, the light emission characteristics particularly in the green and red regions are improved, and therefore a preferable white light source with enhanced color rendering properties can be obtained.

The luminescent material (a) may be, for example, a coumarin derivative such as coumarin 6, coumarin 7 or coumarin 153, a cyanine derivative such as indocyanine green, a fluorescein derivative such as fluorescein, fluorescein isothiocyanate or carboxyfluorescein diacetate, a phthalocyanine derivative such as phthalocyanine green, a perylene derivative such as diisobutyl-4,10-dicyanoperylene-3,9-dicarboxylate, a pyrromethene derivative, a stilbene derivative, an oxazine derivative, a naphthalimide derivative, a pyrazine derivative, a benzimidazole derivative, a benzoxazole derivative, a benzothiazole derivative, an imidazopyridine derivative, an azole derivative, a compound having a fused aryl ring, such as anthracene, or a derivative thereof, an aromatic amine derivative, or an organic metal complex compound. The above-mentioned compound having a partial structure of the general formula (1), the compound of the general formula (2), the compound of the general formula (3), and the compound of the general formula (4) also exhibit light emission with high color purity, and are therefore preferable as the luminescent material contained in the color conversion composition. The color conversion composition of the present invention may contain two or more of them as at least one luminescent material.

The luminescent material (b) may be, for example, a cyanine derivative such as 4-dicyanomethylene-2-methyl-6-(p-dimethylaminostyryl)-4H-pyrane, a rhodamine derivative such as rhodamine B, rhodamine 6G, rhodamine 101 and sulforhodamine 101, a pyridine derivative such as 1-ethyl-2-(4-(p-dimethylaminophenyl)-1,3-butadienyl)-pyridinium-perchlorate, a perylene derivative such as N,N′-bis(2,6-diisopropylphenyl)-1,6,7,12-tetraphenoxyperylene-3,4:9,10-bisdicarboimide, a porphyrin derivative, a pyrromethene derivative, an oxazine derivative, a pyrazine derivative, a compound having a fused aryl ring, such as naphthacene or dibenzodiindenoperylene, or a derivative thereof, or an organic metal complex compound. The compound having a partial structure of the general formula (1), the compound of the general formula (2), the compound of the general formula (3), and the compound of the general formula (4) also exhibit light emission with high color purity, and are therefore preferable as the luminescent material contained in the color conversion composition. The color conversion composition of the present invention may contain two or more of them as at least one luminescent material.

As mentioned above, in order to improve color reproducibility, it is preferable that the full width at half maximum of the emission spectrum of each of blue, green, and red colors is small. Particularly, small full width at half maximum of the emission spectra of green and red colors is effective in improving color reproducibility. For example, the full width at half maximum of the emission spectrum of the luminescent material (a) mentioned above is preferably 50 nm or less, more preferably 40 nm or less, still more preferably 35 nm or less, and particularly preferably 30 nm or less. The full width at half maximum of the emission spectrum of the luminescent material (b) mentioned above is preferably 60 nm or less, more preferably 50 nm or less, still more preferably 45 nm or less, and particularly preferably 40 nm or less.

The amount of the luminescent material in the color conversion composition of the present invention can be selected depending on the molar extinction coefficient, fluorescence quantum yield, and absorption intensity at the excitation wavelength of the compound, and the thickness and transmittance of the color conversion member (color conversion sheet, etc.) formed. Here, the amount of the luminescent material, in the case where two or more luminescent materials are contained in the color conversion composition of the present invention, means the total amount thereof. The amount of the luminescent material is preferably from 1.0×10⁻² parts by weight to 5 parts by weight per 100 parts by weight of the binder resin contained in the color conversion composition of the present invention.

In the case where the color conversion composition contains both a luminescent material (a) providing green emission and a luminescent material (b) providing red emission, since part of green emission is converted to red emission, the amount wₐ of the luminescent material (a) and the amount w_{b} of the luminescent material (b) preferably have a relationship of wₐ≥w_{b}, and the amount ratio wₐ:w_{b} of the luminescent materials (a), (b) is preferably from 200:1 to 3:1. Here, the amount wₐ and the amount w_{b} are in percent by weight relative to the weight of the binder resin contained in the color conversion composition of the present invention.

The luminescent material contained in the color conversion composition of the present invention may contain another compound, as required, other than the above-illustrated compounds. For example, the luminescent material may contain an assist dopant to enhance the energy transfer efficiency from excitation light to the luminescent material. In the case of intending to add an emission color, the color conversion composition of the present invention may contain the above-described organic luminescent material, or a known luminescent material such as an inorganic fluorescent substance, a fluorescent pigment, a fluorescent dye, or a quantum dot.

The following are examples of organic luminescent materials other than the above-illustrated compounds (the compound of the general formula (2), the compound of the general formula (3), and the compound of the general formula (4)). However, the organic luminescent materials are not specifically limited thereto.

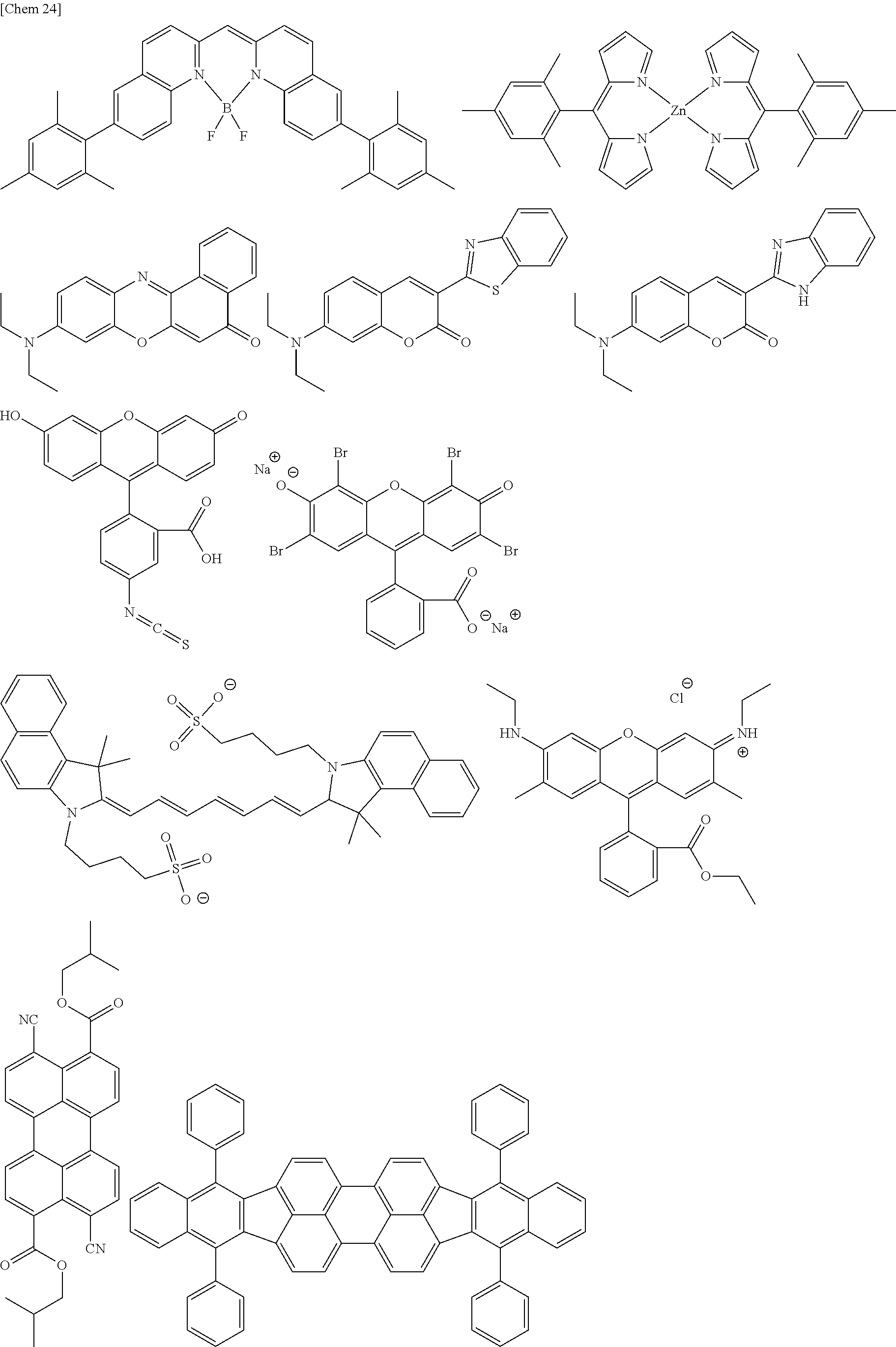

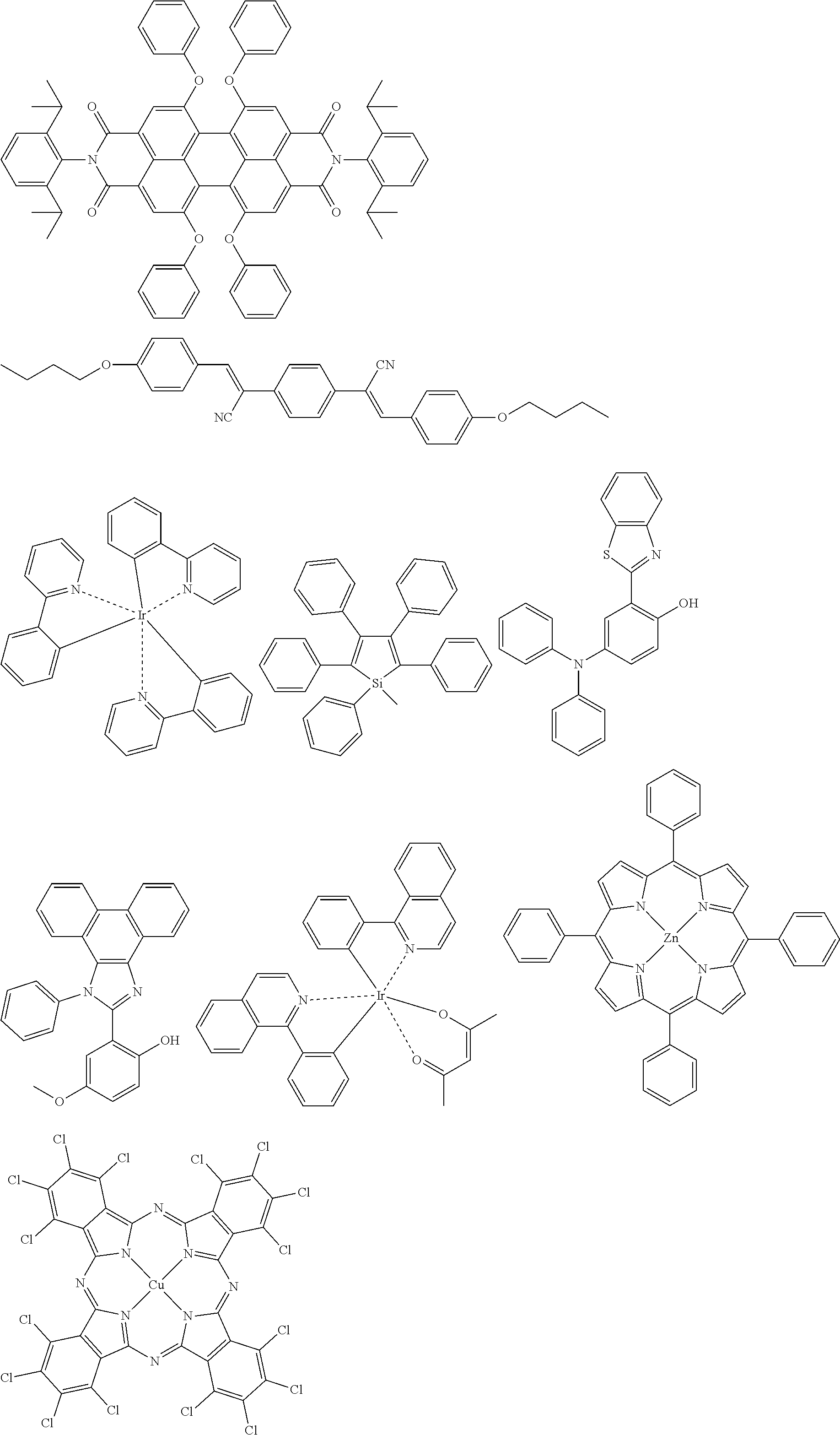

### <Binder Resin>

The color conversion composition of the embodiment of the present invention may further contain a binder resin, in addition to at least one luminescent material. In this color conversion composition of the present invention, the binder resin contains at least one branched polymer selected from the group consisting of star polymers, graft polymers and hyperbranched polymers.

A star polymer is a polymer with a structure in which three or more polymer chains (hereafter also referred to as arm polymers) extend radially from a common center (hereafter also referred to as a core part). A graft polymer is a polymer with a structure in which polymer chain (hereinafter referred to as a side chain polymer) is extended as a side chain from a linear polymer. A hyperbranched polymer is a multi-branched polymer obtained by one-step polymerization of a multifunctional monomer having two or more types of functional groups, which has a configuration having a branch point in a repeating unit and the molecular chains extending three-dimensionally.

The color conversion composition of the present invention contains at least one of these branched polymers, enabling better dispersion of the luminescent material in the color conversion composition or cured product thereof. Furthermore, even under high temperatures, the diffusion of the luminescent material in the color conversion composition can be suppressed and changes in the dispersion state of the luminescent material can be suppressed, thereby suppressing changes in the characteristics of the color conversion member containing the color conversion composition or cured product thereof. In particular, when molecular materials such as organic luminescent materials are used as luminescent materials, thermal diffusion is more likely to occur compared to nanoparticles such as inorganic fluorescent substances and quantum dots, so the improvement effect of including branched polymers is significant. Among them, compounds having a partial structure of the general formula (1), compounds of the general formula (2), compounds of the general formula (3), and compounds of the general formula (4) exhibit significantly changed emission characteristics when molecules in the excited state, or molecules in the excited state and molecules in the ground state are brought into close proximity to each other. For this reason, it is preferable to use the above-mentioned branched polymer to suppress changes in the dispersion state of these compounds (luminescent materials) in the color conversion composition.

The color conversion composition of the present invention may contain a mixture of two or more of star polymers, graft polymers, and hyperbranched polymers as the binder resins. The color conversion composition may contain two or more of the same type of branched polymers, such as two of star polymers.

From the viewpoint of dispersion of the luminescent material at high temperatures, it is preferred that the binder resin of the color conversion composition of the present invention contains at least a star polymer, among the above-mentioned branched polymers. It is believed that the star polymer can exhibit a high dispersion assistance ability by folding the luminescent material with three or more arm polymers extending radially from the core part.

As the polymer material constituting the arm polymer of the star polymer, a polymer material having excellent formability, transparency, and heat resistance is preferable. From the viewpoint of dispersibility of the luminescent material, it is preferable that the arm polymer of the star polymer is a polymer of at least one monomer selected from the group consisting of vinyl compounds, acrylic acid, acrylate ester, acrylamide, methacrylic acid, methacrylate ester, and methacrylamide. When the polymer is a copolymer of a plurality of monomers, the copolymerization may be performed by random polymerization or block polymerization.

As the arm polymer of the star polymer, the more preferred polymer is a polymer of at least one monomer selected from the group consisting of vinyl compounds having a ring structure, acrylic acid, acrylate ester, methacrylic acid, and methacrylate ester. The even more preferred polymer is a polymer of at least one monomer selected from the group consisting of vinyl compounds having an alicyclic structure or an aromatic ring structure, acrylate ester, and methacrylate ester. Among them, a copolymer of vinyl compounds having an alicyclic structure and methacrylate ester and a polymer of methacrylate ester are particularly preferred from the viewpoint that the glass transition temperature of the arm polymer moiety is higher and the dispersion state of the luminescent material can be maintained even at high temperatures.

In the binder resin contained in the color conversion composition of the present invention, the above explanation regarding the constituent materials of the arm polymers of the star polymers also applies to each of the polymer materials constituting the graft polymers and the hyperbranched polymers.

In the binder resin in the color conversion composition of the present invention, it is preferred that at least one branched polymer contained in the binder resin has fewer acidic functional groups and basic functional groups. This is because, when the number of these functional groups is small, the transfer of charges to and from the luminescent material is small, and thus the light emission characteristics of the luminescent material are less likely to be affected. In particular, when a molecular material such as an organic luminescent material is used as the luminescent material, the light emission characteristics change significantly due to the transfer of electrons. Therefore, it is preferable that the branched polymer has few acidic functional groups and basic functional groups, and among them, the branched polymer having fewer basic functional groups is preferable.

Examples of the acidic functional group include a carboxyl group (—COOH), a sulfo group (—SO₃H), a sulfate group (—OSO₃H), a phosphono group (—PO(OH)₂), a phosphonooxy group (—OPO(OH)₂), a hydroxyphosphoryl group (—PO(OH)—), and a sulfanyl group (—SH). Examples of the basic functional group include a primary amino group, a secondary amino group, a tertiary amino group, an ammonium group, an imino group, and a nitrogen-containing heterocyclic group such as pyridine, pyrimidine, pyrazine, imidazole, and triazole.

The acid value of at least one branched polymer contained in the above-described binder resin is preferably 10 mgKOH/g or less, more preferably 1 mgKOH/g or less, still more preferably 0.1 mgKOH/g or less, and particularly preferably 0.01 mgKOH/gm or less.

The base number of the at least one branched polymer is preferably 10 mgKOH/g or less, more preferably 1 mgKOH/g or less, still more preferably 0.1 mgKOH/g or less, and particularly preferably 0.01 mgKOH/gm or less.

The acid value and the base number of the branched polymer mentioned above can be determined, for example, by measuring using the method defined in Japanese Industrial Standards K2501-2003.

As a method for forming an arm polymers of a star polymer or a side chain polymer of a graft polymer, known polymerization methods such as radical polymerization, cationic polymerization, anionic polymerization, polycondensation, etc. can be applied. In the formation method, additional reactions such as hydrolysis or hydrogenation may be performed after polymerization. Among the above polymerization methods, the living polymerization method is preferred because it can form homogeneous polymer chains and express homogeneous dispersion assistance ability. Especially, from the viewpoint that the primary structure can be easily adjusted and the physical properties can be easily adjusted, atom transfer radical polymerization (ATRP) and reversible addition-fragmentation chain transfer (RAFT) polymerization are more preferred.

The polymerization catalyst for ATRP is not particularly limited, but at least one metal element selected from the group consisting of a copper (Cu), iron (Fe), cobalt (Co), chromium (Cr), manganese (Mn), molybdenum (Mo), silver (Ag), zinc (Zn), palladium (Pd), rhodium (Rh), platinum (Pt), ruthenium (Ru), iridium (Ir), ytterbium (Yb), samarium (Sm), rhenium (Re), neodymium (Nd), and nickel (Ni) is suitably used. Among them, Cu is the most suitable from the viewpoint of low cost and good balance between activity and stability.

The ligand of the metal catalyst described above is not particularly limited, but pyridine-based compounds, alkylamine-based compounds, bipyridine-based compounds, and pyridylmethanimine-based compounds can be suitably used. Examples of the pyridine compound include tris(2-pyridylmethyl)amine (TPMA) and N,N,N′,N′-tetrakis(2-pyridylmethyl)ethylenediamine (TPEN). Examples of the alkylamine compounds include tris[2-(dimethylamino)ethyl]amine (Me₆TREN) and N,N,N′,N″,N″-pentamethyldiethylenetriamine (PMDETA). An example of the bipyridine compound is 4,4′-di-tert-butyl-2,2′-pyridyl (dBdby). An example of the pyridylmethanimine compound is N-butyl-2-pyridylmethanimine (Butyl-PMI).

In the binder resin contained in the color conversion composition of the present invention, it is preferred that the star polymer has a small amount of residual polymerization catalyst and the impurity derived from the polymerization catalyst. If the remaining amount is small, the use of star polymer in optical application such as color conversion can reduce changes in optical properties over time, such as yellowing. In order to reduce such residual amount, it is desirable to reduce the amount of metal catalyst used during polymerization. For example, taking the amount of substance of the monomer charged in the reaction solution as 100, the amount of substance of metal atoms in the metal catalyst used is preferably 0.1 or less, more preferably 0.05 or less, still more preferably 0.01 or less, and particularly preferably 0.001 or less.

Among ATRP, ICAR (initiators for the continuous activator regeneration) method and the ARGET (activators regenerated by electron transfer) method are suitable polymerization methods in which the amount of metal catalyst used can be reduced by regenerating the metal catalyst through the addition of a reducing agent.

The core part of the star polymer is a moiety having three or more substitution sites which serve as the starting points of the arm polymers. That is, the number of arm polymers per core part is 3 or more, more preferably 4 or more, and still more preferably 6 or more.

The core part of the star polymer is not particularly limited, but examples thereof include a part containing a sugar alcohol derivative, a part containing a cyclic siloxane derivative, a part containing silsesquioxane, and a microgel. Examples of the sugar alcohol derivative include tritol such as glycerol, tetritol such as erythritol and threitol, pentitol such as arabinitol, xylitol, and arabinitol, hexitol such as iditol, galactitol, glucitol, and mannitol, heptitol such as volemitol and perseitol, octitol such as erythrogalactoctitol, cyclitol such as inositol and quercitol, pentaglycerol, pentaerythritol, and dipentaerythritol. Examples of the cyclic siloxane derivatives include cyclotetrasiloxane and cyclopentasiloxane. Among them, the core part is preferably a part containing silsesquioxane, from the viewpoints of high glass transition temperature (Tg) and high compatibility with resins. As the silsesquioxane, a cage-type silsesquioxane derivative such as octasilsesquioxane, decasilsesquioxane, or dodecasilsesquioxane is preferred. Moreover, from the viewpoints of being relatively inexpensive, exhibiting moderate polarity, and having high affinity with the luminescent material, the core part is preferably a part containing a sugar alcohol derivative.

The polydispersity of the molecular weight of the star polymer is not particularly limited, but is preferably 1.0 to 2.0. The small polydispersity allows the star polymer to be homogeneously dispersed in the color conversion composition of the present invention or in the color conversion members containing the color conversion composition, and to develop a high dispersion assistance ability. The polydispersity of the molecular weight of the star polymer is more preferably 1.0 to 1.5, still more preferably 1.0 to 1.3, and particularly preferably 1.0 to 1.2. Here, the polydispersity can be calculated from the number average molecular weight Mn and the weight average molecular weight Mw by the calculating formula Mw/Mn. The number average molecular weight Mn and the weight average molecular weight Mw can be measured by performing GPC analysis using a commercially available measuring instrument (for example, a GPC analyzer manufactured by Tosoh Corporation (product name HLC-8220)) based on the Japanese Industrial Standards (JIS) JIS K7252-3 (2008).

Specific examples of the star polymer include, but are not limited to, polymers described in Chem. Rev. 2016, 116, 6743, and polymers having a partially modified structure. These resins can be synthesized by known methods. Commercial products can also be used as these resins.

In the color conversion composition of the present invention, it is preferred that the binder resin in the color conversion composition contains at least a star polymer. As one aspect of at least one branched polymer contained in the binder resin, the core part of the star polymer is preferably a moiety containing a sugar alcohol derivative, a cyclic siloxane derivative, or a silsesquioxane. In addition to this, the arm polymer of the star polymer is preferably a polymer of at least one monomer selected from the group consisting of vinyl compounds, acrylic acid, acrylate ester, acrylamide, methacrylic acid, methacrylate ester, and methacrylamide. Further, the polydispersity of the molecular weight of the star polymer is preferably 2.0 or less. In this case, the polydispersity of the molecular weight is more preferably 1.5 or less. The base number of the star polymer is more preferably 10 mgKOH/g or less.

As another aspect of the at least one branched polymer in the color conversion composition of the present invention, the core part of the star polymer contained in the above binder resin is preferably a moiety containing octasilsesquioxane. In addition to this, the arm polymer of the star polymer is preferably a polymer of at least one monomer selected from the group consisting of acrylic acid, acrylate ester, methacrylic acid, and methacrylate ester. Furthermore, the acid value of the star polymer is preferably 10 mgKOH/g or less, the base number of the star polymer is preferably 10 mgKOH/g or less, and the polydispersity of the molecular weight of the star polymer is preferably 2.0 or less. In this case, the base number is more preferably 1 mgKOH/g or less. The polydispersity of the molecular weight is more preferably 1.5 or less.

As another aspect of the at least one branched polymer in the color conversion composition of the present invention, the core part of the star polymer contained in the above binder resin is preferably a moiety containing a sugar alcohol derivative. In addition to this, the arm polymer of the star polymer is preferably a polymer of at least one monomer selected from the group consisting of acrylic acid, acrylate ester, methacrylic acid, and methacrylate ester. Furthermore, the acid value of the star polymer is preferably 10 mgKOH/g or less, the base number of the star polymer is preferably 10 mgKOH/g or less, and the polydispersity of the molecular weight of the star polymer is preferably 2.0 or less. In this case, the base number is more preferably 1 mgKOH/g or less. The polydispersity of the molecular weight is more preferably 1.5 or less.

As another aspect of the at least one branched polymer in the color conversion composition of the present invention, the core part of the star polymer contained in the above binder resin is preferably a moiety containing a cyclic siloxane derivative. In addition to this, the arm polymer of the star polymer is preferably a polymer of at least one monomer selected from the group consisting of acrylic acid, acrylate ester, methacrylic acid, and methacrylate ester. Furthermore, the acid value of the star polymer is preferably 10 mgKOH/g or less, the base number of the star polymer is preferably 10 mgKOH/g or less, and the polydispersity of the molecular weight of the star polymer is more preferably 2.0 or less. In this case, the base number is more preferably 1 mgKOH/g or less. The polydispersity of the molecular weight is preferably 1.5 or less.

In the color conversion composition of the present invention, the binder resin in the color conversion composition may contain at least a graft polymer. As another aspect of the at least one branched polymer contained in the binder resin, the side chain polymer of the graft polymer is preferably a polymer of at least one monomer selected from the group consisting of acrylic acid, acrylate ester, methacrylic acid, and methacrylate ester. In addition to this, the acid value of the graft polymer is preferably 10 mgKOH/g or less, and the base number of the graft polymer is preferably 10 mgKOH/g or less. In this case, the base number is more preferably 1 mgKOH/g or less.

An aspect of the method of producing the branched polymers contained in the binder resin of the color conversion composition of the present invention preferably include a polymerization step to form a plurality of polymer chains by ATRP using a Cu catalyst. In the polymerization step, the amount of substance of Cu atoms used is preferably 0.1 or less per 100 of the amount of substance of the monomer charged in the reaction solution.

As one embodiment of the present invention, 50% by mass or more of resin of 100% by mass of the binder resin contained in the color conversion composition is preferably at least one branched polymer selected from the group consisting of star polymers, graft polymers, and hyperbranched polymers. Accordingly, the luminescent material in the color conversion composition can be more easily incorporated into an entangled structure of a large number of polymer chains of the branched polymer, resulting in a good dispersion state. In this case, two or more of these branched polymers may be mixed together as 50% by mass or more of resin of 100% by mass of the binder resin. From the viewpoint of increasing the entangled structure of polymer chains and improving dispersion stability, the amount of the branched polymer in the binder resin is more preferably 70% by mass or more, and even more preferably at least 80% by mass or more. It is also preferred that the binder resin consist solely of the above branched polymers.

An example of the configuration of the binder resin contained in the color conversion composition of the present invention is a configuration of a binder resin containing at least one branched polymer selected from the group consisting of star polymers, graft polymers and hyperbranched polymers, and at least one resin that does not fall under any of these branched polymers (hereinafter referred to as “resin that does not fall under branched polymer”). In this case, it is possible to achieve both the dispersion assistance of the luminescent material by the branched polymer and the improvement of moldability and heat resistance of the color conversion composition by other resins (such as resins that do not fall under branched polymers), which is preferable.

As resins that do not fall under branched polymers, materials excellent in formability, transparency, heat resistance, and the like are suitably used. The material (resin) may be, for example, a photocurable resist material having a reactive vinyl group, such as an acrylic, methacrylic, poly(vinyl cinnamate)-based, polyimide-based, or cyclic rubber-based resin, an epoxy resin, a silicone resin (including a cured (crosslinked) organopolysiloxane such as silicone rubber or silicone gel), a urea resin, a fluororesin, a polycarbonate resin, an acrylic resin, a methacryl resin, a polyimide resin, cycloolefin, a polyethylene terephthalate resin, a polypropylene resin, a polystyrene resin, a urethane resin, a melamine resin, a polyvinyl resin, a polyamide resin, a phenol resin, a polyvinyl alcohol resin, a cellulose resin, an aliphatic ester resin, an aromatic ester resin, an aliphatic polyolefin resin, an aromatic polyolefin resin, a hydrogenated styrene-based resin, a resin having a fluorene skeleton in the repeating unit, or a copolymer thereof. In the color conversion composition of the present invention, the binder resin may contain two or more of them.

Among these resins, acrylic resins, copolymer resins containing acrylate ester or methacrylate ester moieties, polyester resins, cyclo-olefin resins, epoxy resins, or silicone resins are preferred from the viewpoint of transparency and dispersibility of luminescent materials. From the viewpoint of the heat resistance, hydrogenated styrene-based resins, resins having a fluorene skeleton, and copolymer resins containing these resins can also be suitably used.

In particular, from the viewpoint of achieving both dispersibility of heat resistance of the luminescent material, the resin that does not fall under branched polymer is preferably a polymer of at least one monomer selected from the group consisting of acrylate esters, methacrylate esters, and styrene, or a hydrogenation product thereof. That is, it is preferable that the binder resin in the color conversion composition of the present invention further contains, in addition to at least one branched polymer described above, a resin that does not fall under branched polymer and is a polymer of at least one monomer selected from the group consisting of acrylate esters, methacrylate esters and styrene, or hydrogenation product thereof. In the present invention, the hydrogenated product refers to a compound having a structure obtained by a hydrogenation reaction, that is, a reaction in which hydrogen atoms are added to a multiple bond site using hydrogen gas or the like as a reducing agent. For example, a hydrogenated product of an acrylic-styrene copolymer resin refers to a resin having a structure in which some or all of the benzene rings derived from the styrene in the acrylic-styrene copolymer resin have been replaced with cyclohexane rings. The hydrogenation rate of the hydrogenated product is not particularly limited. These resins (the above-described polymer or hydrogenated product thereof) can be obtained, for example, by a method including copolymerizing monomers materials in the presence of a polymerization initiator. A commercially available product can also be used as the resin.

Examples of the binder resin which dose not fall under branched polymer include thermosetting resins, photocurable resins, and thermoplastic resins. Thermoplastic resins are less likely to inhibit light emission of luminescent materials because they contain fewer reactive functional groups and less amount of reactive impurities, such as polymerization initiators and the crosslinking agent. For this reason, thermoplastic resins can be suitably used as resins that do not fall under branched polymers. From the viewpoint of heat resistance, thermosetting resins and photocurable resins can also be suitably used.

When the resin that does not fall under branched polymer is a thermoplastic resin, it is preferable that Tg of the resin be 100 °C or more from the viewpoint of suppressing thermal diffusion and molecular motion of the luminescent material. That is, it is preferable that the binder resin in the color conversion composition of the present invention further contains a resin that does not fall under branched polymer and has Tg of 100 °C or more, in addition to the at least one branched polymer mentioned above. The Tg of the resin is more preferably 110 °C or more, and especially preferably 120 °C or more. For example, the glass transition temperature of the thermoplastic resin can be measured with a commercially available measuring instrument (for example, a differential scanning calorimeter (trade name: DSC6220, rate of temperature rise: 0.5 °C/min) produced by Seiko Electronic Industry Co. Ltd.).

As one embodiment of the present invention, a resin that does not fall under branched polymer is preferably a polymer of at least one monomer selected from the group consisting of acrylate ester, methacrylate ester, and styrene, or a hydrogenated product thereof, and has Tg of 100 °C or more. In this case, the Tg is more preferably 110 °C or more, and particularly preferably 120 °C or more.

These resins can be obtained, for example, by a method including copolymerizing monomers materials in the presence of a polymerization initiator. A commercially available product can also be used as the resin. Examples of the commercially available resin include the Dianal (trademark) series (for example, BR-80, BR-83, BR-85, BR-88) manufactured by Mitsubishi Chemical Corporation, the Optimas (trademark) series (for example, Optimas 6500, Optimas 7500) manufactured by MITSUBISHI GAS CHEMICAL COMPANY, INC., the Estyrene® MS series (for example, MS-200) manufactured by NIPPON STEEL Chemical & Material Co., Ltd., the CEVIAN-MAS series (for example, MAS30F) manufactured by Daicel Miraizu Ltd., and DENKA TX polymer series (for example, TX-100S) manufactured by Denka Company Limited, but the resin is not limited thereto.

In one embodiment of the present invention, it is preferred that 50% by mass or more resin of 100% by mass of the binder resin contained in the color conversion composition is a resin that does not fall under branched polymers. In this case, the moldability and the heat resistance of the color conversion composition can be improved. In this case, from the viewpoint of maintaining the dispersion assistance effect of the luminescent material by the branched polymer, the ratio of the branched polymer in the binder resin is preferably not less than 0.1% by mass, more preferably not less than 1% by mass, still more preferably not less than 5% by mass, and particularly preferably not less than 10% by mass.

### <Additive>

The color conversion composition of the present invention may contain an additive as another component, in addition to at least one luminescent material and binder resin described above. Examples of the additive include a filler, a light stabilizer, an antioxidant, a processing and heat stabilizer, a light fastness stabilizer such as UV absorbers, a dispersant or a leveling agent for stabilizing the applied film, a scattering agent, a plasticizer, a crosslinking agent such as an epoxy compound, a curing agent such as amine, acid anhydride, and imidazole, a pigment, and an adhesion aid such as a silane coupling agent as a film surface modifier.

Examples of the fillers include fumed silica, glass powder, quartz powder, and other particles, titanium oxide, zirconium oxide, barium titanate, zinc oxide, and silicone microparticles. The color conversion composition of the present invention may contain two or more of them as a filler.

Examples of the light stabilizer include, but are not specifically limited to, tertiary amines, catechol derivatives, complexes and organic acid salts containing at least one transition metal selected from the group consisting of nickel (Ni), scandium (Sc), vanadium (V), manganese (Mn), iron (Fe), cobalt (Co), copper (Cu), yttrium (Y), zirconium (Zr), molybdenum (Mo), silver (Ag), and lanthanoids. In addition, the light stabilizers may be used individually or in combination.

Examples of the antioxidant include, but are not specifically limited to, phenolic antioxidants such as 2,6-di-tert-butyl-p-cresol and 2,6-di-tert-butyl-4-ethylphenol. In addition, these antioxidants may be used individually or in combination.

Examples of the process/heat stabilizer include, but are not specifically limited to, phosphoric stabilizers, such as tributyl phosphite, tricyclohexyl phosphite, triethylphosphine, and diphenylbutylphosphine. In addition, these stabilizers may be used individually or in combination.

Examples of the light-resistant stabilizer include, but are not specifically limited to, benzotriazoles, such as 2-(5-methyl-2-hydroxyphenyl)benzotriazole and 2-[2-hydroxy-3,5-bis(α,α-dimethylbenzyl)phenyl]-2H-benzotriazole. In addition, these light-resistant stabilizers may be used individually or in combination.

The scattering particles are preferably, for example, inorganic particles having a refractive index of 1.7 to 2.8. Examples of the inorganic particles include titania, zirconia, alumina, ceria, tin oxide, indium oxide, iron oxide, zinc oxide, aluminum nitride, sulfides of aluminum, tin, titanium, or zirconium, and hydroxides of titanium or zirconium.

The amount of the additives in the color conversion composition of the present invention can also be set depending on the molar extinction coefficient, fluorescence quantum yield, and absorption intensity at the excitation wavelength of the compound, and the thickness and transmittance of the color conversion member formed. The lower limit of the amounts of these additives are preferably not less than 1.0×10⁻³ part by weight, more preferably not less than 1.0×10⁻² part by weight, and particularly preferably not less than 1.0×10⁻¹ part by weight, relative to 100 parts by weight of the binder resin. Furthermore, the upper limit of the amounts of these additives are preferably not more than 30 parts by weight, more preferably not more than 15 parts by weight, and particularly preferably not more than 10 parts by weight, relative to 100 parts by weight of the binder resin.

### <Solvent>

The color conversion composition of the present invention may further contain a solvent, in addition to at least one luminescent material and binder resin described above. Preferably, the solvent can adjust the viscosity of a resin in a flowing state, and does not have an extreme effect on the light emission and durability of a luminescent material. Examples of the solvent include water, 2-propanol, ethanol, toluene, methyl acetate, ethyl acetate, propyl acetate, butyl acetate, methyl ethyl ketone, methyl isobutyl ketone, cyclohexanone, hexane, cyclohexane, tetrahydrofuran, acetone, terpineol, Texanol, 1,2-dimethoxyethane, Methyl Cellosolve, Ethyl Cellosolve, butyl carbitol, butyl carbitol acetate, 1-methoxy-2-propanol, and propylene glycol monomethyl ether acetate. For the color conversion composition of the present invention, one of these solvents may be used, or two or more of these solvents may be mixed and used. Among these solvents, toluene, methyl ethyl ketone, methyl acetate, ethyl acetate, and tetrahydrofuran are preferably used since they leave little residual solvent after drying.

In the color conversion member according to the embodiment of the present invention described later, the amount of the residual solvent in a color conversion layer included in the color conversion member of the present invention (the amount of the solvent remaining in the color conversion layer after drying) is preferably 3.0% by mass or less, more preferably 1.0% by mass or less, and particularly preferably 0.5% by mass or less in view of further improving the durability of the color conversion member. The amount of the residual solvent in the color conversion layer can be measured by gas chromatography.

### <Method of Producing Color Conversion Composition>

As an example, a method of producing a color conversion composition according to an embodiment of the present invention is described below. In this production method, the above-described luminescent material, a branched polymer as the binder resin, and as necessary other binder resins, additives, solvents, and the like can be mixed so that a predetermined composition is achieved, and then homogeneously mixed or kneaded using a stirrer/kneader to obtain a color conversion composition. Examples of the stirrer/kneader include homogenizers, rotation-revolution stirrers, three-roll mills, ball mills, planetary ball mills, and beads mills. After mixing or dispersing, or in the process of mixing or dispersing, defoaming is also preferably performed under a vacuum or reduced-pressure condition. In addition, a specific component may be added in advance, or a treatment such as aging may be performed. The solvent can be removed by an evaporator to achieve a desired solid concentration.

### <Color Conversion Member>

The color conversion member according to the embodiment of the present invention (hereinafter sometimes abbreviated as color conversion member of the present invention) preferably includes the above-mentioned color conversion composition or a cured product thereof. The shape of the color conversion member is not particularly limited. The shape of the color conversion member may be in the form of layers, particles, fibers, etc. An aspect of the present color conversion member of the present invention is a color conversion sheet. The color conversion sheet includes a color conversion layer containing the color conversion composition of the present invention, or a color conversion layer formed by curing the color conversion composition.

The color conversion member of the present invention may have a single color conversion layer or a plurality of color conversion layers. When the color conversion member has a plurality of color conversion layers, the color conversion layers may be laminated directly or via an intermediate layer such as an adhesive layer. A color conversion member may have, as necessary, a substrate layer or a barrier film, or two or more substrate layers or barrier layers.

For example, a layer composed of a base material such as a known and not specifically limited metal, film, glass, ceramic, or paper material may be used for the substrate layer included in the color conversion member of the present invention. Among them, glass and resin films are preferably used. The resin film is preferably a film composed of a resin such as polyethylene terephthalate (PET), polyethylene naphthalate, (PEN), polyphenylene sulfide, polycarbonate, polypropylene, polyimide, aramide, or silicone. The surface of the substrate layer can be pre-treated with mold release for the reason that separation of the film is facilitated. Similarly, in order to improve the adhesion between layers, the surface of the substrate layer may be pre-treated for easy adhesion.

When the substrate layer is a film-like layer, the thickness of the substrate layer is not specifically limited, but the lower limit of the thickness is preferably not less than 12 μm and more preferably not less than 38 μm. Additionally, the upper limit of the thickness is preferably not more than 5,000 μm and more preferably not more than 3,000 μm.

In addition, as the base material constituting the substrate layer, a member such as a barrier film, a light guide panel, a diffusion panel, a diffusion film, a prism sheet, a reflective polarizing film, a wavelength selective reflection film, a wavelength selective transmission film, a wavelength-selective absorption film can be used.

The barrier film included in the color conversion member of the present invention preferably prevents entry of oxygen, water, heat, and the like into the color conversion layer. The color conversion member of the present invention may include two or more barrier layers. For example, the light conversion member of the present invention may have barrier films on the both sides, or a barrier film on one side, of the color conversion layer.

When the barrier layer is formed of a film having agas barrier properties, the film having gas barrier properties may be, for example, a film composed of an inorganic oxide such as silicon oxide, aluminum oxide, titanium oxide, tantalum oxide, zinc oxide, tin oxide, indium oxide, yttrium oxide, or magnesium oxide; an inorganic nitride such as silicon nitride, aluminum nitride, titanium nitride, or silicon carbide nitride; a metal oxide thin film or a metal nitride thin film with another element added thereto; or a film composed of a resin such as polyvinylidene chloride, an acrylic resin, a silicone resin, a melamine resin, a urethane resin, a fluorine resin, or a polyvinyl alcohol resin, e.g., saponified vinyl acetate. The above-described barrier layer may contain two or more of them. When the above-described barrier layer is composed of a film having a barrier function against water, the film having a barrier function against water may be, for example, a film composed of a resin such as polyethylene, polypropylene, nylon, polyvinylidene chloride, a vinylidene chloride-vinyl chloride copolymer, a vinylidene chloride-acrylonitrile copolymer, a fluorine resin, or a polyvinyl alcohol resin, e.g., saponified vinyl acetate.

Representative structural examples of the color conversion member of the present invention include the structures of the color conversion sheets of the following first to sixth examples. The color conversion member of the present invention is not limited to the structural examples of the color conversion sheets shown below.

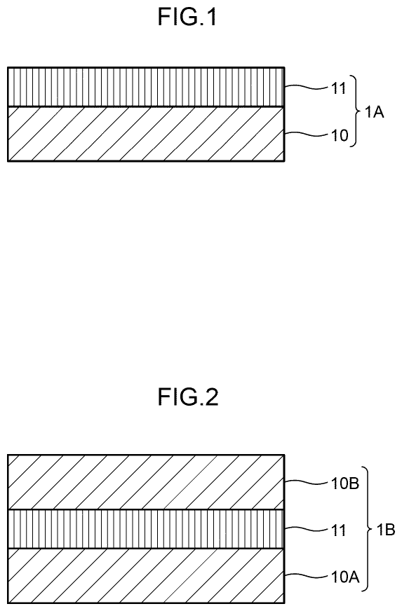

FIG. 1 is a schematic cross-sectional view depicting the first example of a color conversion member according to an embodiment of the present invention. As shown in FIG. 1, the color conversion member 1A of the first example is a color conversion sheet having a laminate structure composed of a substrate layer 10 and a color conversion layer 11. This color conversion layer 11 is a layer containing the color conversion composition of the present invention, which is obtained, for example, by curing the color conversion composition of the present invention. In this structural example of the color conversion member A, the color conversion layer 11 is placed on the substrate layer 10.

FIG. 2 is a schematic cross-sectional view depicting the second example of a color conversion member according to an embodiment of the present invention. As shown in FIG. 2, the color conversion member 1B of the second example is a color conversion sheet having a laminate structure composed of a plurality of substrate layers 10A, 10B, and a color conversion layer 11. In this structural example of the color conversion member 1B, the color conversion layer 11 is sandwiched between the plurality of base substrate layers 10A, 10B.

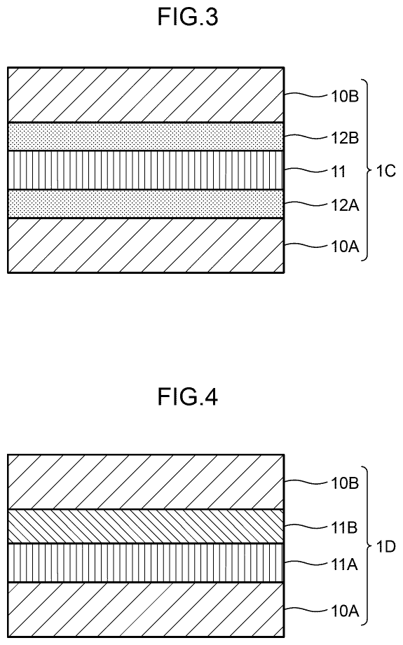

FIG. 3 is a schematic cross-sectional view depicting the third example of a color conversion member according to an embodiment of the present invention. As shown in FIG. 3, the color conversion member 1C of the third example is a color conversion sheet having a laminate structure composed of a plurality of substrate layers 10A, 10B, a color conversion layer 11, and a plurality of barrier layers 12A, 12B. In the structural example of this color conversion member 1C, the color conversion layer 11 is sandwiched between a plurality of barrier films 12A, 12B. Further, a laminate of the color conversion layer 11 and the plurality of barrier films 12A, 12B is sandwiched between the plurality of substrate layers 10A, 10B. Each of the plurality of barrier layers 12A, 12B is a layer to prevent deterioration of the color conversion layer 11 due to oxygen, water, and heat, in the color conversion member 1C.

FIG. 4 is a schematic cross-sectional view depicting the fourth example of a color conversion member according to an embodiment of the present invention. As shown in FIG. 4, the color conversion member 1D of the fourth example is a color conversion sheet having a laminate structure composed of a plurality of substrate layers 11A, 11B, sandwiched between a plurality of substrate layers 10A, 10B. In this structural example of the color conversion member 1D, a plurality of color conversion layers 11A and 11B are stacked on top of the substrate layer 10A in the order of the color conversion layers 11A and 11B, and another substrate layer 10B is stacked on top of this color conversion layer 11B. That is, the color conversion member 1D has a laminate structure with a plurality of substrate layers 10A, 10B and a plurality of color conversion layers 11A, 11B, with the plurality of color conversion layers 11A, 11B sandwiched between the plurality of base material layers 10A, 10B.

FIG. 5 is a schematic cross-sectional view depicting the fifth example of a color conversion member according to an embodiment of the present invention. As shown in FIG. 5, the color conversion member 1E of the fifth example is a color conversion sheet having a laminate structure in which an intermediate layer 13 is sandwiched between a plurality of color conversion layers 11A, 11B, and the laminate composed of the plurality of color conversion layer 11A, 11B and the intermediate layer 13 is sandwiched between a plurality of substrate layers 10A, 10B. In this structural example of the color conversion member 1E, the laminate composed of the plurality of color conversion layers 11A, 11B and the intermediate layer 13 is stacked on top of the substrate layer 10A in the order of the color conversion layers 11A, the intermediate layer 13, and the color conversion layer 11B, and another substrate layer 10B is stacked on top of this color conversion layer 11B. That is, the color conversion member 1E includes a plurality of substrate layers 10A, 10B, a plurality of color conversion layers 11A, 11B, and an intermediate layer 13, and has a laminate structure in which color conversion layer 11B/intermediate layer 13/color conversion layer 11A is sandwiched between the plurality of substrate layers 10A, 10B.

FIG. 6 is a schematic cross-sectional view depicting the sixth example of a color conversion member according to an embodiment of the present invention. As shown in FIG. 6, the color conversion member 1F of the sixth example is a color conversion sheet having a laminate structure in which an intermediate layer 13 is sandwiched between a plurality of color conversion layers 11A, 11B, and the laminate composed of a plurality of color conversion layers 11A, 11B and the intermediate layer 13 is sandwiched between a plurality of barrier layers 12A, 12B, and the laminate composed of the plurality of color conversion layers 11A, 11B and the intermediate layer 13 and the plurality of barrier layers 12A, 12B is sandwiched between a plurality of substrate layers 10A, 10B. These plurality of barrier layers 12A, 12B are formed so as to sandwich the laminate of the plurality of color conversion layers 11A, 11B with the intermediate layer 13 interposed therebetween from both sides in the lamination direction. In this structural example of the color conversion member 1F, a barrier layer 12A, a color conversion layer 11A, an intermediate layer 13, a color conversion layer 11B, and a barrier layer 12B are stacked in this order on top of this substrate layer 10A. As a result, a laminate having a laminate structure of barrier layer 12B/color conversion layer 11B/intermediate layer 13/color conversion layer 11A/barrier layer 12A is formed on this substrate layer 10A. Furthermore, as shown in FIG. 6, a substrate layer 10B is stacked on the barrier layer 12B at the upper end in the stacking direction of this laminate.

Another aspect of the color conversion member of the present invention (an aspect different from the above-mentioned color conversion sheet) is a color conversion substrate. The color conversion substrate includes, for example, a plurality of color conversion layers on a transparent substrate. Although not specifically illustrated in the figure, in the color conversion substrate, partition walls may be formed, and in said color conversion substrate, a color conversion layer may be placed between the partition walls (in a recess).

According to the function required, the color conversion member of the present invention may further have a light diffusion layer, an adhesive layer, and an auxiliary layer having an antireflection function, an antiglare function, an antireflection-antiglare function, a hard coating function (anti-friction function), an antistatic function, an antifouling function, an electromagnetic wave shielding function, an infrared cutting function, an ultraviolet cutting function, a polarizing function, or a toning function.

### <Method of Producing Color Conversion Member>

A method of producing a color conversion member according to the embodiment of the present invention is not particularly limited so long as it is a method capable of forming the color conversion composition of the present invention into a desired shape. For example, the color conversion composition of the present invention is applied to a substrate and dried to form a color conversion layer in the color conversion member of the present invention. When the binder resin contained in the color conversion composition of the present invention is a thermosetting resin, the color conversion composition may be applied to a base material such as a base layer, and then thermally cured to form a color conversion layer. When the binder resin contained in the color conversion composition of the present invention is a photocurable resin, the color conversion composition may be applied to a base material such as a base layer, and then photo-cured to form a color conversion layer. Other examples include a method in which the color conversion composition of the present invention is kneaded while heating and molded using an extruder, and a method in which the color conversion composition of the present invention is placed in a mold and molded by heating, cooling, drying, etc.

In the method of producing the color conversion member mentioned above, the color conversion compositions can be applied by means of a reverse roll coater, a blade coater, a comma coater, a slit die coater, a direct gravure coater, an offset gravure coater, a kiss coater, a natural roll coater, an air knife coater, a roll blade coater, a two-stream coaters, a rod coater, a wire bar coater, an applicator, a dip coater, a curtain coater, a spin coater, a knife coater, or the like, but application of the color conversion composition is not particularly limited thereto.

In the method of producing the color conversion member mentioned above, the color conversion composition after application can be dried using a general heating apparatus such as hot air drier or infrared drier. In this case, the heating temperature is preferably from 60 °C to 200 °C, and the heating time period is preferably from 2 minutes to 4 hours. It is also possible to perform stepwise thermal curing by step-cure or other methods.

When the color conversion layer is formed by thermal curing the color conversion composition described above, the heating apparatus may be, for example, a hot air oven. In this case, the heating conditions can be selected depending on the binder resin in the color conversion composition. For example, the heating temperature is preferably from 100 °C to 300 °C, and the heating time period is preferably from 1 minute to 2 hours.

When the color conversion layer is formed by photo-curing the color conversion composition described above, high-energy light such as ultraviolet rays is preferably irradiated to the color conversion composition. In this case, the photoirradiation conditions can be selected depending on the binder resin in the color conversion composition. For example, the wavelength of the irradiated light is preferably from 200 nm to 500 nm, and the amount of irradiation is preferably from 10 mJ/cm² to 10 J/cm².

In the method of producing the color conversion member mentioned above, after preparing the color conversion layer, the substrate layer may be changed, as necessary. In this case, simple methods include, for example, methods of re-laminating the substrate by using a hot plate, and methods using a vacuum laminator or a dry film laminator.

### <Light Source Unit>

The light source unit according to the embodiment of the present invention (hereinafter sometimes abbreviated as light source unit of the present invention) is configured to include at least a light source and the above-mentioned color conversion composition or color conversion member. In the case where the light source unit of the present invention includes a color conversion composition, the arrangement of the light source and the color conversion composition is not particularly limited, and the color conversion composition may be applied directly to the light source, or the color conversion composition may be applied to a substrate such as a film or glass separated from the light source. In the case where the light source unit of the present invention includes the color conversion member, the positions of the light source and the color conversion member are not particularly limited, and the light source may be in close contact with the color conversion member, or may employ a remote phosphor system in which the light source is separated from the color conversion member. In addition, the light source unit of the present invention may further include a color filter for the purpose of increasing the color purity, or may include an optical member such as a prism sheet, a reflective polarizing film, or a diffusion film for the purpose of improving brightness or homogenizing emitted light.

An aspect of the light source unit of the present invention is a configuration including a color conversion member (color conversion sheet) having a configuration illustrated in FIG. 5 above, a light source located at the lower part of FIG. 5 (below the substrate layer 10A), and a prism sheet and a reflective polarizing film stacked at the upper part of FIG. 5 (above the substrate layer 10B). A diffusion plate may be provided between the light source and the color conversion member shown in FIG. 5, and a reflective plate may be provided below the light source.

Another aspect of the light source unit of the present invention includes a configuration including a light source and a light guide panel, and a color conversion layer formed by directly applying the color conversion composition of the present invention, stacked on the light output side of the light guide panel. In a light source unit having this configuration, a light diffusion layer or wavelength selective transmission layer may be further formed on said color conversion layer.

The light source unit of the present invention is useful for various light sources such as spatial lighting, backlighting, and the like. Specifically, the light source unit of the present invention can be used in applications such as display, lighting device, interior, sign, signboard applications and is particularly suitable for use in display and lighting device.

### <Light Source>

As for the type of the light source included in the light source unit of the present invention, any light source may be used as long as it emits light in the wavelength region where the luminescent material used for the color conversion composition can absorb light. For example, any excitation light source, including a fluorescent light source such as a hot cathode fluorescent lamp, a cold cathode fluorescent lamp, or an inorganic electroluminescence (EL), an organic EL element light source, a light-emitting diode (LED) light source, an incandescent light source, or sunlight can be utilized in principle. Among them, from the viewpoint of color purity, the light source is preferably an LED or an organic EL element, and more preferably an LED.

For example, in display and lighting applications, from the viewpoint of increasing the color purity of blue light, an LED or organic EL element having a maximum emission in the wavelength range of 400 nm to 500 nm is a preferred light source. Furthermore, as the above light source, blue LED with maximum emission in the wavelength range from 430 nm to 480 nm are more preferable, and blue LED with maximum emission in the wavelength range of 445 nm to 470 nm are especially preferable.

The light source may have one emission peak or two or more emission peaks, and is preferably have one emission peak in order to increase the color purity. It is also possible to use a plurality of light sources having different types of emission peaks in any combination.

### <Display and Lighting Device>

A display according to an embodiment of the present invention includes at least a light source unit having a light source and a color conversion composition or a color conversion member as described above. For example, a light source unit as described above is used as a backlight unit in displays such as liquid crystal displays.

The lighting device according to the embodiment of the present invention includes at least a light source unit having a light source and a color conversion composition or a color conversion member as described above. For example, this lighting device is configured to emit white light, wherein the configuration includes a blue LED light source as a light source unit in combination with a color conversion composition or a color conversion member that converts the blue light from the blue LED light source into a light with a wavelength longer than that of the blue light.

### EXAMPLES

The present invention will be described below by the following examples, but the present invention is not limited to the examples. First, evaluation methods and materials such as luminescent materials in Examples and Comparative Examples will be described.

### <Evaluation of Durability Against Light>

In the evaluation of durability against light, a blue LED element was lighted by flowing a current of 30 mA to a light emitting device with a color conversion member each prepared in Examples and Comparative Examples, and the blue LED element (Model Number SMBB450H-1100, manufactured by Ushio Epitex Inc., emission peak wavelength: 450 nm) mounted therein, and measured for the initial emission peak strength by using a spectral radiance meter (CS-1000, manufactured by Konica Minolta, Inc.). The distance between the color conversion member and the blue LED element in the light emitting device was set to be 3 cm. Then, after continuous irradiation of light from the blue LED element under an environment at 50 °C, the time required for the emission peak intensity to decrease by 5% was observed to evaluate the durability against light of the color conversion member.

### <Luminescent Material>

In the following Examples and Comparative Examples, compounds D-1 to D-8 were used as luminescent materials contained in the color conversion members. Compounds D-1 to D-8 are the compounds shown below.

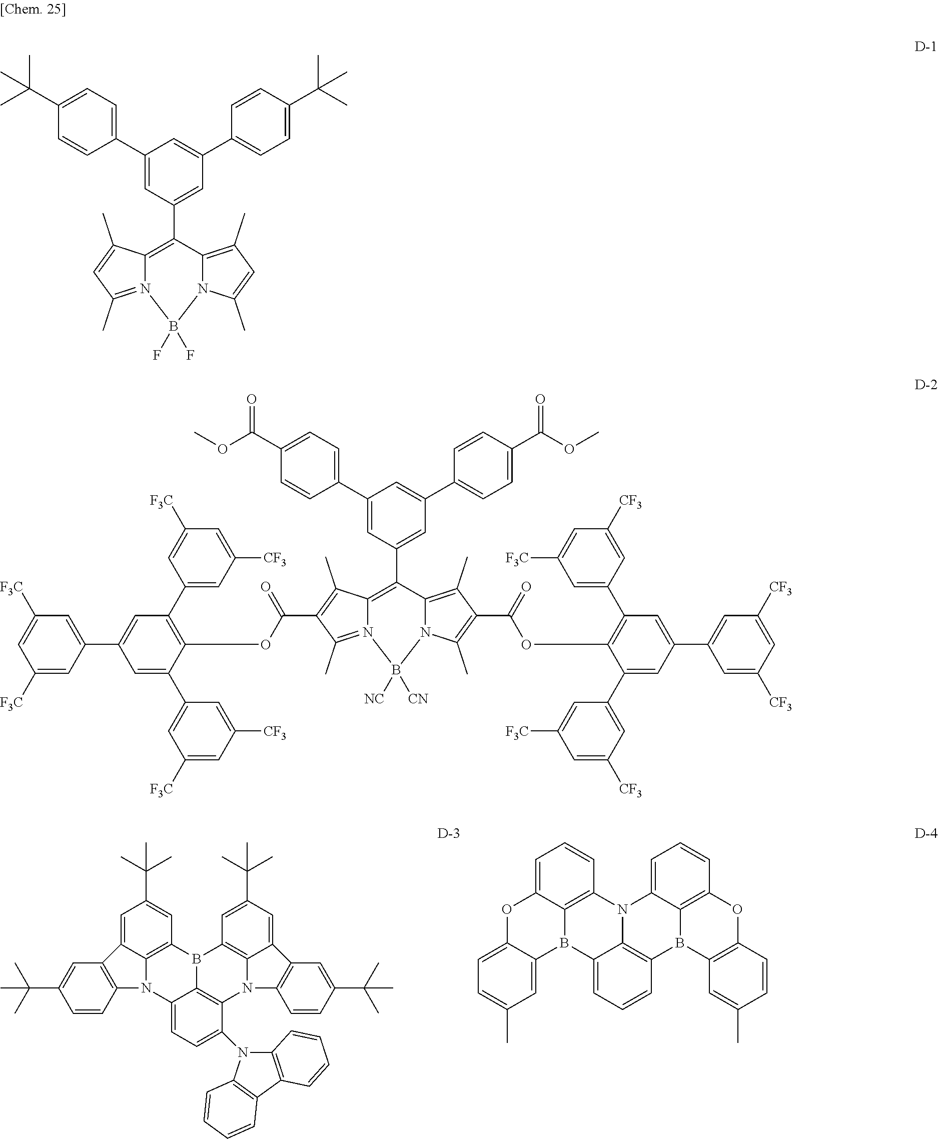

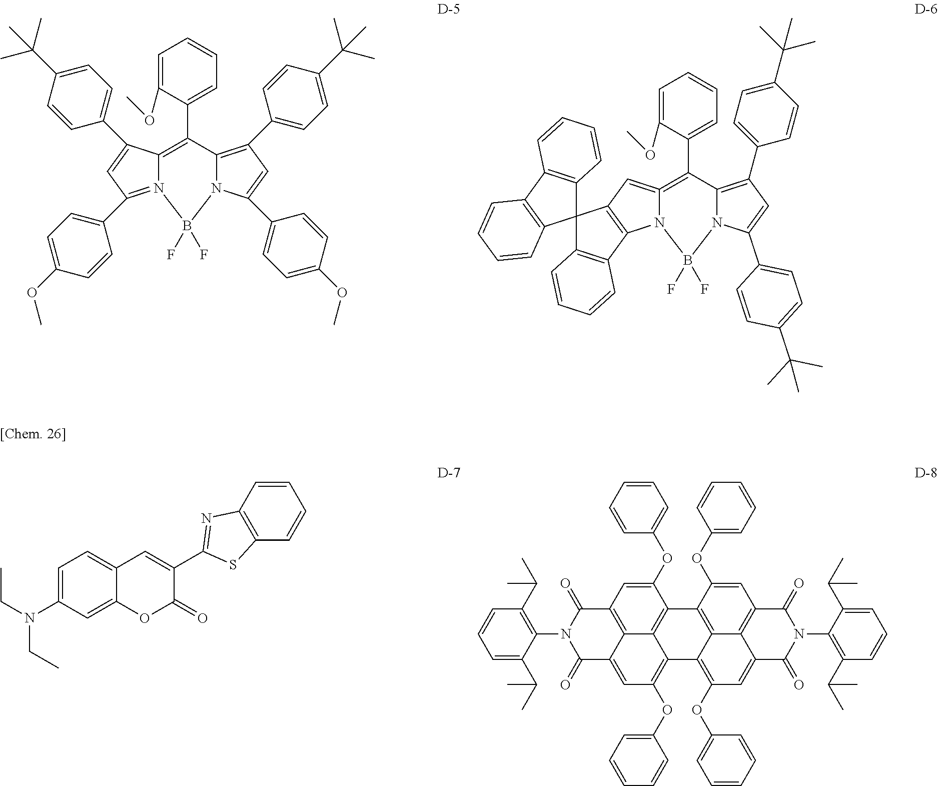

### <Branched Polymer>

In the examples described below compounds P-1 to P-4 and compounds P-7 to P-12, which are examples of branched polymers, were used as binder resins. The compounds P-1 to P-4 and the compounds P-7 to P-12 were star polymers described below, and were synthesized by atom transfer radical polymerization (ATRP) according to a known method. The acid value and base number of each of the compounds P-1 to P-4 and the compounds P-7 to P-10 were 0 mgKOH/g. The acid value of the compound P-11 was 5 mg KOH/g, and the base number of the compound P-11 was 0 mg KOH/g. The acid value of the compound P-12 was 14 mg KOH/g, and the base number was 0 mg KOH/g. The polydispersity of each of the compounds P-1 to P-4 and the compounds P-7 to P-12 are as follows. That is, 1.2 for the compound P-1, 1.5 for the compound P-2, 1.6 for the compound P-3, 3.7 for the compound P-4, 1.3 for the compound P-7, 1.2 for the compound P-8, 1.3 for the compound P-9, 1.4 for the compound P-10, 1.4 for the compound P-11, and 1.5 for the compound P-12.

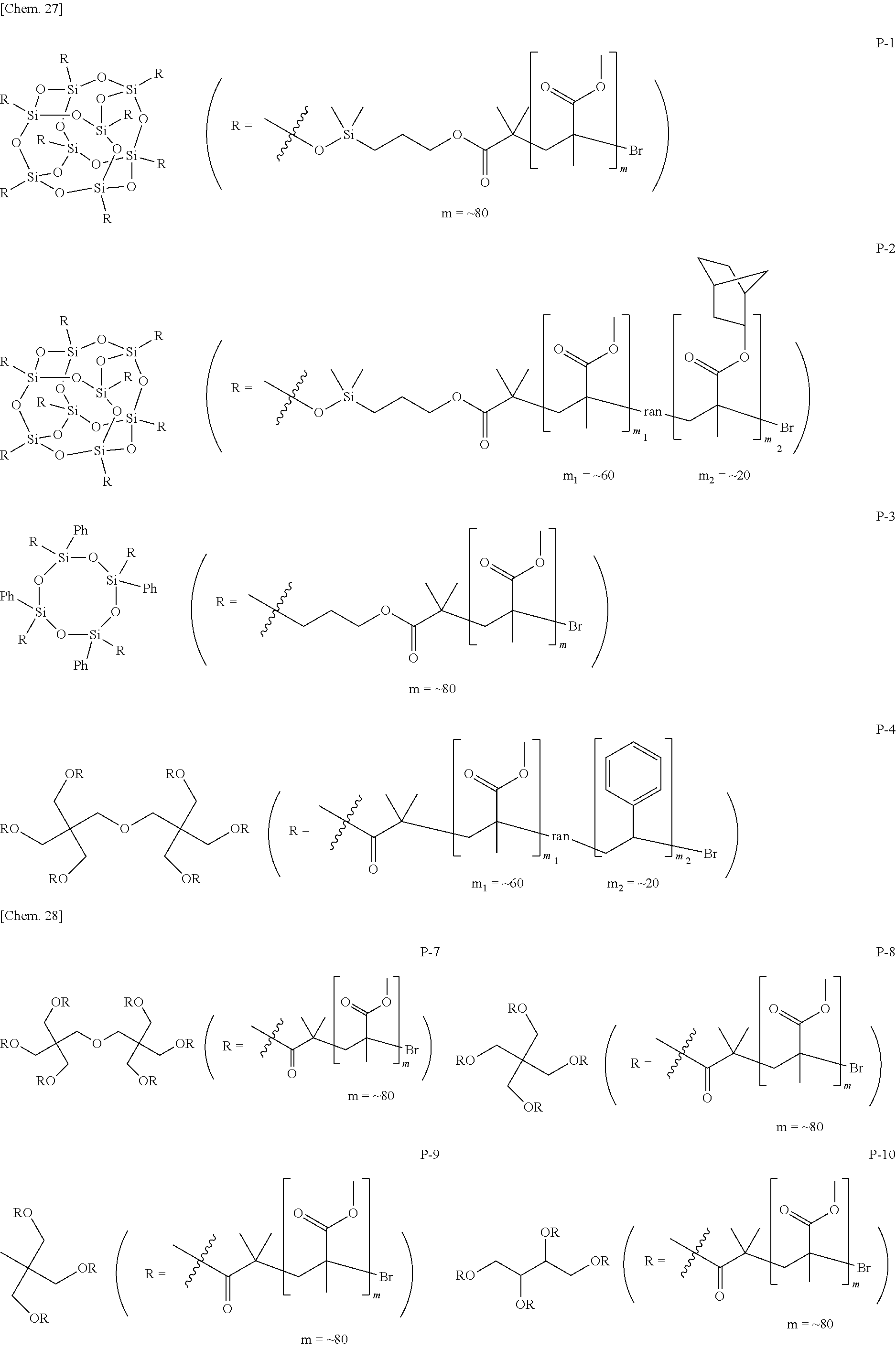

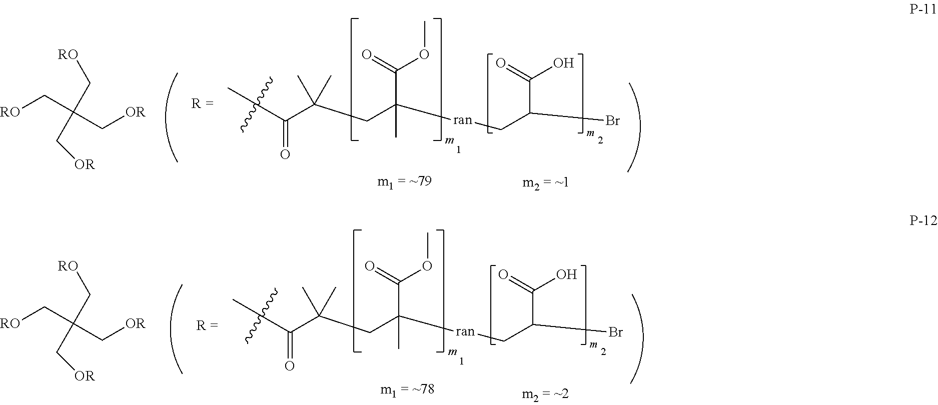

### Synthesis Example 1

### Synthesis Method of Compound P-1

In Synthesis Example 1, octakis {(2-bromoisobutyrate)propyldimethylsilyloxy}octasilsesquioxane (2.8 g), methyl methacrylate (MMA) (80 g), and 2,2′-azodiisobutyronitrile (AIBN) (0.49 g) were placed in a flask, and the inside of the flask was replaced with nitrogen. A solution of copper (II) bromide (0.039 g), tris(2-pyridylmethyl)amine (TPMA) (0.051 g), and degassed dimethylformamide (DMF) (80 mL) mixed therein was added to the flask, and stirred at 70 °C for 12 hours. The reaction solution was cooled to room temperature, added dropwise to a large amount of water to precipitate, filtered, and dried to obtain a white solid. The resulting white solid was dissolved in ethyl acetate, and the solution was added dropwise to a large amount of methanol to precipitate, then filtered and dried. Thus, 80 g of the compound P-1 was obtained.

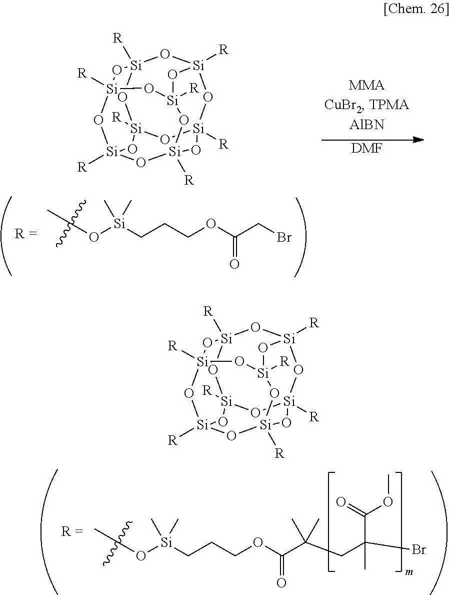

### Synthesis Example 2

### Synthesis Method of Compound P-8

In Synthesis Example 2, pentaerythritoltetrakis{(2-bromoisobutyrate) (1.5 g), methyl methacrylate (MMA) (80 g), and 2,2′-azodiisobutyronitrile (AIBN) (0.99 g) were placed in a flask, and the inside of the flask was replaced with nitrogen. A solution of copper (II) bromide (0.078 g), tris(2-pyridylmethyl)amine (TPMA) (0.10 g), and degassed dimethylformamide (DMF) (80 mL) mixed therein was added to the flask, and stirred at 70 °C for 12 hours. The reaction solution was cooled to room temperature, added dropwise to a large amount of water to precipitate, filtered, and dried to obtain a white solid. The resulting white solid was dissolved in ethyl acetate, and the solution was added dropwise to a large amount of methanol to precipitate, then filtered and dried. Thus, 80 g of the compound P-8 was obtained.

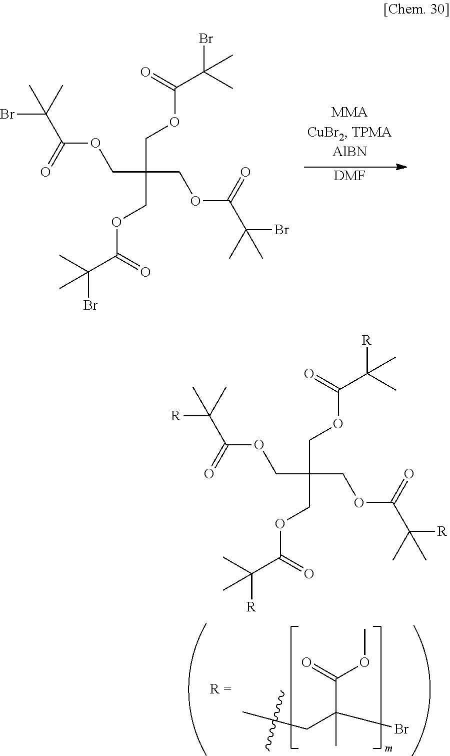

In Examples described below, compounds P-5, P-6, and compounds P-13, P-14 were used as binder resins. The compounds P-5, P-6 and the compounds P-13 and P-14 are branched polymers shown below.
Compound P-5: Acrylic graft polymer “RESEDA GP-301” (manufactured by Toagosei Company, Limited; acid value; 0 mgKOH/g, base number: 0 mgKOH/g)
Compound P-6: Hyperbranched polymer manufactured by SIGMA-ALDRICH (SIGMA-ALDRICH®, product number 806331, acid value: 0 mg KOH/g, base number: 0 mg KOH/g)
Compound P-13: Acrylic graft polymer “DISPERBYK-2023” (manufactured by BYK Japan KK, acid value: 4, base number: 7)
Compound P-14: Acrylic graft polymer “DISPERBYK-2013” (manufactured by BYK Japan KK, acid value: 8, base number: 18)

### <Other Binder Resin>

In the following Examples and Comparative Examples, Resin A, Resin B, and Resin C, which were not branched polymers, were used as other binder resins. Resin A, Resin B, and Resin C are as follows.
Resin A: PMMA resin BR-85 (manufactured by Mitsubishi Chemical Corporation, Tg=105 °C)
Resin B: PMMA-hydrogenated styrene copolymer resin Optimas 7500 (manufactured by MITSUBISHI GAS CHEMICAL COMPANY, INC., Tg=120 °C)
Resin C: Acrylic resin Hi-pearl M-4501 (manufactured by Negami Chemical Industrial Co., Ltd., Tg=84 °C)

### <Scattering Material>

In the following Examples and Comparative Examples, titanium dioxide particles “JR-301” (manufactured by TAYCA CORPORATION) were used as the scattering material.

### Example 1

In Example 1, first, 80 parts by weight of resin A, which is one of binder resins, was mixed with 20 parts by weight of compound P-1 as a branched polymer which is one of binder resins, 0.28 parts by weight of compound D-1 as a luminescent material, 3.0 parts by weight of JR-301 as a scattering material, and 300 parts by weight of ethyl acetate as a solvent. Then, the mixture was stirred and defoamed at 1,000 rpm for 20 minutes by using a planetary stirring/defoaming device, “MAZERUSTAR®” KK-400 (manufactured by Kurabo Industries Ltd.), to obtain a resin liquid for preparation of a color conversion layer.

Next, the above-obtained resin liquid for preparation of a color conversion layer was applied on “Cerapeel” BLK (manufactured by TORAY ADVANCED FILM Co., Ltd.) using a film applicator, and heated and dried at 120 °C for 20 minutes to form a color conversion layer having a mean film thickness of 20 μm.

Next, the thermosetting adhesive layer was applied on a polyethylene terephthalate film “LUMIRROR®” U48 (manufactured by Toray Industries, Inc.; thickness: 50 μm) using a coating method, on which was laminated an ethylene-vinyl alcohol copolymer film (ethylene content, 32 mol %; thickness, 12 μm; total light transmittance 90%). Thus, an oxygen barrier laminate film 1, which is an example of a barrier layer, was produced. The oxygen permeability of the oxygen barrier laminate film 1 using the ethylene-vinyl alcohol copolymer film was about 0.7 cc/m²·day·atm. Two sheets of the oxygen barrier laminate film 1 were prepared.

Subsequently, the thermosetting adhesive layer was applied on an ethylene-vinyl alcohol copolymer film side of one sheet of the oxygen barrier laminate film 1 using a coating method, on which was laminated a color conversion layer. Thereafter, the above-mentioned “Cerapeel” BLK was peeled off from this color conversion layer.

Finally, the thermosetting adhesive layer was formed on an ethylene-vinyl alcohol copolymer film side of another sheet of the oxygen barrier laminate film 1 using a coating method, and the obtained thermosetting adhesive layer was laminated on the above-described color conversion layer after “Cerapeel” BLK had been peeled off. Thus, the sheet-like color conversion member (color conversion sheet) having a structure shown in FIG. 3 above was prepared. The mean film thickness of the thermosetting adhesive layers included in the color conversion member was all 0.50 μm. Note that the thermosetting adhesive layer is not shown in FIG. 3.

The sheet-like color conversion member prepared as described above was used to convert the color of the light from the blue LED element. As a result, when only the green light emission region was extracted, green light emission with high color purity was obtained, with a peak wavelength of 526 nm and a full width at half maximum of the emission spectrum at the peak wavelength of 29 nm. Moreover, after continuous irradiation of light from the blue LED element under an environment at 50 °C, the time required for the emission peak intensity to decrease by 5% (durability against light) was about 1,000 hours. Example 1 showed approximately two times improvement in durability against light compared to Comparative Example 1 described below. The composition and evaluation results of the color conversion members of Example 1 are as shown in Table 1.

### Examples 2 to 10

In Examples 2 to 10, the sheet-like color conversion member was prepared and evaluated in the same manner as in Example 1, except that the luminescent materials, branched polymers, and binder resins were changed to those listed in Table 1, and the amount of the luminescent material mixed was changed to the same amount of substance as that of the compound D-1 in Example 1. The composition and evaluation results of the color conversion members of Examples 2 to 10 are as shown in Table 1.

### Examples 11 to 14

In Examples 11 to 14, the sheet-like color conversion member was prepared and evaluated in the same manner as in Example 1, except that branched polymers listed in Table 1 were used without using other binder resins, and the amounts of the branched polymers were changed to 100 parts by weight. The composition and evaluation results of the color conversion members of Examples 11 to 14 are as shown in Table 1.

### Comparative Examples 1 to 5

In Comparative Examples 1 to 5, the sheet-like color conversion members were produced and evaluated in the same manner as in Example 1, except that the luminescent materials listed in Table 1 were used as the luminescent materials and binder resins, no branched polymers were used, the amounts of other binder resins were changed to 100 parts by weight, and the amount of the luminescent material mixed was adjusted to the same amount of substance as that of the compound D-1 in Example 1. The composition and evaluation results for the color conversion member of each of Comparative Examples 1 to 5 are as shown in Table 1.

### Example 15

In Example 15, first, 80 parts by weight of resin A, which is one of binder resins, was mixed with 20 parts by weight of compound P-1 as a branched polymer which is one of binder resins, 1.0 parts by weight of compound D-2 as a luminescent material, and 300 parts by weight of ethyl acetate as a solvent. Then, the mixture was stirred and defoamed at 1,000 rpm for 20 minutes by using a planetary stirring/defoaming device, “MAZERUSTAR®” KK-400 (manufactured by Kurabo Industries Ltd.), to obtain a resin liquid for preparation of a color conversion layer.

In the same manner as described above, a polyester resin “Vylon®” 630 (manufactured by Toyobo Co., Ltd.) was used as a resin, and 300 parts by weight of ethyl acetate as a solvent was mixed with 100 parts by weight of the polyester resin. Then, the mixture was stirred and defoamed at 300 rpm for 20 minutes by using a planetary stirring/defoaming device, “MAZERUSTAR®” KK-400 (manufactured by Kurabo Industries Ltd.), to obtain a resin composition for adhesive layer.

Next, the resin composition for preparation of a color conversion layer obtained as described above was applied to a substrate layer, a polyethylene terephthalate film “Lumirror®” U34 (manufactured by Toray Industries, Inc.; thickness: 75 μm), and was heated at 120 °C for 20 minutes and dried to form a color conversion layer having a mean film thickness of 20 μm, and a unit including the color conversion layer was obtained.

Next, the resin composition for preparation of a color conversion layer for adhesive layer obtained as described above was applied on a substrate layer side of a diffusion film, “Texcel®” TDF127 (manufactured by Toray Advanced Materials, Inc.; thickness: 145 μm) having a laminate structure of the substrate layer and the diffusion layer, and was heated and dried at 120 °C for 20 minutes to form an adhesive layer having a mean film thickness of 10 μm, thereby to obtain a unit including the adhesive layer.

Finally, the above two units were heat-laminated so that the color conversion layer and the adhesive layer were directly laminated, thereby preparing the sheet-like color conversion member having a laminate structure of “substrate layer/color conversion layer/adhesive layer/substrate layer/light diffusion layer”. This laminate structure can be a structure in which a light diffusion layer is formed on either one of the two substrate layers shown in FIG. 2 above. Note that the adhesive layer is not shown in FIG. 2.

The sheet-like color conversion member prepared as described above was used to convert the color of the light from the blue LED element. As a result, when only the green light emission region was extracted, green light emission with high color purity was obtained, with a peak wavelength of 528 nm and a full width at half maximum of the emission spectrum at the peak wavelength of 29 nm. Moreover, after continuous irradiation of light from the blue LED element under an environment at 50 °C, the time required for the emission peak intensity to decrease by 5% was about 1,000 hours. Example 15 showed approximately two times improvement in durability against light compared to Comparative Example 6 described below. The composition and evaluation results of the color conversion members of Example 15 are as shown in Table 2.

### Examples 16 to 22

In Examples 16 to 22, the sheet-like color conversion member was prepared and evaluated in the same manner as in Example 15, except that branched polymers and other binder resin were changed to those listed in Table 2. The composition and evaluation results of the color conversion members of Examples 16 to 22 are as shown in Table 2.

### Examples 23 to 29

In Examples 23 to 29, the sheet-like color conversion member was prepared and evaluated in the same manner as in Example 15, except that branched polymers listed in Table 2 were used without using other binder resins, and the amounts of the branched polymers were changed to 100 parts by weight. The composition and evaluation results of the color conversion members of Examples 23 to 29 are as shown in Table 2.

### Comparative Example 6

In Comparative Example 6, the sheet-like color conversion member was prepared and evaluated in the same manner as in Example 15, except that no branched polymer was used and the amount of the resin A, which is a binder resin, was changed to 100 parts by weight. The composition and evaluation results for the color conversion member of Comparative Example 6 are as shown in Table 2.

### Example 30

In Example 30, first, 80 parts by weight of resin A, which is one of binder resins, was mixed with 20 parts by weight of compound P-1 as a branched polymer which is one of binder resins, 0.1 parts by weight of compound D-5 as a luminescent material, 3.0 parts by weight of JR-301 as a scattering material, and 300 parts by weight of ethyl acetate as a solvent. Then, the mixture was stirred and defoamed at 1,000 rpm for 20 minutes by using a planetary stirring/defoaming device, “MAZERUSTAR®” KK-400 (manufactured by Kurabo Industries Ltd.), to obtain a resin liquid for preparation of a color conversion layer.

In the same manner as described above, a polyester resin “Vylon®” 630 (manufactured by Toyobo Co., Ltd.) was used as a resin, and 300 parts by weight of ethyl acetate as a solvent was mixed with 100 parts by weight of this polyester resin. Then, the mixture was stirred and defoamed at 300 rpm for 20 minutes by using a planetary stirring/defoaming device, “MAZERUSTAR®” KK-400 (manufactured by Kurabo Industries Ltd.), to obtain a resin composition for adhesive layer.

Next, the resin composition for preparation of a color conversion layer obtained as described above was applied to a substrate layer, “Lumirror®” U34 (manufactured by Toray Industries, Inc.; thickness: 75 μm) using a slit die coater, and was heated at 120 °C for 20 minutes and dried to form a color conversion layer having a mean film thickness of 20 μm, thereby to obtain a unit including the color conversion layer.

Next, the resin composition for preparation of a color conversion layer for adhesive layer obtained as described above was applied to a substrate layer, “Lumirror®” U34 (manufactured by Toray Industries, Inc.; thickness: 75 μm), and was heated at 120 °C for 20 minutes to form an adhesive layer having a mean film thickness of 10 μm, thereby to obtain a unit including the adhesive layer.

Finally, the above two units were heat-laminated so that the color conversion layer and the adhesive layer were directly laminated, thereby preparing the sheet-like color conversion member having a laminate structure shown in FIG. 2 above. Note that the adhesive layer is not shown in FIG. 2.

The sheet-like color conversion member prepared as described above was used to convert the color of the light from the blue LED element. As a result, when only the red light emission region was extracted, red light emission with high color purity was obtained, with a peak wavelength of 625 nm and a full width at half maximum of the emission spectrum at the peak wavelength of 49 nm. Moreover, after continuous irradiation of light from the blue LED element under an environment at 50 °C, the time required for the emission peak intensity to decrease by 5% was about 1,000 hours. Example 30 showed approximately two times improvement in durability against light compared to Comparative Example 7 described below. The composition and evaluation results of the color conversion members of Example 30 are as shown in Table 3.

### Examples 31 to 33

In Examples 31 to 33, the sheet-like color conversion member was prepared and evaluated in the same manner as in Example 30, except that the luminescent materials and branched polymers were changed to those listed in Table 3, and the amount of the luminescent material mixed was changed to the same amount of substance as that of the compound D-5 in Example 30. The composition and evaluation results of the color conversion members of Examples 31 to 33 are as shown in Table 3.

### Examples 34 and 35

In Examples 34 and 35, the sheet-like color conversion member was prepared and evaluated in the same manner as in Example 31, except that branched polymers listed in Table 3 were used without using other binder resins, and the amounts of the branched polymers were changed to 100 parts by weight. The composition and evaluation results of the color conversion members of Examples 34 and 35 are as shown in Table 3.

### Comparative Examples 7 to 9

In Comparative Examples 7 to 9, the sheet-like color conversion members were produced and evaluated in the same manner as in Example 30, except that the luminescent materials listed in Table 3 were used as the luminescent materials, no branched polymers were used, the amounts of other binder resins were changed to 100 parts by weight, and the amount of the luminescent material mixed was adjusted to the same amount of substance as that of the compound D-5 in Example 30. The composition and evaluation results for the color conversion member of each of Comparative Examples 7 to 9 are as shown in Table 3.

### Example 36

In Example 36, first, 90 parts by weight of resin A, which is one of binder resins, was mixed with 10 parts by weight of compound P-1 as a branched polymer which is one of binder resins, 0.1 parts by weight of compound D-5 as a luminescent material, 3.0 parts by weight of JR-301 as a scattering material, and 300 parts by weight of ethyl acetate as a solvent. Then, the mixture was stirred and defoamed at 1,000 rpm for 20 minutes by using a planetary stirring/defoaming device, “MAZERUSTAR®” KK-400 (manufactured by Kurabo Industries Ltd.), to obtain a resin composition for preparation of a color conversion layer.

Next, the resin composition for preparation of a color conversion layer obtained as described above was applied to a substrate layer, “Lumirror®” U34 (manufactured by Toray Industries, Inc.; thickness: 75 μm), and was heated at 120 °C for 20 minutes and dried to form a layer (A) with a mean film thickness of 16 μm. Thus, the sheet-like color conversion member having a laminate structure shown in FIG. 1 above was prepared.

The sheet-like color conversion member prepared as described above was used to convert the color of the light from the blue LED element. As a result, when only the green light emission region was extracted, green light emission with high color purity was obtained, with a peak wavelength of 528 nm and a full width at half maximum of the emission spectrum at the peak wavelength of 29 nm, as in Example 15. Taking the emission intensity in Comparative Example 10 described below as 1.00, the emission intensity of the green light in Example 36 was 1.05, which is 5% higher than that in Comparative Example 10. The composition and evaluation results of the color conversion members of Example 36 are as shown in Table 4.

### Examples 37 to 40

In Examples 37 to 40, the sheet-like color conversion member was prepared and evaluated in the same manner as in Example 36, except that branched polymers were changed to those listed in Table 4. The composition and evaluation results of the color conversion members of Examples 37 to 40 are as shown in Table 4.

### Examples 41 to 43

In Examples 41 to 43, the sheet-like color conversion member was prepared and evaluated in the same manner as in Example 36, except that branched polymers listed in Table 4 were used without using other binder resins, and the amounts of the branched polymers were changed to 100 parts by weight. The compositions and evaluation results of the color conversion member in each of Examples 41 to 43 are as shown in Table 4.

### Comparative Example 10

In Comparative Example 10, the sheet-like color conversion member was prepared and evaluated in the same manner as in Example 36, except that no branched polymer was used and the amount of the resin A, which is another binder resin, was changed to 100 parts by weight. The composition and evaluation results for the color conversion member of Comparative Example 10 are as shown in Table 4.

TABLE 1

| | | | | | Full | |
|---|---|---|---|---|---|---|
| | | | | | width at | |
| | | | Another | Peak | half | Durability |
| | Luminescent | Branched | binder | wavelength | maximum | against |
| | material | polymer | resin | (nm) | (nm) | light (h) |
| Example 1 | D-1 | P-1 | A | 526 | 29 | 1000 |
| Example 2 | D-1 | P-3 | A | 526 | 29 | 800 |
| Example 3 | D-1 | P-4 | A | 526 | 29 | 750 |
| Example 4 | D-1 | P-5 | A | 526 | 29 | 600 |
| Example 5 | D-1 | P-6 | A | 526 | 29 | 650 |
| Example 6 | D-1 | P-8 | A | 526 | 29 | 900 |
| Example 7 | D-1 | P-1 | C | 526 | 29 | 650 |
| Example 8 | D-3 | P-1 | A | 519 | 38 | 1500 |
| Example 9 | D-4 | P-1 | A | 520 | 31 | 1000 |
| Example 10 | D-7 | P-1 | A | 490 | 61 | 480 |
| Example 11 | D-1 | P-1 | — | 526 | 29 | 750 |
| Example 12 | D-1 | P-8 | — | 526 | 29 | 700 |
| Example 13 | D-1 | P-5 | — | 526 | 29 | 550 |
| Example 14 | D-3 | P-1 | — | 519 | 38 | 1200 |
| Comparative | D-1 | — | A | 526 | 29 | 500 |
| Example 1 | | | | | | |
| Comparative | D-3 | — | A | 519 | 38 | 800 |
| Example 2 | | | | | | |
| Comparative | D-4 | — | A | 520 | 31 | 550 |
| Example 3 | | | | | | |
| Comparative | D-7 | — | A | 490 | 61 | 300 |
| Example 4 | | | | | | |
| Comparative | D-1 | — | C | 526 | 29 | 400 |
| Example 5 | | | | | | |

TABLE 2

| | | | | | Full | |
|---|---|---|---|---|---|---|
| | | | | | width at | |
| | | | Another | Peak | half | Durability |
| | Luminescent | Branched | binder | wavelength | maximum | against |
| | material | polymer | resin | (nm) | (nm) | light (h) |
| Example 15 | D-2 | P-1 | A | 528 | 29 | 1000 |
| Example 16 | D-2 | P-1 | B | 528 | 29 | 1300 |
| Example 17 | D-2 | P-2 | B | 528 | 29 | 1600 |
| Example 18 | D-2 | P-7 | B | 528 | 29 | 1300 |
| Example 19 | D-2 | P-8 | B | 528 | 29 | 1300 |
| Example 20 | D-2 | P-9 | B | 528 | 29 | 1000 |
| Example 21 | D-2 | P-10 | B | 528 | 29 | 1200 |
| Example 22 | D-2 | P-12 | B | 528 | 29 | 1000 |
| Example 23 | D-2 | P-1 | — | 528 | 29 | 700 |
| Example 24 | D-2 | P-2 | — | 528 | 29 | 1000 |
| Example 25 | D-2 | P-7 | — | 528 | 29 | 700 |
| Example 26 | D-2 | P-8 | — | 528 | 29 | 700 |
| Example 27 | D-2 | P-9 | — | 528 | 29 | 600 |
| Example 28 | D-2 | P-10 | — | 528 | 29 | 600 |
| Example 29 | D-2 | P-12 | — | 528 | 29 | 550 |
| Comparative | D-2 | — | A | 528 | 29 | 500 |
| Example 6 | | | | | | |

TABLE 3

| | | | | | Full | |
|---|---|---|---|---|---|---|
| | | | | | width at | |
| | | | Another | Peak | half | Durability |
| | Luminescent | Branched | binder | wavelength | maximum | against |
| | material | polymer | resin | (nm) | (nm) | light (h) |
| Example 30 | D-5 | P-1 | A | 625 | 49 | 1000 |
| Example 31 | D-6 | P-1 | A | 620 | 41 | 1400 |
| Example 32 | D-6 | P-8 | A | 620 | 41 | 1400 |
| Example 33 | D-8 | P-1 | A | 603 | 55 | 1100 |
| Example 34 | D-6 | P-1 | — | 620 | 41 | 1200 |
| Example 35 | D-6 | P-8 | — | 620 | 41 | 1100 |
| Comparative | D-5 | — | A | 625 | 49 | 500 |
| Example 7 | | | | | | |
| Comparative | D-6 | — | A | 620 | 41 | 700 |
| Example 8 | | | | | | |
| Comparative | D-8 | — | A | 603 | 55 | 600 |
| Example 9 | | | | | | |

TABLE 4

| | Luminescent | Branched | Another binder | Light emission |
|---|---|---|---|---|
| | material | polymer | resin | intensity |
| Example 36 | D-2 | P-1 | A | 1.05 |
| Example 37 | D-2 | P-8 | A | 1.05 |
| Example 38 | D-2 | P-5 | A | 1.03 |
| Example 39 | D-2 | P-13 | A | 0.90 |
| Example 40 | D-2 | P-14 | A | 0.50 |
| Example 41 | D-2 | P-1 | — | 1.03 |
| Example 42 | D-2 | P-8 | — | 1.03 |
| Example 43 | D-2 | P-11 | — | 1.00 |
| Comparative | D-2 | — | A | 1.00 |
| Example 10 | | | | |

### INDUSTRIAL APPLICABILITY

As seen above, a color conversion composition and a color conversion member according to the present invention, and a light source unit, a display, and a lighting device, including the same, are suitable for achieving both improved color reproducibility and increased durability against light.

### REFERENCE SIGNS LIST

1A, 1B, 1C, 1D, 1E, 1F color conversion member
10, 10A, 10B substrate layer
11, 11A, 11B color conversion layer
12A, 12B barrier layer
13 intermediate layer

1. A color conversion composition comprising:
at least one luminescent material and a binder resin,
wherein the binder resin contains at least one branched polymer selected from the group consisting of a star polymer, a graft polymer, and a hyperbranched polymer.

2. The color conversion composition according to claim 1,
wherein the binder resin contains at least the star polymer, and
an arm polymer of the star polymer is a polymer of at least one monomer selected from the group consisting of a vinyl compound, acrylic acid, acrylate ester, acrylamide, methacrylic acid, methacrylate ester, and methacrylamide.

3. The color conversion composition according to claim 1,
wherein the binder resin contains at least the star polymer, and
a core part of the star polymer is a part containing any one of a sugar alcohol derivative, a cyclic siloxane derivative, and silsesquioxane.

4. The color conversion composition according to claim 1,
wherein the binder resin contains at least the star polymer, and
a core part of the star polymer is a part containing silsesquioxane.

5. The color conversion composition according to claim 1,
wherein the binder resin contains at least the star polymer, and
a core part of the star polymer is a part containing a sugar alcohol derivative.

6. The color conversion composition according to claim 1,
wherein an acid value of the at least one branched polymer is 10 mgKOH/g or less.

7. The color conversion composition according to claim 1,
wherein a base number of the at least one branched polymer is 10 mgKOH/g or less.

8. The color conversion composition according to claim 1,
wherein the binder resin further contains a resin that does not fall under any one of the star polymer, the graft polymer, and the hyperbranched polymer, the resin being a polymer of at least one monomer selected from the group consisting of acrylate ester, methacrylate ester, and styrene, or a hydrogenated product thereof.

9. The color conversion composition according to claim 1,
wherein the binder resin further contains a resin that does not fall under any one of the star polymer, the graft polymer, and the hyperbranched polymer, the resin having a glass transition temperature of 100 °C or more.

10. The color conversion composition according to claim 1,
wherein a full width at half maximum of an emission spectrum at an emission peak wavelength of the at least one luminescent material is 60 nm or less.

11. The color conversion composition according to claim 1,
wherein the at least one luminescent material contains a compound having a partial structure of the general formula (1): 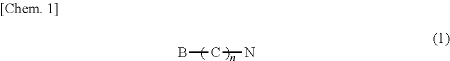
(wherein in the general formula (1), B is a boron atom, N is a nitrogen atom, and C is a carbon atom; n is an integer of 0 to 2; and when n is 0, the partial structure of the general formula (1) is a directly combined structure between B and N).

12. The color conversion composition according to claim 1,
wherein the at least one luminescent material contains at least one of a compound of the general formula (2), a compound of the general formula (3), and a compound of the general formula (4): 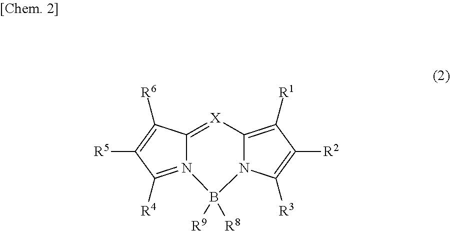
(wherein in the general formula (2), X is C—R⁷ or N; each of R¹ to R⁹, which may be the same as or different from one another, is a substituent selected from a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, a carbonyl group, a carboxyl group, an oxycarbonyl group, an ester group, a carbamoyl group, an amide group, a sulfonyl group, a sulfonate ester group, a sulfonamide group, an amino group, an imino group, a nitro group, a silyl group, a siloxanyl group, a boryl group, a phosphine oxide group, and a fused ring and an aliphatic ring each formed between adjacent substituents; and each of the R¹ to R⁹ may independently be substituted with the selected substituent, and these substituents may be further substituted with the selected substituent) 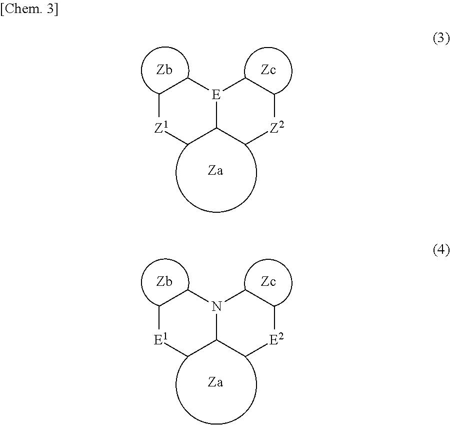
(wherein in the general formula (3) or the general formula (4), the ring Za, the ring Zb, and the ring Zc independently are a substituted or unsubstituted aryl ring having 6 to 30 ring-forming carbon atoms or a substituted or unsubstituted heteroaryl ring having 5 to 30 ring-forming carbon atoms; Z¹ and Z² are independently an oxygen atom, NRa (a nitrogen atom bearing a Ra substituent), or sulfur atom; in cases where Z¹ is NRa, the substituent Ra, together with the ring Za or the ring Zb, optionally forms a ring; in cases where Z² is NRa, the substituent Ra, together with the ring Za or the ring Zc, optionally forms a ring; E is a boron atom, a phosphorus atom, SiRa (a silicon atom bearing a Ra substituent), or P═O; E¹ and E² are independently BRa (a boron atom bearing a Ra substituent), PRa (a phosphorus atom bearing a Ra substituent), SiRa₂ (a silicon atom bearing two Ra substituents), P(═O)Ra₂ (a phosphine oxide bearing two Ra substituents) or P(═S)Ra₂ (phosphine sulfide bearing two Ra substituents), C═O (a carbonyl group), S(═O) or S(═O)₂; in cases where E¹ is BRa, PRa, SiRa₂, P(═O)Ra₂, or P(═S)Ra₂, the substituent Ra, together with the ring Za or the ring Zb, optionally forms a ring; in cases where E² is BRa, PRa, SiRa₂, P(═O)Ra₂, or P(═S)Ra₂, the substituent Ra, together with the ring Za or the ring Zc, optionally forms a ring; each of substituents Ra independently is a substituent selected from a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, a carbonyl group, a carboxyl group, an oxycarbonyl group, an ester group, a carbamoyl group, an amide group, a sulfonyl group, a sulfonate ester group, a sulfonamide group, an amino group, an imino group, a nitro group, a silyl group, a siloxanyl group, a boryl group, a phosphine oxide group, and a fused ring and an aliphatic ring each formed between adjacent substituents; and the substituent Ra may independently be substituted with the selected substituent, and these substituents may be further substituted with the selected substituent).

13. A color conversion member comprising the color conversion composition according to claim 1 or a cured product thereof.

14. A light source unit, comprising:
a light source, and
the color conversion member according to claim 13.

15. The light source unit according to claim 14,
wherein the light source is a light-emitting diode or an organic electroluminescence element with a maximum light emission having a wavelength of in the range of 400 nm to 500 nm.

16. A display comprising the light source unit according to claim 14.

17. A lighting device comprising the light source unit according to claim 14.
